(19) United States
(12) Patent Application Publication
(10) Pub. No.: US 2025/0326968 A1
(43) Pub. Date: Oct. 23, 2025

(54) URANIUM-BASED PHOSPHORS AND COMPOSITIONS FOR DISPLAYS AND LIGHTING APPLICATIONS

(71) Applicant: EDISON INNOVATIONS, LLC, Allen, TX (US)

(72) Inventors: Samuel Joseph Camardello, Niskayuna, NY (US); Anant A. Setlur, Niskayuna, NY (US); James E. Murphy, Niskayuna, NY (US)

(21) Appl. No.: 18/698,659

(22) PCT Filed: Oct. 10, 2022
(86) PCT No.: PCT/US2022/077858

§ 371 Date: Apr. 4, 2024

Related U.S. Application Data
(63) Continuation-in-part of application No. PCT/US2022/024577, filed on Apr. 13, 2022.
(60) Provisional application No. 63/254,021, filed on Oct. 8, 2021.

(51) Int. Cl. C09K 11/77; C09K 11/02; C09K 11/61; H10H 20/851

(52) U.S. Cl. CPC C09K 11/7796; C09K 11/025; C09K 11/617; C09K 11/7709; C09K 11/771; C09K 11/7777; C09K 11/7778; C09K 11/7795; H10H 20/8513

(57) ABSTRACT

A uranium-based phosphor selected from (i) phosphors having formula I or II:

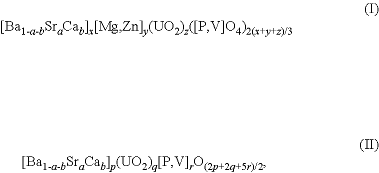

where the phosphor having formula I or II is doped with an activator ion including Pr³⁺, Sm³⁺, or mixtures thereof, where 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5; (ii) a phosphor having formula I or II, where the phosphor having formula I or II is doped with an activator ion selected from Eu³⁺, Pr³⁺, Sm³⁺, and mixtures thereof; and a counter ion comprising one or more alkali metal ions; and (iii) phosphors having formula III

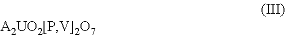

where the phosphors having formula III are doped with an activator ion selected from: Eu³⁺, Pr³⁺, Sm³⁺, and mixtures thereof, where A is Li, Na, K, Rb, Cs, or a combination thereof.

### CROSS REFERENCE TO RELATED APPLICATIONS

This is a U.S. National Stage Entry of International Application No. PCT/US2022/077858 filed Oct. 10, 2022, which claims the priority benefit of U.S. Provisional Patent Application Ser. No. 63/254,021 filed Oct. 8, 2021 and of International Application No. PCT/US2022/024577 filed Apr. 13, 2022, each of which is incorporated herein by reference in its entirety.

### BACKGROUND OF THE INVENTION

The field of the invention relates generally to phosphor materials and devices, and more particularly to Uranium-based phosphor materials useful for display applications and lighting applications.

General lighting is based on human eye sensitivity to visible radiation and on the solar spectra. The effect of eye sensitivity relates to the total lumen output, while the match to full spectra of solar radiation creates the color rendering index (CRI). Traditional types of general lighting include incandescent lighting and fluorescent lighting. LED lighting provides increased efficacy. a 40% reduction in electricity use and an extended average life over traditional general lighting. LED lighting can cover a nearly continuous range across the visible wavelengths of about 380 nm to about 750 nm and can be used for general lighting applications and display applications. The tunability of LED lighting can be used to create both a full spectrum (high CRI) and high efficacy (lumens/watt) lighting based on the desired properties and phosphor combinations used. LED lighting also creates the ability to have human centric lighting, that will subtly change color throughout the day, and specialty lighting for applications such as plant growth.

White light can be generated by employing a near-ultraviolet (UV) or blue emitting LED in conjunction with an inorganic phosphor or a blend of inorganic phosphors, such as red-emitting phosphors and green or yellow-green emitting phosphors. The total emission from the phosphor and the LED chip provides a color point with corresponding color coordinates (x and y on the 1931 ClE chromaticity diagram) and correlated color temperature (CCT), and its spectral distribution provides a color rendering capability, measured by the color rendering index (CRI) based on a scale of 100. Efficacy is the measurement of the amount of light emitted per power used (lumens/watt) with higher amounts preferred. Narrow band red-emitting phosphors based on complex fluoride materials activated by Mn arc described in U.S. Pat. Nos. 7,358,542, 7,497,973, and 7,618,649. These complex fluorides can be utilized in combination with yellow-green emitting phosphors such as cerium-doped yttrium aluminum garnet Y₃Al₅O₁₂:Ce³⁺ (YAG) or other garnet compositions to achieve warm white light (CCTs<5000 K on the blackbody locus, color rendering index (CRI>80) from a blue LED, with high efficacy. High efficiency with a variety of emissions from the phosphor materials is also desired.

Current display device technology relies on liquid crystal displays (LCDs), which is one of the most widely used flat panel displays for industrial and residential applications. Next-generation devices will have low energy consumption, compact size, and high brightness, requiring larger color gamut coverage. Smaller LEDs, such as mini-LEDs or micro-LEDs, will be needed for next-generation devices. Mini-LEDs have a size of about 100 μm to 0.7 mm. For micro-LEDs, the displays may be self-emissive or include miniaturized backlighting arrayed with individual LEDs smaller than 100 μm. When these next-gen micro-LED displays are self-emissive and require a color conversion layer, very thin layers or films of phosphor material with high absorption coefficients are needed.

### BRIEF DESCRIPTION OF THE INVENTION

In one embodiment, uranium-based phosphor materials include phosphors including a uranyl (UO₂) group and having formulas I, II, III, N or V:

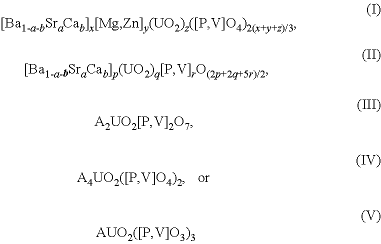

where 0≤a≤1, 0≤b≤1, 0.75≤x≤1.25, 0.75≤y≤1.25, 0.75≤z≤1.25; 2.5≤p≤3.5, 1.75≤q≤2.25, 3.5≤r≤4.5 and A is Li, Na, K, Rb, Cs, or a combination thereof.

In some embodiments, the uranium-based phosphors are doped with an activator ion. In some embodiments, the activator ion includes Pr³⁺, Sm³⁺, or mixtures thereof. In some embodiments, the activator ion is selected from Eu³⁺, Pr³⁺, Sm³⁺, and mixtures thereof. In some embodiments, the uranium-based phosphor is doped with a counter ion. In some embodiments, the counter ion is one or more alkali metal ions. In other embodiments, the counter ion is selected from Li⁺, K⁺, Na⁺, Rb⁺, Cs⁺, and mixtures thereof.

In one aspect, a uranium-based phosphor is provided. The uranium-based phosphor is selected from:
(i) a phosphor having formula I or II:

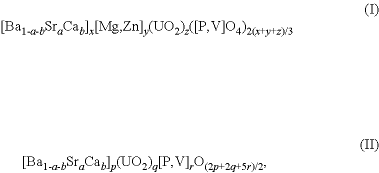

where the phosphor having formula I or II is doped with an activator ion including Pr³⁺, Sm³⁺, or mixtures thereof, where 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5;
(ii) a phosphor having formula I or II, where the phosphor having formula I or II is doped with an activator ion selected from Eu³⁺, Pr³⁺, Sm³⁺, and mixtures thereof; and a counter ion comprising one or more alkali metal ions; and
(iii) a phosphor having formula III:

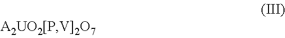

where the phosphor having formula III is doped with an activator ion selected from: Eu³⁺, Pr³⁺, Sm³⁺, and mixtures thereof, where A is Li, Na, K, Rb, Cs, or a combination thereof.

In another aspect, a uranium-based phosphor is provided. The uranium-based phosphor having formula (III), (N) or (V):

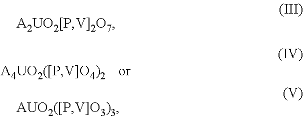

where A is Li, Na, K, Rb, Cs, or a combination thereof.

In another aspect, a phosphor composition is provided. The composition includes a uranium-based phosphor and at least one other luminescent material. The uranium-based phosphor is selected from:
(i) a phosphor having formula I or II:

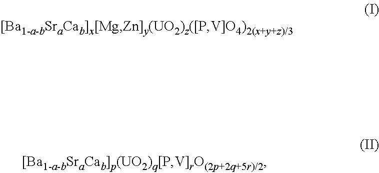

where the phosphor having formula I or II is doped with an activator ion including Pr³⁺, Sm³⁺, or mixtures thereof, where 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5;
(ii) a phosphor having formula I or II, where the phosphor having formula I or II is doped with an activator ion selected from Eu³⁺, Pr³⁺, Sm³⁺, and mixtures thereof; and a counter ion comprising one or more alkali metal ions; and
(iii) a phosphor having formula III:

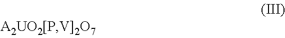

where the phosphor having formula III is doped with an activator selected from: Eu³⁺, Pr³⁺, Sm³⁺, and mixtures thereof, where A is Li, Na, K, Rb, Cs, or a combination thereof.

In another aspect, a phosphor composition is provided. The composition includes a uranium-based phosphor and at least one other luminescent material. The uranium-based phosphor having formula (III), (N) or (V):

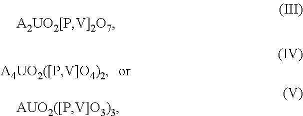

where A is Li, Na, K, Rb, Cs, or a combination thereof.

In another aspect, a phosphor composition is provided. The composition includes a uranium-based phosphor and a red emitting phosphor. The uranium-based phosphor is selected from:
(i) a phosphor having formula I or II:

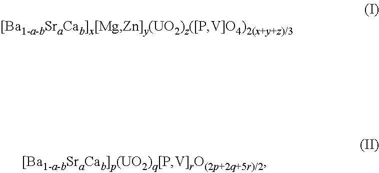

where the phosphor having formula I or II is doped with an activator ion including Pr³⁺, Sm³⁺, or mixtures thereof, where 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5;
(ii) a phosphor having formula I or II, where the phosphor having formula I or II is doped with an activator ion selected from Eu³⁺, Pr³⁺, Sm³⁺, and mixtures thereof; and a counter ion comprising one or more alkali metal ions; and
(iii) a phosphor having formula III:

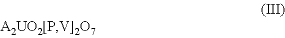

where the phosphor having formula III is doped with an activator selected from: Eu³⁺, Pr³⁺, Sm³⁺, and mixtures thereof, where A is Li, Na, K, Rb, Cs, or a combination thereof. The red emitting phosphor has formula VI:

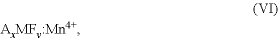

wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7.

In another aspect, a phosphor composition is provided. The composition includes a uranium-based phosphor and a red emitting phosphor. The uranium-based phosphor having formula (III), (IV) or (V):

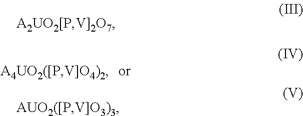

where A is Li, Na, K, Rb, Cs, or a combination thereof. The red emitting phosphor has formula VI:

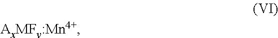

wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7.

In yet another aspect, a device including an LED light source radiationally and/or optically coupled to a uranium-based phosphor is provided. The uranium-based phosphor is selected from:
(i) a phosphor having formula I or II:

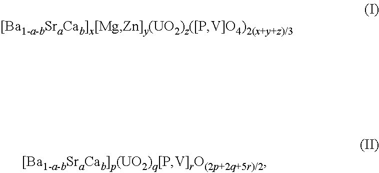

where the phosphor having formula I or II is doped with an activator ion including Pr³⁺, Sm³⁺, or mixtures thereof, where 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5;
(ii) a phosphor having formula I or II, where the phosphor having formula I or II is doped with an activator ion selected from Eu³⁺, Pr³⁺, Sm³⁺, and mixtures thereof; and a counter ion comprising one or more alkali metal ions; and
(iii) a phosphor having formula III:

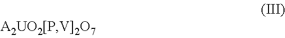

where the phosphor having formula III is doped with an activator ion selected from: Eu³⁺, Pr³⁺, Sm³⁺, and mixtures thereof, where A is Li, Na, K, Rb, Cs, or a combination thereof.

In yet another aspect, a device including an LED light source radiationally and/or optically coupled to a uranium-based phosphor is provided. The uranium-based phosphor having formula (III), (N) or (V):

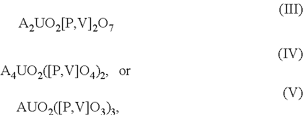

where A is Li, Na, K, Rb, Cs, or a combination thereof.

Another aspect is a lighting apparatus including the device. Yet another aspect is a backlight apparatus including the device. Another aspect is a device and lighting apparatus for horticulture lighting. Another aspect is a phosphor package for horticulture lighting.

### BRIEF DESCRIPTION OF THE DRAWINGS

FIG. 1 is a schematic cross-sectional view of a device, in accordance with one embodiment of the disclosure.

FIG. 2 is a schematic cross-sectional view of a lighting apparatus, in accordance with one embodiment of the disclosure.

FIG. 3 is a schematic cross-sectional view of a lighting apparatus, in accordance with another embodiment of the disclosure.

FIG. 4 is a cutaway side perspective view of a lighting apparatus, in accordance with one embodiment of the disclosure.

FIG. 5 is a schematic perspective view of a surface-mounted device (SMD), in accordance with one embodiment of the disclosure.

FIG. 6A is a spectra graph of emission wavelength (nm) vs. emission intensity for Na₂UO₂P₂O₇.

FIG. 6B is a spectra graph of emission wavelength (nm) vs. emission intensity for Na₂UO₂P₂O₇ doped with Eu³⁺.

FIG. 6C is a spectra graph of emission wavelength (nm) vs. emission intensity for Na₂UO₂P₂O₇ doped with Pr³⁺.

FIG. 6D is a spectra graph of emission wavelength (nm) vs. emission intensity for Na₂UO₂P₂O₇ doped with Sm³⁺.

FIG. 6E is a spectra graph of emission wavelength (nm) vs. emission intensity for Na₂UO₂P₂O₇ doped with Tb³⁺.

FIG. 6F is a spectra graph of emission wavelength (nm) vs. emission intensity for Na₂UO₂P₂O₇ doped with Dy³⁺.

FIG. 6G is a spectra graph of emission wavelength (nm) vs. emission intensity for Na₂UO₂P₂O₇ doped with Eu³⁺ and Pr³⁺.

FIG. 6H is a spectra graph of emission wavelength (nm) vs. emission intensity for Na₂UO₂P₂O₇ doped with Eu³⁺ and Sm³⁺.

FIG. 7A is a spectra graph of emission wavelength (nm) vs. emission intensity for K₂UO₂P₂O₇.

FIG. 7B is a spectra graph of emission wavelength (nm) vs. emission intensity for K₂UO₂P₂O₇ doped with Eu³⁺.

FIG. 7C is a spectra graph of emission wavelength (nm) vs. emission intensity for K₂UO₂P₂O₇ doped with Sm³⁺.

FIG. 7D is a spectra graph of emission wavelength (nm) vs. emission intensity for K₂UO₂P₂O₇ doped with Pr³⁺.

FIG. 8A is a spectra graph of emission wavelength (nm) vs. emission intensity for NaUO₂P₃O₉.

FIG. 8B is a spectra graph of emission wavelength (nm) vs. emission intensity for NaUO₂P₃O₉ doped with Eu³⁺.

FIG. 9A is a spectra graph of emission wavelength (nm) vs. emission intensity for K₄UO₂(PO₄)₂.

FIG. 9B is a spectra graph of emission wavelength (nm) vs. emission intensity for K₄UO₂(PO₄)₂ doped with Eu³⁺.

FIG. 10A is a spectra graph of emission wavelength (nm) vs. emission intensity for Ba₃(PO₄)₂(UO₂)₂P₂O₇.

FIG. 10B is a spectra graph of emission wavelength (nm) vs. emission intensity for Ba₃(PO₄)₂(UO₂)₂P₂O₇ doped with Eu³⁺.

FIG. 10C is a spectra graph of emission wavelength (nm) vs. emission intensity for Ba₃(PO₄)₂(UO₂)₂P₂O₇ doped with Eu³⁺ and K⁺.

FIG. 10D is a spectra graph of emission wavelength (nm) vs. emission intensity for Ba₃(PO₄)₂(UO₂)₂P₂O₇ doped with Sm³⁺ and K⁺.

FIG. 10E is a spectra graph of emission wavelength (nm) vs. emission intensity for Ba₃(PO₄)₂(UO₂)₂P₂O₇ doped with Pr³⁺ and K⁺.

FIG. 10F is a spectra graph of emission wavelength (nm) vs. emission intensity for Ba₃(PO₄)₂(UO₂)₂P₂O₇ doped with Sm³⁺ and K⁺.

FIG. 10G is a spectra graph of emission wavelength (nm) vs. emission intensity for Ba₃(PO₄)₂(UO₂)₂P₂O₇ doped with Pr³⁺ and K⁺.

FIG. 10H is a spectra graph of emission wavelength (nm) vs. emission intensity for Ba₃(PO₄)₂(UO₂)₂P₂O₇ doped with Eu³⁺ and K⁺.

FIG. 11A is a spectra graph of emission wavelength (nm) vs. emission intensity for BaZnUO₂(PO₄)₂.

FIG. 11B is a spectra graph of emission wavelength (nm) vs. emission intensity for BaZnUO₂(PO₄)₂ doped with Eu³⁺.

FIG. 11C is a spectra graph of emission wavelength (nm) vs. emission intensity for BaZnUO₂(PO₄)₂ doped with Eu³⁺ and K⁺.

FIG. 11D is a spectra graph of emission wavelength (nm) vs. emission intensity for BaZnUO₂(PO₄)₂ doped with Eu³⁺ and Li⁺.

FIG. 11E is a spectra graph of emission wavelength (nm) vs. emission intensity for BaZnUO₂(PO₄)₂ doped with Eu³⁺ and Na⁺.

FIG. 11F is a spectra graph of emission wavelength (nm) vs. emission intensity for BaZnUO₂(PO₄)₂ doped with Pr³⁺.

FIG. 11G is a spectra graph of emission wavelength (nm) vs. emission intensity for BaZnUO₂(PO₄)₂ doped with Pr³⁺ and K⁺.

FIG. 11H is a spectra graph of emission wavelength (nm) vs. emission intensity for BaZnUO₂(PO₄)₂ doped with Sm³⁺.

FIG. 11I is a spectra graph of emission wavelength (nm) vs. emission intensity for BaZnUO₂(PO₄)₂ doped with Sm³⁺ and K⁺.

FIG. 11J is a spectra graph of emission wavelength (nm) vs. emission intensity for BaZnUO₂(PO₄)₂ doped with Eu³⁺ and Li⁺.

FIG. 12 is a spectra graph of emission wavelength (nm) vs. emission intensity for BaZnUO₂(PO₄)₂ doped with Eu³⁺.

FIG. 13A is a spectra graph of emission wavelength (nm) vs. emission intensity for gamma-Ba₂UO₂(PO₄)₂.

FIG. 13B is a spectra graph of emission wavelength (nm) vs. emission intensity for gamma-Ba₂UO₂(PO₄)₂ doped with Eu³⁺.

FIG. 13C is a spectra graph of emission wavelength (nm) vs. emission intensity for gamma-Ba₂UO₂(PO₄)₂ doped with Eu³⁺ and K⁺.

FIG. 13D is a spectra graph of emission wavelength (nm) vs. emission intensity for gamma-Ba₂UO₂(PO₄)₂ doped with Sm³⁺ and K⁺.

FIG. 13E is a spectra graph of emission wavelength (nm) vs. emission intensity for gamma-Ba₂UO₂(PO₄)₂ doped with Pr³⁺ and K⁺.

FIG. 13F is a spectra graph of emission wavelength (nm) vs. emission intensity for gamma-Ba₂UO₂(PO₄)₂ doped with Dy³⁺ and K⁺.

FIG. 13G is a spectra graph of emission wavelength (nm) vs. emission intensity for gamma-Ba₂UO₂(PO₄)₂ doped with Tb³⁺ and K⁺.

FIG. 13H shows the XRD powder pattern for gamma-Ba₂UO₂(PO₄)₂.

FIG. 14 is a spectra graph of emission wavelength (nm) vs. emission intensity for Na₂UO₂P₂O₇:Eu³⁺ (U-Eu Red) and PFS phosphors in Example 11.

FIG. 15 is a spectra graph of emission wavelength (nm) vs. emission intensity for Na₂UO₂P₂O₇ doped with Eu³⁺.

FIG. 16 is a spectra graph of emission wavelength (nm) vs. emission intensity for Na₂UO₂P₂O₇ doped with Eu³⁺.

FIG. 17A is a spectra graph of emission wavelength (nm) vs. emission intensity for Rb₂UO₂P₂O₇.

FIG. 17B is a spectra graph of emission wavelength (nm) vs. emission intensity for Rb₂UO₂P₂O₇ doped with Sm³⁺.

FIG. 17C is a spectra graph of emission wavelength (nm) vs. emission intensity for Rb₂UO₂P₂O₇ doped with Eu³⁺.

FIG. 17D is a spectra graph of emission wavelength (nm) vs. emission intensity for Rb₂UO₂P₂O₇ doped with Pr³⁺.

FIG. 18A is a spectra graph of emission wavelength (nm) vs. emission intensity for Cs₂UO₂P₂O₇.

FIG. 18B is a spectra graph of emission wavelength (nm) vs. emission intensity for Cs₂UO₂P₂O₇ doped with Eu³⁺.

FIG. 18C is a spectra graph of emission wavelength (nm) vs. emission intensity for Cs₂UO₂P₂O₇ doped with Pr³⁺.

FIG. 18D is a spectra graph of emission wavelength (nm) vs. emission intensity for Cs₂UO₂P₂O₇ doped with Sm³⁺.

### DETAILED DESCRIPTION OF THE INVENTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. All references are incorporated herein by reference.

Square brackets in the formulas indicate that at least one of the elements within the brackets is present in the phosphor material, and any combination of two or more thereof may be present, as limited by the stoichiometry of the composition. For example, the formula [Ca,Sr,Ba]₃MgSi₂O₈:Eu²⁺,Mn²⁺ encompasses at least one of Ca, Sr or Ba or any combination of two or more of Ca, Sr or Ba. Examples include Ca₃MgSi₂O₈:Eu²⁺,Mn²⁺; Sr₃MgSi₂O₈:Eu²⁺,Mn²⁺; or Ba₃MgSi₂O₈:Eu²⁺,Mn²⁺. Formula with an activator after a colon “:” indicates that the phosphor composition is doped with the activator. Formula showing more than one activator separated by a “,“after a colon”:” indicates that the phosphor composition is doped with either activator or both activators. For example, the formula [Ca,Sr,Ba]₃MgSi₂Os:Eu²⁺,Mn²⁺ encompasses [Ca,Sr,Ba]₃MgSi₂O₈:Eu²⁺, [Ca,Sr,Ba]₃MgSi₂O₈:Mn²⁺ or [Ca,Sr,Ba]₃MgSi₂O₈:Eu²⁺ and Mn²⁺.

The uranium-based phosphor materials of the present disclosure provide a narrow band green emission and, in some cases, provide good energy transfer with good quantum efficiency. These phosphors can be used for a variety of LED based lighting and display applications. The pure green emission on its own can be used in displays to provide high gamut and to fill in the teal gap for human centric lighting. The efficient energy transfer of these materials to ions like Eu³⁺, Pr³⁺ and Sm³⁺ makes them spectrally better-suited to provide high efficacy lighting (lumens/watt) and can be used in phosphor blends to produce lighting apparatus with high efficacy and CRI values. The uranium-based phosphors are spectrally blue-shifted compared with other commercially available phosphors. This color shift provides a greater overlap with the human eye sensitivity and a higher lumens/watt measurement.

The activators of Eu³⁺, Pr³⁺ and Sm³⁺ also provide emission spectra for specialty high CRI lighting and lighting for plant growth. In some embodiments, the uranium-based phosphors sensitized with europium, praseodymium and samarium activator ions provide a narrow emission spectra in the red/far-red region (about 600 nm-800 nm), which is desirable for horticultural lighting. In some embodiments, horticulture lighting includes LED-based white lighting with a composition including a uranium-based phosphor, which can be used for indoor lighting and outdoor lighting for plant growth. In other embodiments, the horticulture lighting includes phosphor packages including uranium-based phosphors. In some embodiments, the horticulture lighting may be solar-based.

The phosphors doped with Eu³⁺, Sm³⁺ and Pr³⁺ also have tunable emission spectra based on the amount of activator ion added to the host compositions. This spectral tuning leads to the ability to make a phosphor for display applications that can have both a green and red emission peak to produce wide color gamut displays; this is especially useful for film-based displays where the Mura of the film is important in the final application. Instead of having to ensure that multiple phosphors are evenly dispersed in a film, there would only be the need to have one phosphor evenly dispersed because it supplies both green and red emission.

The inventors discovered that uranium-based phosphor materials of the present disclosure can produce an energy transfer with good quantum efficiency when the uranyl ion is used as a sensitizer to the activator ions, Europium, Praseodymium or Samarium. This was surprising, as others have tried to sensitize Europium emission for use in LEDs for years, but all previous attempts have been unsuccessful with very minimal energy transfer, low absorption and or quantum efficiencies too low to be useful in the final applications.

The inventors discovered that specific luminescent materials, can be activated by uranium-based phosphors to produce an efficient energy transfer. In other embodiments, the inventors unexpectedly discovered that co-doping specific activator ions, such as Eu³⁺, Pr³⁺ and Sm³⁺, with an alkali counter ion can increase the efficient energy transfer of the uranium-based phosphor materials.

The luminescence of Europium, Praseodymium and Samarium show that the emission can be used for lighting applications to obtain general lighting with high efficacy (Lms/W), which is not obtainable with commercial market phosphor solutions. The pure uranium emission spectra of the phosphor materials can absorb at 450 nm and fill in the teal gap, which leads to a full spectra in general lighting and higher CRI values. The pure uranium spectra can be used for display backlight applications to provide a high gamut.

In some embodiments, the inventors surprisingly discovered that the phosphor materials showed full energy transfer to the Europium, Praseodymium and Samarium activator ions. The phosphor materials have very high absorption and, in some embodiments, the full conversion red emission phosphor materials can be used to prepare thin phosphor films needed for smaller sized LEDs, such as micro-LEDs and mini-LEDs. The phosphor materials produce a high gamut and can be easily processed for making films for smaller LEDs or deposited on micro LEDs to achieve a full red conversion.

In one embodiment, uranium-based phosphor materials include phosphors including a uranyl (UO₂) group and having formulas I, II, III, N or V:

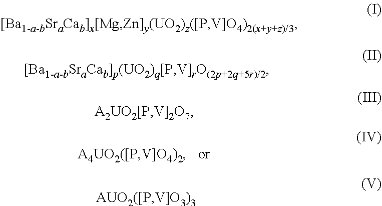

where 0≤a≤1, 0≤b≤1, 0.75≤x≤1.25, 0.75≤y≤1.25, 0.75≤z≤1.25; 2.5≤p≤3.5, 1.75≤q≤2.25, 3.5≤r≤4.5 and A is Li, Na, K, Rb, Cs, or a combination thereof.

In some embodiments, the uranium-based phosphors are doped with an activator ion. In some embodiments, the activator ion includes Pr³⁺, Sm³⁺, or mixtures thereof. In some embodiments, the activator ion is selected from Eu³⁺, Pr³⁺, Sm³⁺, and mixtures thereof. In some embodiments, the uranium-based phosphor is doped with a counter ion. In some embodiments, the counter ion is one or more alkali metal ions. In other embodiments, the counter ion is selected from Li⁺, K⁺, Na⁺, Rb⁺ or Cs⁺ and mixtures thereof.

In one aspect, an activated uranium-based phosphor is provided. The uranium-based phosphor material is selected from:
(i) a phosphor having formula I or II:

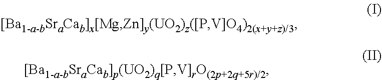

where the phosphor having formula I or II is doped with an activator ion including Pr³⁺, Sm³⁺, or mixtures thereof, where 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5;
(ii) a phosphor having formula I or II, where the phosphor having formula I or II is doped with an activator ion selected from Eu³⁺, Pr³⁺, Sm³⁺, and mixtures thereof; and a counter ion comprising one or more alkali metal ions; and
(iii) a phosphor having formula III:

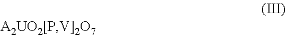

where the phosphor having formula III is doped with an activator ion selected from: Eu³⁺, Pr³⁺, Sm³⁺, and mixtures thereof, where A is Li, Na, K, Rb, Cs, or a combination thereof.

The uranium-based phosphor material may be co-doped with uranium ions and activator ions. The lanthanide activator ions, particularly Eu³⁺, Pr³⁺ or Sm³⁺, have luminescent properties. Additional ions, such as Mn²⁺, Mn⁴⁺, Ce³⁺, Sn³⁺, Bi³⁺, Sb³⁺, Cr³⁺, Tb³⁺, Ti⁴⁺, In⁺, Tl⁺, Dy³⁺ and Pb²⁺, may be present. The inventors discovered that uranium-based phosphor material co-doped with lanthanide activator ions, such as Eu³⁺, pr³⁺ or Sm³⁺, showed an efficient energy transfer from the green pure uranium emission spectra. This was surprising as other ions in the lanthanide series did not exhibit an energy transfer or good quantum efficiency.

The inventors found that the uranium-based phosphor materials co-doped with activator ions, such as Eu³⁺, Pr³⁺ or Sm³⁺ were color tunable, that is the ratio of the green emission from the uranium to the emission color of the activator ion could be adjusted depending on the ratio of the activator ion. The color shift of the phosphors can be a large change in the color coordinate values (ccx and ccy values) or very small change in the color coordinate values, as desired. In some embodiments, the phosphor emission may be shifted so that is spectrally closer to the eye sensitivity range centered at 555 nm. These activator ions can be used in lighting applications to provide a higher intensity in human centric lighting and high efficacy (Lms/W) lighting that is not currently available in commercial market phosphor solutions.

In some embodiments, there is complete energy transfer to the activator ion fully quenching the uranium emission. For example, Europium emission is red and the inventors discovered that a Uranium-based phosphor material co-doped with a Europium activator ion could be adjusted from a pure green emission to a pure red emission depending on the doped amount of the Europium activator ion. In other embodiments, there is a partial quenching of the uranium emission. For example, a Uranium-based phosphor material co-doped with a Pr³⁺ or Sm³⁺ activator ion can adjust a pure green emission to an orange or orange-red emission depending on the doped amounts of the activator ions.

In some embodiments, the uranium-based phosphor materials may be used for high efficacy general lighting. In other embodiments, the uranium-based phosphor materials may be color-tuned to reduce hazardous blue light emission for use in eye-safe displays. In other embodiments, the uranium-based phosphor materials may be color-tuned to produce emission suitable for plant growth. In other embodiments, the uranium-based phosphor may be color tuned to produce a high gamut display with the green and red emission produced from a single phosphor.

The inventors surprisingly discovered that the energy transfer in uranium-based phosphors could be increased by co-doping the uranium-based phosphors with an activator ion and a counter ion and that the quantum efficiency of the phosphor could be improved by co-doping the uranium-based phosphors with an activator ion and a counter ion. The counter ion may be an alkali metal, such as Li⁺, K⁺, Na⁺, Rb⁺ or Cs⁺ and mixtures thereof. This was unexpected as the alkali metal ions did not enhance all lanthanide activator ions and uranium-based phosphors as shown in the Examples.

Energy transfer from the uranium ion to the activator ion can be measured by a change in color coordinate values, ccx and ccy (x and y on the 1931 ClE chromaticity diagram. As the phosphors are color tunable, the change in the color coordinate values may be very small and can range to very large differences, as needed. In some embodiments, the change in color coordinate values (ccx and ccy values) may be less than 10%. In other embodiments, the change in color coordinate values may be less than 5%. In other embodiments, the change in color coordinates is at least 10%. In some embodiments, the activated phosphor exhibits a ccx value change by at least 15% and a ccy value by at least 10%. In some embodiments, the activated phosphor exhibits a ccx value change of at least 25%. In another embodiment, the activated phosphor exhibits a ccx value change of at least 50%. In some embodiments, the activated phosphor exhibits a ccx value change from about 15% to about 200%. In another embodiment, the ccx value change is from about 25% to about 200% and in another embodiment, the ccx value change is from about 50% to about 200%. In some embodiments, the activated phosphor exhibits a ccy value change of at least 10%. In another embodiment, the activated phosphor exhibits a ccy value change from about 10% to about 50%.

Without wishing to be bound by theory, it is believed that the alkali metal interacts with the Europium, Praseodymium and Samarium activator ions and aids in distributing the activator ion into the host lattice by reduce the need for a charge compensating defect.

In some embodiments, the uranium-based phosphors have formula I: [Ba_{1-a-b}SrₐCa_{b}]ₓ[Mg,Zn]_{y}(UO₂)_{z}([P,V)]O₄)_{2(x+y+z)/3}, where 0≤a≤1, 0≤b≤1, 0.75≤x≤1.25, 0.75≤y≤1.25, 0.75≤z≤1.25. In some embodiments, one or more activator ions may be present, such as Eu³⁺, Pr³⁺ or Sm³⁺. In another embodiment, one or more counter ions may be present. The counter ions may be alkali metals. In some embodiments, the counter ions may be Li⁺, Na⁺, K⁺, Rb⁺, Cs⁺, or mixtures thereof. Particular examples include Ba[Mg, Zn]UO₂(PO₄)₂, and more particularly, BaMgUO₂(PO₄)₂ and BaZnUO₂(PO₄)₂.

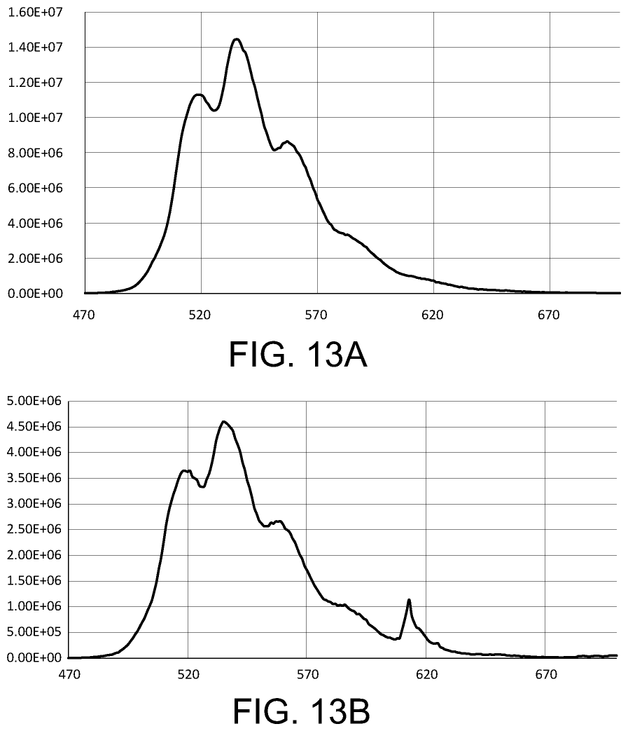

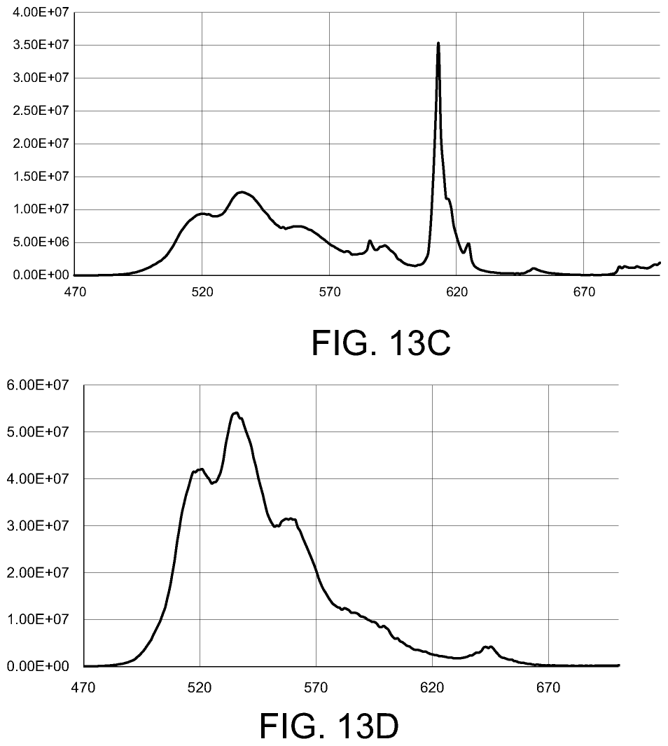

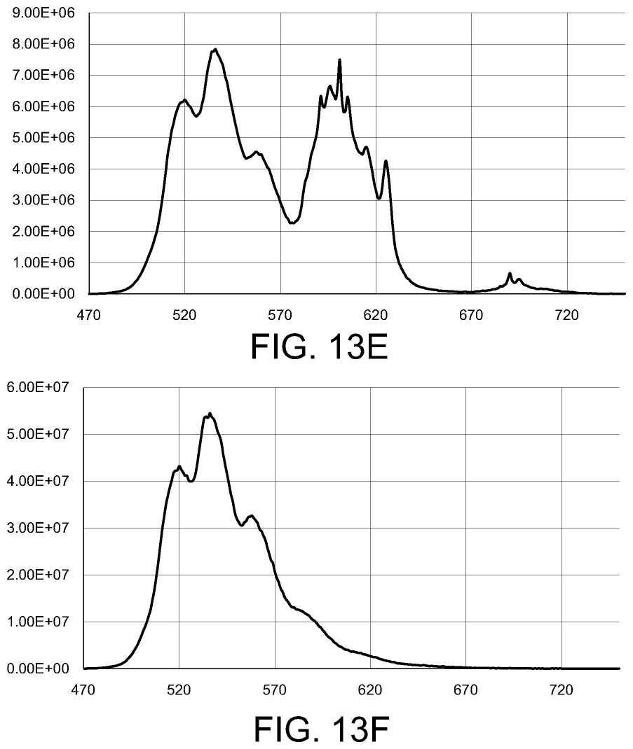

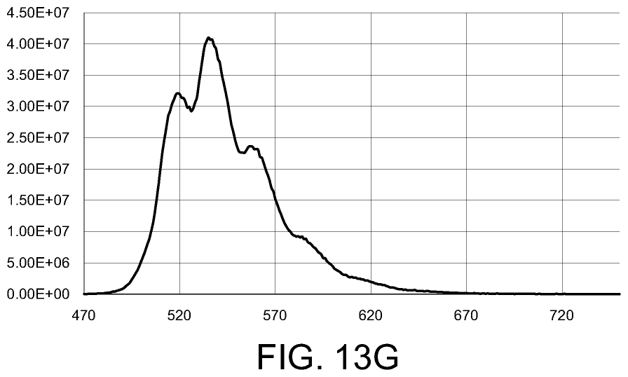

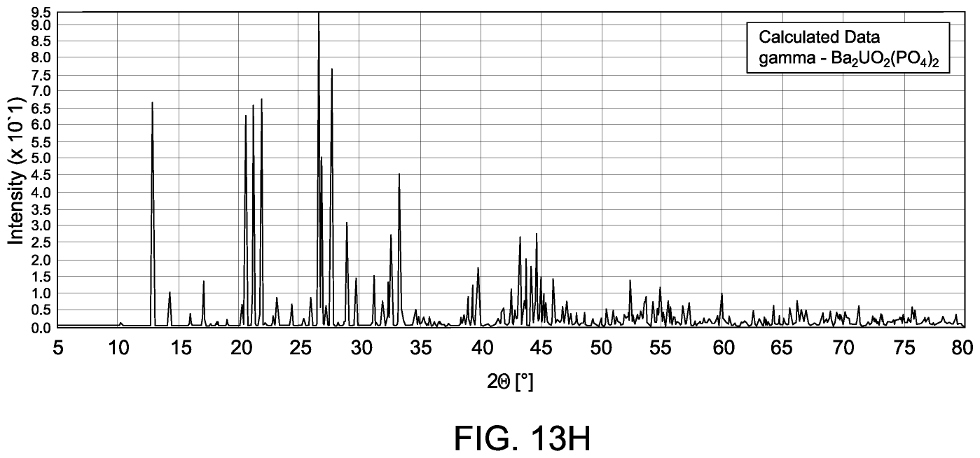

In some embodiments, the uranium-based phosphors have formula II: [Ba_{1-a-b}SrₐCa_{b}]ₚ(UO₂)_{q}[P,V]ᵣO_{(2p+2q+5r)/2}, where 0≤a≤1, 0≤b≤1, 2.5≤p≤3.5, 1.75≤q≤2.25, and 3.5≤r≤4.5. In some embodiments, the uranium-based phosphors have formula IIA: [Ba,Sr,Ca,]_{P}(UO₂)_{q}[P,V]ᵣO_{(2p+2q+5r)/2}. In some embodiments, one or more activator ions may be present for formula II or IIA, such as Eu³⁺, Pr³⁺, or Sm³⁺ and mixtures thereof. In another embodiment, one or more counter ions may be present for formula II or IIA. The counter ions may be alkali metals. In some embodiments, the counter ions may be one or more of: Li⁺, Na⁺, K⁺, Rb⁺ or Cs⁺. Particular examples include Ba₃(PO₄)₂(UO₂)₂P₂O₇, Ba₃(PO₄)₂(UO₂)₂V₂O₇ and gamma γ-Ba₂UO₂(PO₄)₂. In one embodiment, when the formula is [Ba], p is 3.5, q is 1.75, [P] and r is 3.5, the compound is Ba₂UO₂(PO₄)₂ and is in the gamma phase. In another embodiment, when the formula is Ba₂UO₂(PO₄)₂, the phosphor is in the gamma phase and is 7-Ba₂UO₂(PO₄)₂. Phosphor gamma phase Ba₂UO₂(PO₄)₂ described in PCT Publication No. WO 2021/211600, which is incorporated herein by reference. Gamma phase Ba₂UO₂(PO₄)₂ or γ-Ba₂UO₂(PO₄)₂ having an XRD powder pattern as shown in FIG. 13H.

In other embodiments the uranium-based phosphors have formula III: A₂UO₂[P,V]₂O₇, where A is Li, Na, K, Rb, Cs, or a combination thereof. In some embodiments, one or more activator ions may be present, such as Eu³⁺, Pr³⁺ or Sm³⁺ In some embodiments, A is Li⁺, Na⁺, K⁺, Rb⁺ or Cs⁺. Particular examples include A₂UO₂P₂O₇, and more particularly, Na₂UO₂P₂O₇ and K₂UO₂P₂O₇.

In one embodiment, the uranium-based phosphors may include Ba₃(PO₄)₂(UO₂) P₂O₇, BaZnUO₂(PO₄)₂, Na₂UO₂P₂O₇, K₂UO₂P₂O₇, BaMgUO₂(PO₄)₂, or γ-Ba₂UO₂(PO₄)₂.

The phosphors of the present disclosure may be characterized as uranium-doped or U-doped because the U⁶⁺ ions are part of the emitting species. The term ‘U-doped’ typically indicates that a relatively small number of uranium atoms is substituted in the host lattice. In many compounds the uranium is present in the host lattice as the uranyl ion (UO₂)²⁺. Because the uranyl ion is characterized by linear O-U-O bonding, there is typically an upper limit to the substitution that can be achieved, on the order of a few mole percent with respect to the site on which it is substituted. When substituting for a M²⁺ ion there are size constraints between the M²⁺ and the (UO₂) center that may create host lattice strain and/or compensating defects in the host lattice. As a result, concentration quenching of the U⁶⁺ emission usually occurs before full substitution is achieved. In contrast, the phosphors of the present disclosure contain the UO₂ species as part of the host lattice and comprise uranyl ions at a concentration as high as about 40 mole % relative to the total number of moles of M²⁺ cations present.

The phosphor material may be doped with activator ions, such as Eu³⁺, Pr³⁺ or Sm³⁺. A small number of the activator ions are incorporated into the host lattice of the compound. In another embodiment, the phosphor material may be doped with both activator ions and counter ions. A small number of activator ions, such as Eu³⁺, Pr³⁺ or Sm³⁺ and counter ions, such as alkali ions, are incorporated into the host lattice of the compound. The alkali ions may include Li⁺, Na⁺, K⁺, Rb⁺ or Cs⁺.

In some embodiments, the phosphor materials may include activator ions in an amount of from about 0.001 to about 10 mole percent. In another embodiment, the activator ions may be present in an amount of from about 0.01 mole percent to about 10 mole percent. In another embodiment, the activator ion may be present in an amount from about 0.1 mole percent to about 10 mole percent. In another embodiment, the activator ion may be present in an amount from about 0.5 to about 5 mole percent. In another embodiment, the activators may be present from about 1 to about 3 mole percent. In another embodiment, the activator ion may be present from about 0.01 mole percent to about 1 mole percent. In another embodiment, the activator ion may be present from about 0.05 mole percent to about 1 mole percent. In another embodiment, the activator ion may be present from about 0.1 mole percent to about 1 mole percent. In another embodiment, the activator ion may be present from about 0.5 mole percent to about 1 mole percent.

The uranium-based phosphor material may be co-doped with one or more counter ions. In one embodiment, the counter ion may be present in an amount from about 0.01 mole percent to about 10 mole percent. In one embodiment, the counter ion may be present in an amount of from about 0.1 to about 10 molar percent. In another embodiment, the counter ions may be present in an amount of from about 0.5 to about 5 mole percent. In another embodiment, the counter ion may be present from about 1 to about 3 mole percent. In another embodiment, the counter ion may be present from about 0.01 mole percent to about 1 mole percent. In another embodiment, the counter ion may be present from about 0.05 mole percent to about 1 mole percent. In another embodiment, the counter ion may be present from about 0.1 mole percent to about 1 mole percent. In another embodiment, the counter ion may be present from about 0.5 mole percent to about 1 mole percent.

In another aspect, a uranium-based phosphor is provided. The uranium-based phosphor having formula (III), (N) or (V):

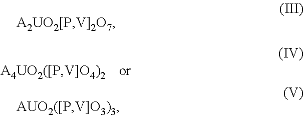

where A is Li, Na, K, Rb, Cs, or a combination thereof.

The uranium-based phosphors can absorb at 450 nm and emit in the green range. Phosphors having formulas III, IV and V emit a bright green color, which can provide high gamut to displays. For general lighting, the phosphors fill in the teal gap to provide a full spectra for human centric lighting with higher CRI values.

In some embodiments, the uranium-based phosphor have formula III: A₂UO₂[P,V]₂O₇, where A is Li, Na, K, Rb, Cs, or a combination thereof. Examples of phosphors include K₂UO₂P₂O₇, Na₂UO₂P₂O₇, Rb₂UO₂P₂O₇ and Cs₂UO₂P₂O₇.

In some embodiments, the uranium-based phosphors have formula N: A₄UO₂([P,V]O₄)₂, where A is Li, Na, K, Rb, Cs, or a combination thereof. Examples of phosphors include K₁UO₂(PO₄)₂ or K₁UO₂(VO₄)₂.

In some embodiments, the uranium-based phosphors have formula V: AUO₂([P,V]O₃)₃, where A is Li, Na, K, Rb, Cs, or a combination thereof. In one embodiment, the phosphor may be NaUO₂P₃O₉.

In one embodiment, the uranium-based phosphors may include K₂UO₂P₂O₇, Na₂UO₂P₂O₇, Rb₂UO₂P₂O₇, Cs₂UO₂P₂O₇, K₄UO₂(PO₄)₂ or NaUO₂P₃O₉. The phosphors emit bright green and can provide a large gamut for display applications.

The uranium-based phosphor materials of the present disclosure may be produced by firing a mixture of precursors under an oxidizing atmosphere. Non-limiting examples of suitable precursors include the appropriate metal oxides, hydroxides, alkoxides, carbonates, nitrates, aluminates, silicates, citrates, oxalates, carboxylates, tartarates, stearates, nitrites, peroxides, phosphates, pyrophosphates, alkali salts and combinations thereof. Suitable materials for use as precursors include, but are not limited to, BaCO₃, BaHPO₄, Ba₃(PO₄)₂, Ba₂P₂O₇, Ba₂Zn(PO₄)₂, BaZnP₂O₇, Ba(OH)₂, Ba(C₂O₄), Ba(C₂H₃O₂)₂, Ba₃(C₆H₅O₇)₂, Ba(NO₃)₂, CaCO₃, Cs₂CO₃, HUO₂PO₄-4H₂O, KH₂PO₄, K₂HPO₄, K₂CO₃, Li₂CO₃, Li₂HPO₄, LiH₂PO₄, Mg(C₂O₄), Mg(C₂H₃O₂)₂, Mg(C₆H₆O₇), MgCO₃, MgO, Mg(OH)₂, Mg₃(PO₄)₂, Mg₂P₂O₇, Mg₂Ba(PO₄)₂, MgHPO₄, Mg(NO₃)₂, NaH₂PO₄, Na₂HPO₄, Na₂CO₃, NH₄MgPO₄, (NH₄)₂HPO₄, NH₄VO₃, Rb₂CO₃, SrCO₃, Zn(C₂O₄), Zn(C₂H₃O₂)₂, Zn₃(C₆H₅O₇)₂, ZnCO₃, ZnO, Zn(OH)₂, Zn₃(PO₄)₂, Zn₂P₂O₇, Zn₂Ba(PO₄)₂, ZnHPO₄, Zn(NO₃)₂, NH₄ZnPO₄, UO₂, UO₂(NO₃)₂, (UO₂)₂P₂O₇, (UO₂)₃(PO₄)₂, NH₄(UO₂)PO₄, UO₂CO₃, UO₂(C₂H₃O₂)₂, UO₂(C₂O₄), H(UO₂)PO₄, UO₂(OH)₂, and ZnUO₂(C₂H₃O₂)₄, and various hydrates. For example, the exemplary phosphor BaZnUO₂(PO₄)₂ may be produced by mixing the appropriate amounts of BaCO₃, ZnO, and UO₂ with the appropriate amount of (NH₄)₂HPO₄ and then firing the mixture under an air atmosphere. The precursors may be in solid form or in solution. Non-limiting examples of solvents include water, ethanol, acetone, and isopropanol, and suitability depends chiefly on solubility of the precursors in the solvent. After firing, the phosphor may be milled to break up any agglomerates that may have formed during the firing procedure.

The mixture of starting materials for producing the phosphor includes, but is not limited to, activator precursor oxide compounds, such as Eu₂O₃, Sm₂O₃, or Pr₆O₁₁ and precursor phosphate compounds, such as EuPO₄, SmPO₄ or PrPO₄.

The mixture of starting materials for producing the phosphor may also include one or more low melting temperature flux materials, such as boric acid, borate compounds such as lithium tetraborate, alkali phosphates, and combinations thereof. Non-limiting examples include (NH₄)₂HPO₄ (DAP). Li₃PO₄, Na₃PO₄, NaBO₃—H₂O, Li₂B₄O₇, K₄P₂O₇, Na₄P₂O₇, H₃BO₃, and B₂O₃. The flux may lower the firing temperature and/or firing time for the phosphor. If a flux is used, it may be desirable to wash the final phosphor product with a suitable solvent to remove any residual soluble impurities that may have originated from the flux.

The firing of the samples is generally done in air, but since the uranium is in its highest oxidation state (U⁶⁺) it can also be fired in O₂ or other wet or dry oxidizing atmospheres, including at oxygen partial pressures above one atmosphere, at a temperature between about 300° C. and about 1300° C., particularly between about 500° C. and about 1200° C., for a time sufficient to convert the mixture to the phosphor. The firing time required may range from about one to twenty hours, depending on the amount of the mixture being fired, the extent of contact between the solid and the gas of the atmosphere, and the degree of mixing while the mixture is fired or heated. The mixture may rapidly be brought to and held at the final temperature, or the mixture may be heated to the final temperature at a lower rate such as from about 2° C./minute to about 200° C./minute.

The phosphors may be ground or milled, in a conventional manner, into smaller particle sizes, as desired. In some embodiments, the median particle size of the phosphor may range from about 1 to about 50 microns. In another embodiment, the median particle size may range from about 15 to about 35 microns. In another embodiment, the median particle size may be about 30 microns or less.

In another embodiment, the phosphors are in particulate form with particle size diameter in the range from about 0.1 μm to about 15 μm. In another embodiment, the particle size diameter is in the range from about 0.1 pm to about 10 μm. In another embodiment, the particle size distribution that is, D50 of less than 15 μm, particularly, D50 of less than 10 μm, particularly D50 of less than 5 μm, or D50 of less than 3 μm, or D50 of less than 2 μm, or D50 of less than 1 μm. In another embodiment, the particle size distribution D50 may be in a range from about 0.1 μm to about 5 μm. In another embodiment, the D50 particle size is in a range from about 0.1 μm to about 3 μm. In another embodiment, the D50 particle size is in a range from about 0.1 μm to about 1 μm. In another embodiment, the D50 particle size is in a range from about 1 μm to about 5 μm. D50 (also expressed as D₅₀) is defined as the median particle size for a volume distribution. D90 or D₉₀ is the particle size for a volume distribution that is greater than the particle size of 90% of the particles of the distribution. D10 or D₁₀ is the particle size for a volume distribution that is greater than the particle size of 10% of the particles of the distribution. Particle size of the phosphors may be conveniently measured by laser diffraction or optical microscopy methods, and commercially available software can generate the particle size distribution and span. Span is a measure of the width of the particle size distribution curve for a particulate material or powder, and is defined according to the equation:

$$Span = \frac{( {D}_{90} - {D}_{10} )}{{D}_{50}}$$

wherein D₉₀, D₁₀ and D₅₀ are defined above. For phosphor particles, span of the particle size distribution is not necessarily limited and may be ≤1.0 in some embodiments.

In another aspect, a composition is provided. The composition includes an activated uranium-based phosphor and a red emitting phosphor. The uranium-based phosphor is selected from:
(i) a phosphor having formula I or II:

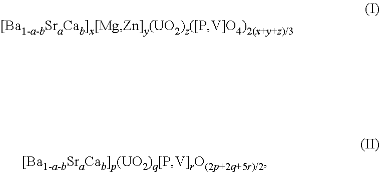

where the phosphor having formula I or II is doped with an activator ion including Pr³⁺, Sm³⁺, or mixtures thereof, where 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5;
(ii) a phosphor having formula I or II, where the phosphor having formula I or II is doped with an activator ion selected from Eu³⁺, Pr³⁺, Sm³⁺, and mixtures thereof; and a counter ion comprising one or more alkali metal ions; and
(iii) a phosphor having formula III:

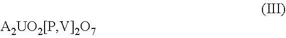

where the phosphor having formula III is doped with an activator selected from: Eu³⁺, Pr³⁺, Sm³⁺, and mixtures thereof, where A is Li, Na, K, Rb, Cs, or a combination thereof.

In another aspect, a composition is provided. The composition includes a uranium-based phosphor and a red emitting phosphor. The uranium-based phosphor having formula (III), (IV) or (V):

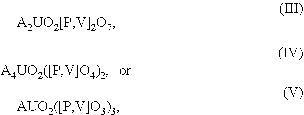

where A is Li, Na, K, Rb, Cs, or a combination thereof.

In one embodiment, the red emitting phosphor has formula VI:

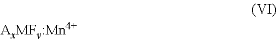

where A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the MF_{y} ion; and y is 5, 6 or 7.

The red emitting phosphor of formula VI is radiationally and/or optically coupled to the LED light source. The phosphors of formula I are described in US Patent Nos. 7,497,973, and U.S. Pat. No. 8,906,724, and related patents assigned to the General Electric Company. Examples of the red emitting phosphors of formula VI include, K₂(TiF₆):Mn⁴⁺, K₂(SnF₆):Mn⁴⁺, Cs₂(TiF₆):Mn⁴⁺, Rb₂(TiF₆):Mn⁴⁺, Cs₂(SiF₆):Mn⁴⁺, Rb₂(SiF₆):Mn⁴⁺, Na₂(SiF₆):Mn⁴⁺, Na₂(TiF₆):Mn⁴⁺, Na₂(ZrF₆):Mn⁴⁺, K₃(ZrF₇):Mn⁴⁺, K₃(BiF₇):Mn⁴⁺, K₃(YF₇):Mn⁴⁺, K₃(LaF₇):Mn⁴⁺, K₃(GdF₇):Mn⁴⁺, K₃(NbF₇):Mn⁴⁺ or K₃(TaF₇):Mn⁴⁺. In certain embodiments, the phosphor of formula VI is K₂SiF₆:Mn⁴⁺ (PFS).

In one embodiment, the red-emitting phosphor has a Mn loading or Mn % of at least 1 wt %. In another embodiment, the red-emitting phosphor has a Mn loading of at least 1.5 wt %. In another embodiment, the red-emitting phosphor has a Mn loading of at least 2 wt %. In another embodiment, the red-emitting phosphor has a Mn % of at least 3 wt %. In another embodiment the Mn % is greater than 3.0 wt %. In another embodiment, the content of Mn in the red-emitting phosphor is from about 1 wt % to about 4 wt %.

In one embodiment, the red-emitting phosphors based on complex fluoride materials activated by Mn phosphors may be at least partially coated with surface coatings to enhance stability of the phosphor particles and resist aggregation by modifying the surface of the particles and increase the zeta potential of the particles. In one embodiment, the surface coatings may be a metal fluoride, silica or organic coating. In one embodiment, the red-emitting phosphors based on complex fluoride materials activated by Mn⁴⁺ phosphors are at least partially coated with a metal fluoride, which increases positive Zeta potential and reduces agglomeration. In one embodiment, the metal fluoride coating includes MgF₂, CaF₂, SrF₂, BaF₂, AgF, ZnF₂, AlF₃ or a combination thereof. In another embodiment, the metal fluoride coating is in an amount from about 0.1 wt % to about 10 wt %. In another embodiment, the metal fluoride coating is present in an amount from about 0.1 wt % to about wt %. In another embodiment, the metal fluoride coating is present from about 0.3 wt % to about 3 wt %. Metal fluoride coated red-emitting phosphors based on complex fluoride materials activated by Mn are prepared as described in WO 2018/093832, US Publication No. 2018/0163126 and US Publication No. 2020/0369956. The entire contents of each of which are incorporated herein by reference.

The red-emitting phosphor having formula VI may be used in any particle size that is desired. In some embodiments, the median particle size of the phosphor may range from about 1 to about 50 microns. In another embodiment, the median particle size may range from about 15 to about 35 microns. In another embodiment, the median particle size may be about 30 microns or less.

In one embodiment, the red-emitting phosphor is in particulate form with particle size diameter in the range from about 0.1 μm to about 15 μm. In another embodiment, the particle size diameter is in the range from about 0.1 μm to about 10 μm. In another embodiment, the particle size distribution that is, D50 of less than 15 μm, particularly, D50 of less than 10 μm, particularly D50 of less than 5 μm, or D50 of less than 3 μm, or D50 of less than 2 μm, or D50 of less than 1 μm. In another embodiment, the particle size distribution D50 may be in a range from about 0.1 μm to about 5 μm. In another embodiment, the D50 particle size is in a range from about 0.1 μm to about 3 μm. In another embodiment, the D50 particle size is in a range from about 0.1 μm to about 1 μm. In another embodiment, the D50 particle size is in a range from about 1 μm to about 5 μm. D50 (also expressed as D₅₀) is defined as the median particle size for a volume distribution. D90 or D₉₀ is the particle size for a volume distribution that is greater than the particle size of 90% of the particles of the distribution. D10 or D₁₀ is the particle size for a volume distribution that is greater than the particle size of 10% of the particles of the distribution. Particle size of the phosphors may be conveniently measured by laser diffraction or optical microscopy methods, and commercially available software can generate the particle size distribution and span. Span is a measure of the width of the particle size distribution curve for a particulate material or powder, and is defined according to the equation:

$$Span = \frac{( {D}_{90} - {D}_{10} )}{{D}_{50}}$$

wherein D₉₀, D₁₀ and D₅₀ are defined above. For phosphor particles, span of the particle size distribution is not necessarily limited and may be ≤1.0 in some embodiments.

In another aspect, a composition is provided. The composition includes an activated uranium-based phosphor and at least one other luminescent material. The uranium-based phosphor is selected from:
(i) a phosphor having formula I or II:

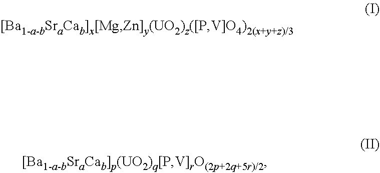

where the phosphor having formula I or II is doped with an activator ion including Pr³⁺, Sm³⁺, or mixtures thereof, where 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5;
(ii) a phosphor having formula I or II, where the phosphor having formula I or II is doped with an activator ion selected from Eu³⁺, Pr³⁺, Sm³⁺, and mixtures thereof; and a counter ion comprising one or more alkali metal ions; and
(iii) a phosphor having formula III:

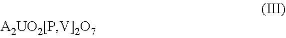

where the phosphor having formula III are doped with an activator ion selected from: Eu³⁺, Pr³⁺, Sm³⁺, and mixtures thereof, where A is Li, Na, K, Rb, Cs, or a combination thereof.

In another aspect, a composition is provided. The composition includes a uranium-based phosphor and at least one other luminescent material. The uranium-based phosphor having formula (III), (N) or (V):

a uranium-based phosphor having formula (III), (N) or (V):

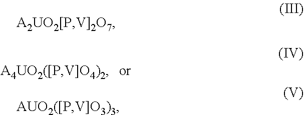

where A is Li, Na, K, Rb, Cs, or a combination thereof.

A phosphor composition according to the present disclosure may include, in addition to the uranium-based phosphor material, one or more other luminescent materials. Additional luminescent materials, such as blue, yellow, red, orange, or other color phosphors may be used in the phosphor composition to customize the white color of the resulting light and produce specific spectral power distributions.

Suitable phosphors for use in the phosphor composition, include, but are not limited to: ((Sr_{1-z}[Ca,Ba,Mg,Zn]_{z})_{1-(x+w)}[Li,Na,K,Rb]_{w}Ceₓ)₃(Al_{1-y}Si_{y})O_{4+y+3(x-w)}F_{1-y-3(x-w)}, O<x≤0.10, 0≤y≤0.5, 0≤z≤0.5, 0≤w≤x; [Ca,Ce]₃Sc₂Si₃O₁₂ (CaSiG); [Sr,Ca,Ba]₃Al₁₋ₓ SiₓO₄₊ₓF₁₋ₓ:Ce³⁺ (SASOF)); [Ba,Sr,Ca]₅(PO₄)₃[Cl,F,Br,OH]:Eu²⁺,Mn²⁺; [Ba,Sr,Ca]BPO₅:Eu²⁺,Mn²⁺; [Sr,Ca]₁₀(PO₄)₆*vB₂O₃:Eu²⁺ (wherein O<v≤1); Sr₂Si₃O₈*₂SfCl₂:Eu²⁺; [Ca,Sr,Ba]₃MgSi₂O₈:Eu²⁺,Mn²⁺; BaAl₈O₁₃:Eu²⁺; 2SrO*0.84P₂O₅*0.16B₂O₃:Eu²⁺; [Ba,Sr,Ca]MgAl₁₀O₁₇:Eu²⁺,Mn²⁺; [Ba,Sr,Ca]Al₂O₄:Eu²⁺; [Y,Gd,Lu,Sc,La]BO₃:Ce³⁺,Tb³⁺; ZnS:Cu⁺,Cl⁻; ZnS:Cu⁺,Al³⁺; ZnS:Ag⁺,Cl⁻; ZnS:Ag⁺,Al³⁺; [Ba,Sr,Ca]₂Si₁₋ₙO₄₋₂ₙ:Eu²⁺ (wherein 0≤n≤0.2); [Ba,Sr,Ca]₂[Mg,Zn]Si₂O₇:Eu²⁺; [Sr,Ca,Ba][Al,Ga,In]₂S₄:Eu²⁺; [Y,Gd,Tb,La,Sm,Pr,Lu]₃[Al,Ga]_{5$}O_{12-3/2a}:Ce³⁺ (wherein 0≤a≤0.5); [Ca,Sr]₈[Mg,Zn](SiO₄)₄Cl₂:Eu²⁺,Mn²⁺; Na₂Gd₂B₂O₇:Ce³⁺,n³⁺; [Sr,Ca,Ba,Mg,Zn]₂P₂O₇:Eu²⁺,Mn²⁺; [Gd,Y,Lu,La]₂O₃:Eu³⁺,Bi³⁺; [Gd,Y,Lu,La]₂O₂S:Eu³⁺,Bi³⁺; [Gd,Y,Lu,La]VO₄:Eu³⁺,Bi³⁺; [Ca,Sr,Mg]S:Eu²⁺,Ce³⁺; SrY₂S₄:Eu²⁺; CaLa₂S₄:Ce³⁺; [Ba,Sr,Ca]MgP₂O₇:Eu²⁺,Mn²⁺; [Y,Lu]₂WO₆:Eu³⁺,Mo⁶⁺; [Ba,Sr,Ca]_{b}Si_{g}Nₘ:Eu²⁺ (wherein 2b+4g=3m); Ca₃(SiO₄)Cl₂:Eu²⁺; [Lu,Sc,Y,Tb]₂₋ᵤ₋ᵥCeᵥCa₁₊ᵤLi_{w}Mg_{2-w}P_{w}[Si,Ge]_{3-w}O_{12-u/2} (where 0.5≤u≤1, 0≤v≤0.1, and 0≤w≤0.2); [Y,Lu,Gd]₂₋ₘ [Y,Lu,Gd]CaₘSi₄N₆₊ₘC₁₋ₘ:Ce³⁺, (wherein 0≤m≤0.5); [Lu,Ca,Li,Mg,Y], alpha-SiAlON doped with Eu²⁺ and/or Ce³⁺; Sr(LiAl₃N₄):Eu²⁺, [Ca,Sr,Ba]SiO₂N₂:Eu²⁺,Ce³⁺; beta-SiAlON:Eu²⁺; 3.5MgO*0.5MgF₂*GeO₂:Mn⁴⁺; Ca_{1-c-f}Ce_{c}Eu_{f}Al_{1+c}Si_{1-c}N₃, (where 0≤c≤0.2, 0≤f≤0.2); Ca₁₋ₕ₋ᵣCeₕEuᵣAl₁₋ₕ(Mg,Zn)ₕSiN₃, (where 0≤h≤0.2, 0≤r≤0.2); Ca_{1-2s-c}Ceₛ[Li,Na]ₛEuₜAlSiN₃, (where 0≤s≤0.2, 0≤t≤0.2, s+t>0); [Sr, Ca]AlSiN₃; and Eu²⁺,Ce³⁺, Li₂CaSiO₄:Eu²⁺.

In one embodiment, an additional luminescent material maybe a red emitting phosphor of formula VI as discussed previously,

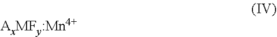

wherein A is Li, Na, K, Rb, Cs, or a combination thereof; M is Si, Ge, Sn, Ti,Zr, Al, Ga, In, Sc, Hf, Y, La, Nb, Ta, Bi, Gd, or a combination thereof; x is an absolute value of a charge of the MF_{y} ion; and y is 5, 6 or 7.

In particular embodiments, additional phosphors include: [Y,Gd,Lu,Tb]₃[Al,Ga]₅O₁₂:Ce³⁺, β-SiAlON:Eu²⁺, [Sr,Ca,Ba][Ga,Al]₂S₄:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, [Ba,Sr,Ca]₂Si₂O₄:Eu²⁺ and K₂SiF₆:Mn⁴⁺.

Other additional luminescent materials suitable for use in the phosphor composition may include electroluminescent polymers such as polyfluorenes, preferably poly(9,9-dioctyl fluorene) and copolymers thereof, such as poly(9,9′-dioctylfluorene-co-bis-N,N′-(4-butylphenyl)diphenylamine) (F8-TFB); poly(vinylcarbazole) and polyphenylenevinylene and their derivatives. In addition, the light emitting layer may include a blue, yellow, orange, green or red phosphorescent dye or metal complex, a quantum dot material, or a combination thereof. Materials suitable for use as the phosphorescent dye include, but are not limited to, tris(1-phenylisoquinoline) iridium (III) (red dye), tris(2-phenylpyridine) iridium (green dye) and iridium (III) bis(2-(4,6-difluorephenyl)pyridinato-N,C2) (blue dye). Commercially available fluorescent and phosphorescent metal complexes from ADS (American Dyes Source, Inc.) may also be used. ADS green dyes include ADS060GE, ADS061 GE, ADS063GE, and ADS066GE, ADS078GE, and ADS090GE. ADS blue dyes include ADS064BE, ADS065BE, and ADS070BE. ADS red dyes include ADS067RE, ADS068RE, ADS069RE, ADS075RE, ADS076RE, ADS067RE, and ADS077RE.

Exemplary QD materials include, but are not limited to, group II-N compound semiconductors such as CdS, CdSe, CdS/ZnS, CdSe/ZnS or CdSe/CdS/ZnS, group II-VI, such as CdTe, ZnSe, ZnTe, ZnS, HgTe, HgS, HgSe, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, group III-V or group IV-VI compound semiconductors such as GaN, GaP, GaNP, GaNAs, GaPAs, GaAs, GaAlNP, GaAlNAs, GaAlPAs, GaInNP, GaInNAs, GaInPAs, AlN, AlNP, AlNAs, AlP, AlPAs, AlAs, InN, InNP, InP, InNAs, InPAs, InAS, InAlNP, InAlNAs, InAlPAs, PbS/ZnS or PbSe/ZnS, group IV, such as Si, Ge, SiC, and SiGe, chalcopyrite-type compounds, including, but not limited to, CulnS₂, CulnSe₂, CuGaS₂, CuGaSe₂, AglnS₂, AglnSe₂, AgGaS₂, AgGaSe₂ or perovskite QDs having a formula of ABX₃ where A is cesium, methylammonium or formamidinium, B is lead or tin and C is chloride, bromide or iodide.

In one embodiment, the perovskite quantum dot may be CsPbX₃, where X is Cl, Br, I or a combination thereof. The mean size of the QD materials may range from about 2 nm to about 20 nm. The surface of QD particles may be further modified with ligands such as amine ligands, phosphine ligands, phosphatide and polyvinylpyridine. In one aspect, the red phosphor may be a quantum dot material.

All of the semiconductor quantum dots may also have appropriate shells or coatings for passivation and/or environmental protection. The QD materials may be a core/shell QD, including a core, at least one shell coated on the core, and an outer coating including one or more ligands, preferably organic polymeric ligands. Exemplary materials for preparing core-shell QDs include, but are not limited to, Si, Ge, Sn, Se, Te, B, C (including diamond), P. Co, Au, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdSeZn, CdTe, HgS, HgSe, HgTe, BeS, BeSe, BeTe, MgS, MgSe, MnS, MnSe, GeS, GeSe, GeTe, SnS, SnSe, SnTe, PbO, PbS, PbSe, PbTe, CuF, CuCl, CuBr, Cu, Si₃N₄, Ge₃N₄, Al₂O₃, [Al, Ga, In]z[S, Se, Te]₃, and appropriate combinations of two or more such materials. Exemplary core-shell luminescent nanocrystals include, but are not limited to, CdSe/ZnS, CdSe/CdS, CdSe/CdS/ZnS, CdSeZn/CdS/ZnS, CdSeZn/ZnS, InP/ZnS, PbSe/PbS, PbSe/PbS, CdTe/CdS and CdTe/ZnS.

In one embodiment, the phosphor composition may include scattering particles. In one embodiment, the scattering particles have a particle size of at least 1 μm. In another embodiment, the scattering particles have a particle size from about 1 μm to about 10 μm. In another embodiment, the scattering particles may include titanium dioxide, aluminum oxide (Al₂O₃), zirconium oxide, indium tin oxide, cerium oxide, tantalum oxide, zinc oxide, magnesium fluoride (MgF₂), calcium fluoride (CaF₂), strontium fluoride (SrF₂), barium fluoride (BaF₂), silver fluoride (AgF), aluminum fluoride (AlF₃) or combinations thereof.

The ratio of each of the individual phosphors and other luminescent materials in the phosphor composition may vary depending on the characteristics of the desired light output. The relative proportions of the individual phosphors and other luminescent materials in the various phosphor compositions may be adjusted such that when their emissions are blended and employed in a device, for example a lighting apparatus, there is produced visible light of predetermined x and y values on the ClE chromaticity diagram.

In one embodiment, the phosphor composition may include a uranium-based phosphor having formula III, IV or V and a red phosphor having formula VI. In another embodiment, the composition includes a uranium-based phosphor, such as K₄UO₂(PO₄)₂, K₄UO₂(PO₄)₂ or NaUO₂P₃O₉.with K₂SiF₆:Mn⁴.

The phosphor composition may be in the form of an ink or slurry composition, which can be applied to a substrate, such as an LED light source or formed into a film. The ink composition may be blended with a binder or a solvent.

Examples of binders include, but are not limited to silicone polymers, polysiloxanes, ethyl cellulose, polystyrene, polyacrylate, polymethyl acrylate (PMA), polymethyl methacrylate (PMMA), polycarbonate, polyurethane, polyetherether ketone, polysulfone, polyphenylene sulfide, polyvinylpyrrolidone (PVP), polyethyleneimine (PEI), poly(l-naphthyl methacrylate), poly(vinyl phenyl sulfide) (PVPS), polyvinyl alcohol (PVA), polyvinyl butyral (PVB), poly(N-vinylphthalimide), polyvinylidene fluoride (PDVF), poly(vinylidene fluoride-co-hexafluoropropylene) (PVDF-HFP), silicone materials and UV-curable materials, such as epoxy resins, acrylic resins, acrylate resins and urethane-based materials.

Examples of solvents include, but are not limited to, water, ethanol, acetone and isopropanol.

In another aspect, devices including an LED light source radiationally and/or optically coupled to an activated uranium-based phosphor is provided. The uranium-based phosphor material is selected from:
(i) a phosphor having formula I or II:

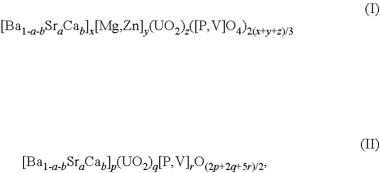

where the phosphor having formula I or II is doped with an activator ion including Pr³⁺, Sm³⁺, or mixtures thereof, where 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5;
(ii) a phosphor having formula I or II, where the phosphor having formula I or II is doped with an activator ion selected from Eu³⁺, Pr³⁺, Sm³⁺, and mixtures thereof; and a counter ion comprising one or more alkali metal ions; and
(iii) a phosphors having formula III:

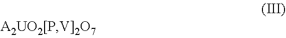

where the phosphor having formula III is doped with an activator ion selected from: Eu³⁺, Pr³⁺, Sm³⁺, and mixtures thereof, where A is Li, Na, K, Rb, Cs, or a combination thereof.

In yet another aspect, devices including an LED light source radiationally and/or optically coupled to a uranium-based phosphor is provided. The uranium-based phosphor having formula (III), (N) or (V):

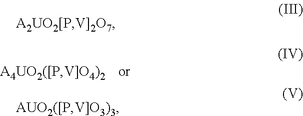

where A is Li, Na, K, Rb, Cs, or a combination thereof.

In one embodiment, a lighting apparatus includes the device. In another embodiment, a backlight apparatus includes the device. In one embodiment, the device and lighting apparatus are for horticulture lighting. In one embodiment, a phosphor package is for horticulture lighting.

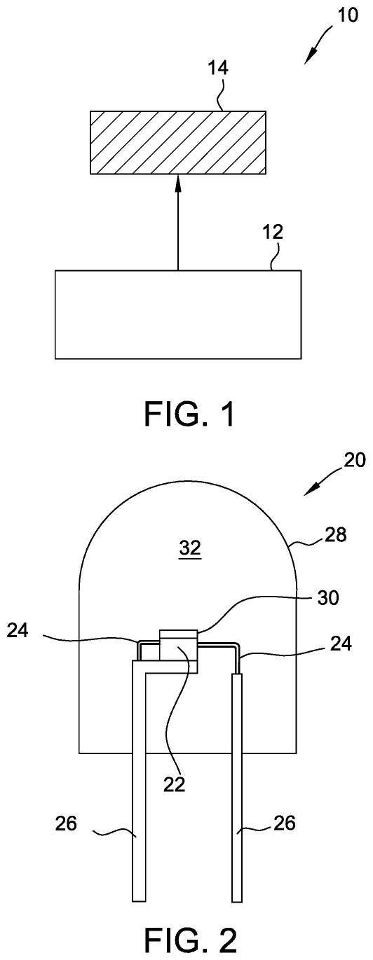

Devices according to the present disclosure include an LED light source radiationally connected and/or optically coupled to one or more of the uranium-based phosphor materials, such as uranium-based phosphors having formulas I, II, III, N or V. In some embodiments, the uranium-based phosphors may be activated uranium-based phosphors having formulas I, II or III. FIG. 1 shows a device 10, according to one embodiment of the present disclosure. The device 10 includes a LED light source 12 and a phosphor composition 14 including a uranium-based phosphor material of the present disclosure. The LED light source 12 may be a UV or blue emitting LED. In some embodiments, the LED light source 12 produces blue light in a wavelength range from about 380 nm to about 460 nm. In the device 10, the phosphor composition 14 including the uranium-based phosphor material as described herein, is radiationally coupled and/or optically coupled to the LED light source 12. Radiationally connected or coupled or optically coupled means that radiation from the LED light source 12 is able to excite the phosphor composition 14, and the phosphor composition 14 is able to emit light in response to the excitation by the radiation. The phosphor composition 14 may be disposed on a part or portion of the LED light source 12 or located remotely at a distance from the LED light source 12. In some embodiments, the device may be a backlight unit for display applications.

The general discussion of the example LED light source discussed herein is directed toward an inorganic LED based light source. The most popular white LEDs are based on blue or UV emitting GaInN chips. In addition, to inorganic LED light sources, the term LED light source is meant to encompass all LED light sources such as semiconductor laser diodes (LD), organic light emitting diodes (OLED) or a hybrid of LED and LD. The LED light source may be a miniLED or microLED, which can be used in self-emissive displays. Further, it should be understood that the LED light source may be replaced, supplemented or augmented by another radiation source unless otherwise noted and that any reference to semiconductor, semiconductor LED, or LED chip is merely representative of any appropriate radiation source, including, but not limited to, LDs and OLEDs.

The phosphor composition 14 may be present in any form such as powder, glass, or composite e.g., phosphor-polymer composite or phosphor-glass composite. Further, the phosphor composition 14 may be used as a layer, sheet, film, strip, dispersed particulates, or a combination thereof. In some embodiments, the phosphor composition 14 includes the uranium-based phosphor material in glass form. In some of these embodiments, the device 10 may include the phosphor composition 14 in form of a phosphor wheel (not shown). The phosphor wheel may include the uranium-based phosphor material embedded in a glass. A phosphor wheel and related devices are described in WO 2017/196779.

The uranium-based phosphor material is optically coupled or radiationally connected to an LED light source. In one embodiment, a white light blend may be obtained by blending the uranium-based phosphor material and an additional luminescent material with an LED light source, such as a blue or UV LED. The pure uranium emission spectra of the phosphor materials have a narrow band emission in the green range close to the center of the eye sensitivity range. The phosphor material can absorb at 450 nm and can fill in the teal gap range of human centric lighting, which leads to a full spectra for general lighting and provide high CRI values. The pure uranium spectra can be used for display backlight applications to provide a high gamut display.

In one embodiment, the uranium-based phosphor material is doped with an activator ion providing an orange or red emission. In one embodiment, the uranium-based phosphor is doped with a Europium activator ion having a red emission that is spectrally close to the eye sensitivity range, which appears brighter to human vision. In one embodiment, a Europium-doped uranium-based phosphor is combined with a yellow-green or green emitting phosphor, such as an yttrium-aluminum garnet (YAG) phosphor, and a blue-emitting or UV-emitting LED to prepare a white blend with a high efficacy (lumens/Watt) value. In another embodiment, a composition includes an activated uranium-based phosphor and a red phosphor having formula VI.

In some embodiments, the uranium-based phosphor may be used for plant lighting. In one embodiment, a plant lighting blend or composition includes a uranium-based phosphor doped with Sm³⁺ and having a peak emission around 650 nm. In another embodiment, a plant lighting composition includes a uranium-based phosphor doped with pi³⁺.

FIG. 2 illustrates a lighting apparatus or lamp 20, in accordance with some embodiments. In one embodiment, the lighting apparatus 20 may be a backlight apparatus. The lighting apparatus 20 includes an LED chip 22 and leads 24 electrically attached to the LED chip 22. The leads 24 may comprise thin wires supported by a thicker lead frame(s) 26 or the leads 24 may comprise self-supported electrodes and the lead frame may be omitted. The leads 24 provide current to LED chip 22 and thus cause it to emit radiation.

A layer 30 of a phosphor composition including the uranium-based phosphor material is disposed on a surface of the LED chip 22. The phosphor layer 30 may be disposed by any appropriate method, for example, using a slurry or ink composition prepared by mixing the phosphor composition and a binder material or solvent (as discussed above). In one such method, a silicone slurry in which the phosphor composition particles are randomly suspended or uniformly dispersed is placed around the LED chip 22. This method is merely exemplary of possible positions of the phosphor layer 30 and LED chip 22. The phosphor layer 30 may be coated over or directly on the light emitting surface of the LED chip 22 by coating and drying the slurry over the LED chip 22. The light emitted by the LED chip 22 mixes with the light emitted by the phosphor composition to produce desired emission.

With continued reference to FIG. 2, the LED chip 22 may be encapsulated within an envelope 28. The envelope 28 may be formed of, for example glass or plastic. The LED chip 22 may be enclosed by an encapsulant material 32. The encapsulant material 32 may be a low temperature glass, or a polymer or resin known in the art, for example, an epoxy, silicone, epoxy-silicone, acrylate or a combination thereof. In an alternative embodiment, the lighting apparatus 20 may only include the encapsulant material 32 without the envelope 28. Both the envelope 28 and the encapsulant material 32 should be transparent to allow light to be transmitted through those elements.

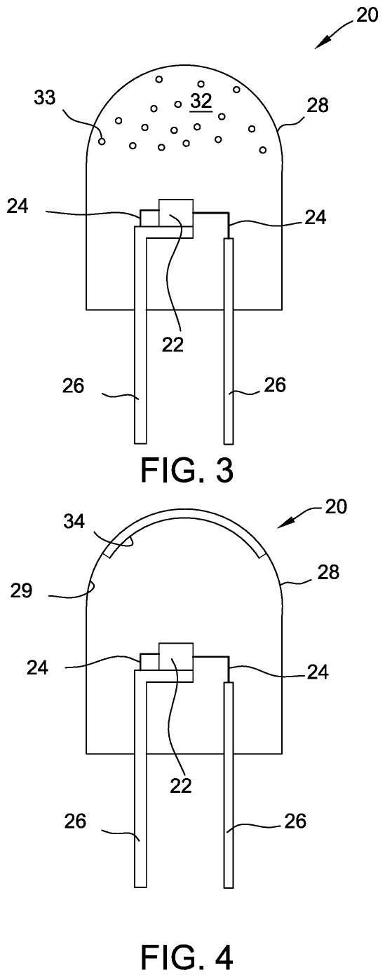

In some embodiments as illustrated in FIG. 3, a phosphor composition 33 uranium-based phosphor material is interspersed within the encapsulant material 32, instead of being formed directly on the LED chip 22, as shown in FIG. 2. The phosphor composition 33 may be interspersed within a portion of the encapsulant material 32 or throughout the entire volume of the encapsulant material 32. Blue light or UV light emitted by the LED chip 22 mixes with the light emitted by phosphor composition 33, and the mixed light transmits out from the lighting apparatus 20.

In yet another embodiment, a layer 34 of the phosphor composition including the uranium-based phosphor material, is coated onto a surface of the envelope 28, instead of being formed over the LED chip 22, as illustrated in FIG. 4. As shown, the phosphor layer 34 is coated on an inside surface 29 of the envelope 28, although the phosphor layer 34 may be coated on an outside surface of the envelope 28, if desired. The phosphor layer 34 may be coated on the entire surface of the envelope 28 or only a top portion of the inside surface 29 of the envelope 28. The UV/blue light emitted by the LED chip 22 mixes with the light emitted by the phosphor layer 34, and the mixed light transmits out. Of course, the phosphor composition may be located in any two or all three locations (as shown in FIGS. 2-4) or in any other suitable location, such as separately from the envelope 28, remote or integrated into the LED chip 22. In one embodiment, the phosphor layer 34 may be a film and located remotely from the LED chip 22. In another embodiment, the phosphor layer 34 may be a film and disposed on the LED chip 22. In some embodiments, the phosphor layer 34 may be applied to the LED chip 22 as an ink composition. In some embodiments, the phosphor layer 34 may be applied to the LED chip 22 as an ink composition and dried to form a film on the LED chip 22. In some embodiments, the phosphor composition may be a single layer or multi-layered. In some embodiments, the film is a multi-layered structure where each layer of the multi-layered structure includes at least one phosphor or quantum dot material. In another embodiment, a device structure includes a layer of a phosphor composition on an LED chip and a remote layer including a quantum dot material. In another embodiment, a device structure includes a layer of a phosphor composition on an LED chip and a remote layer including a quantum dot material and phosphor material. In another embodiment, a device structure includes a layer of a phosphor composition on an LED chip and a film including quantum dot material located remotely from the LED chip. In another embodiment, a device structure includes a layer of a phosphor composition on an LED chip and a film including quantum dot material and phosphor material located remotely from the LED chip.

In any of the above structures, the lighting apparatus 20 (FIGS. 2-4) may also include a plurality of scattering particles (not shown), which are embedded in the encapsulant material 32. The scattering particles may comprise, for example, alumina, silica, zirconia, or titania. The scattering particles effectively scatter the directional light emitted from the LED chip 22, preferably with a negligible amount of absorption.

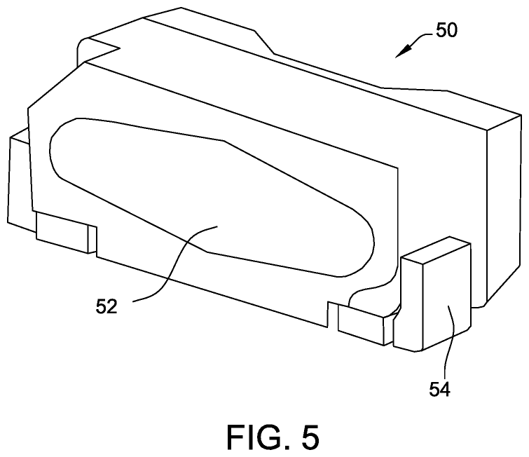

In one embodiment, the lighting apparatus 20 shown in FIG. 3 or FIG. 4 may be a backlight apparatus. In another embodiment, the backlight apparatus comprises a backlight unit 10. Some embodiments include a surface mounted device (SMD) type light emitting diode 50, e.g. as illustrated in FIG. 5, for backlight applications. This SMD is a “side-emitting type” and has a light-emitting window 52 on a protruding portion of a light guiding member 54. An SMD package may comprise an LED chip as defined above, and a phosphor composition including the green-emitting phosphor as described herein. In another embodiment, the device may be a direct lit display.

By use of the phosphor compositions described herein, devices can be provided producing white light for display applications, for example, LCD backlight units, having high color gamut and high luminosity. Alternately, devices can be provided producing white light for general illumination having high luminosity and high CRI values for a wide range of color temperatures of interest (2000 K to 10,000 K).

Devices of the present disclosure include lighting and display apparatuses for general illumination and display applications. Examples of display apparatuses include liquid crystal display (LCD) backlight units, televisions, computer monitors, vehicular displays, laptops, computer notebooks, mobile phones, smartphones, tablet computers and other handheld devices. Where the display is a backlight unit, the uranium-based phosphor materials may be incorporated in a film, sheet or strip that is radiationally coupled and/or optically coupled to the LED light source, as described in US Patent Application Publication No. 2017/0254943. Examples of other devices include chromatic lamps, plasma screens, xenon excitation lamps, UV excitation marking systems, automotive headlamps, home and theatre projectors, laser pumped devices, and point sensors. The list of these applications is meant to be merely exemplary and not exhaustive. In some embodiments, the displays may be eye-safe displays with reduced hazardous blue light emission.

In some embodiments, devices of the present disclosure include horticulture lighting. In one embodiment, horticulture lighting may include a device including an LED light source radiationally and/or optically coupled to a uranium-based phosphor having formula (I), (II), (III), (IV) or (V). In another embodiment, the device may include a red phosphor having formula (VI). In another embodiment, the device includes a uranium-based phosphor having formula (I), (II), (III), (N) or (V) and a red phosphor having formula (VI). In another embodiment, the horticulture lighting includes a device including an activated uranium-based phosphor having formula (I), (II) or (III), and a red phosphor having formula (VI), wherein the uranium-based phosphor is doped with an activator ion selected from the group consisting of Eu³⁺, Sm³⁺ and/or Pr³⁺. In another embodiment, a horticulture lighting includes a device including an activated uranium-based phosphor of (i), (ii) or (iii). In another embodiment, horticulture lighting includes a device having formula (I), (II) or (III), and a red phosphor having formula (VI), where the uranium-based phosphor is doped with Sm³⁺ and/or Pr³⁺.

In another embodiment, horticulture lighting may include a phosphor package including activated uranium-based phosphors of sections (i), (ii) or (iii). In another embodiment, the horticulture lighting includes a composition including a uranium-based phosphor of sections (i), (ii) or (iii) and a red phosphor having formula (VI). In some embodiments, the phosphor package is a film or a sheet including dispersed activated uranium-based phosphors. In other embodiments, the phosphor package includes activated uranium-based phosphors dispersed within a medium or substrate. In some embodiments, the medium or substrate is transparent and may be used for solar plant lighting.

In some embodiments, films including single phosphor materials may be disposed on small-size LEDs, such as micro-LEDs or mini-LEDs. In some embodiments, a film includes a red-emitting uranium-based phosphor material including a Europium activator ion. The uranium-based phosphor material strongly absorbs UV/blue emitting LED light and has shorter decay times. The uranium-based phosphor material is stable in water and can be easily ground or milled into small particle sizes for processing into films and maintain good quantum efficiency. Because the phosphor material has high absorption, minimal loading of the phosphor material can be used in the films, to create full conversion micro-LED displays or to be used in applications where the film thickness layer is crucial. In some embodiments, the uranium-based phosphor can emit both in the green and red, which is beneficial for preparing very thin single phosphor films having good Mura measurements. In some embodiments, the uranium-based phosphor material may be prepared into a film by ink jet printing, spin coating or slot die coating.

In other embodiments, the film includes phosphor particle sizes from about 0.1 to about 15 microns. In other embodiments, of no more than 5 microns. In another embodiment, the film includes phosphor particles sizes of from about 0.1 micron to about 5 microns. In another embodiment, the film includes particle sizes of from about 0.5 micron to about 5 microns. In another embodiment, the film includes particle sizes from about 0.1 micron to about 1 micron. In another embodiment, the film includes particle sizes from about 0.5 micron to about 1 micron. In another embodiment, the film includes particle sizes from about 1 micron to about 3 microns.

In some embodiments, the film may include scattering agents. In another embodiment, a brightness enhancement film, such as a double brightness enhancement film (DBEF) may be used in a lighting apparatus to enhance brightness to the viewer or plant, if used for horticulture lighting.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

### EXAMPLES

Quantum efficiency measurements of the phosphors in the Examples were performed on cured silicone tape. Phosphor particles were dispersed in a polyacrylate binder material or 2-part thermally curable polydimethylsiloxane elastomer (such as is sold as Sylgard® 184 from Dow Corning) by mixing. The dispersed phosphor particles were prepared at a concentration of 0.12 g of phosphor to 1.8 g of silicone to 0.5 g of phosphor per 1.5 g silicone. The mixture was applied to a silicone tape and cured. The quantum efficiencies (QE) of the phosphor particles were measured in these films. The QE measurements were reported in relation to the QE of potassium fluoride sulfide phosphors (PFS) or β-SiAlON.

### Example 1: Preparation of Na₂UO₂P₂O₇ Phosphor and Na₂UO₂P₂O₇ doped with 1% Activator Ions (Eu³⁺, Pr³⁺, Sm³⁺, Tb³⁺ and Dy³⁺)

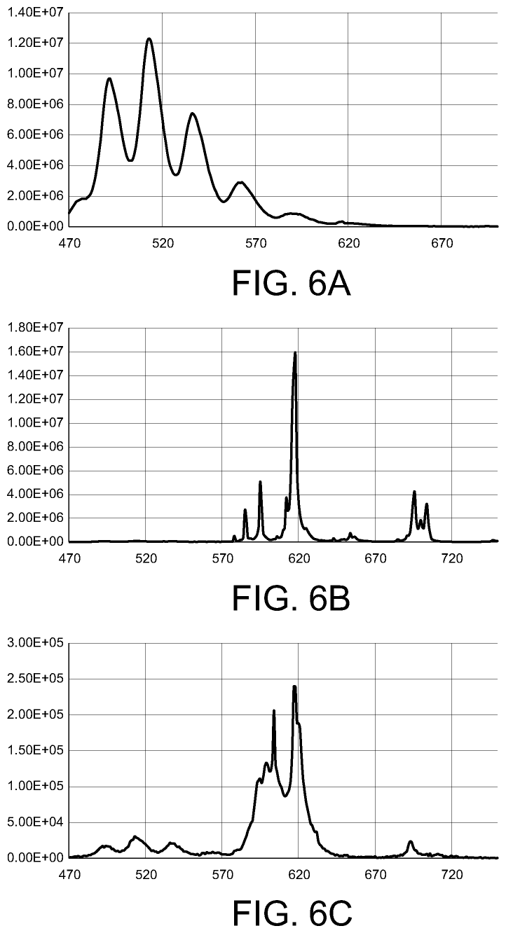

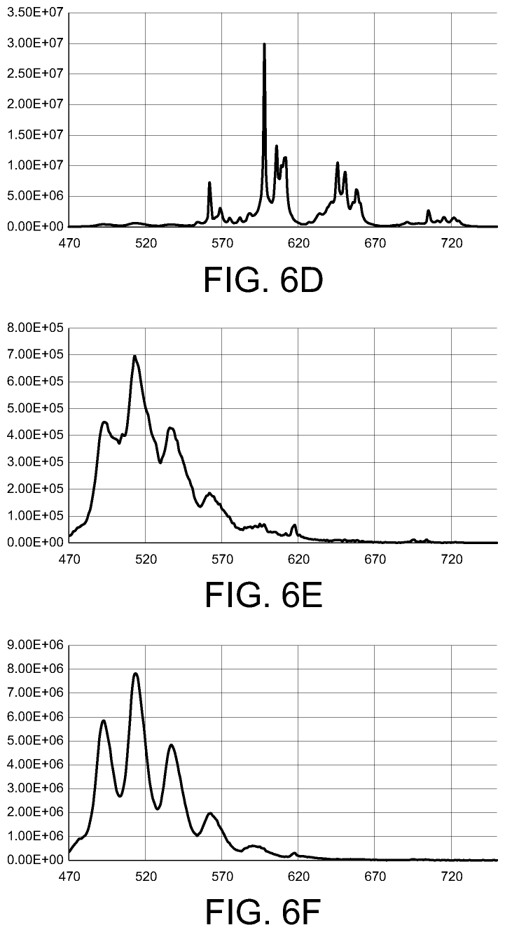

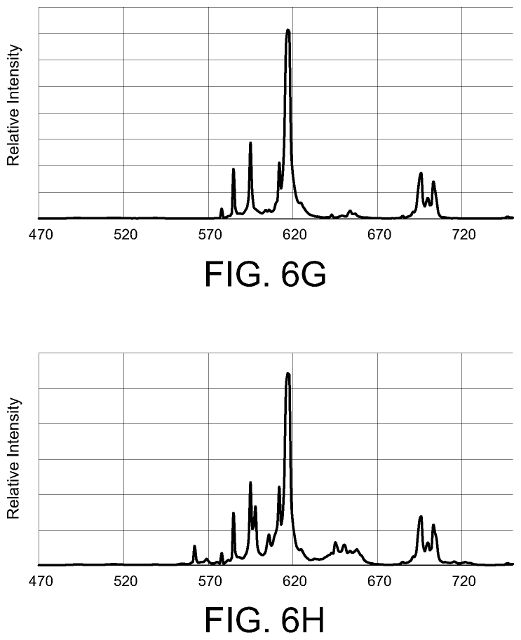

Na₂CO₃, HUO₂PO₄-4H₂O and NaH₂PO₄ were weighted out in a mol ratio of 0.5:1:1 and then put in a Nalgene bottle with zirconia media and ball milled for two hours. After the mixture was thoroughly blended the powder was transferred into an alumina crucible and fired at 500° C. for 5 hours, the mixture was then sieved through a 40-mesh screen and blended again in the same Nalgene bottle for two additional hours. The powder was put back into the alumina crucible and fired at 900° C. for 5 hours. After the final firing, a yellow body colored powder was obtained. The emission spectra of Na₂UO₂P₂O₇ is shown in FIG. 6A.

For preparing Na₂UO₂P₂O₇ doped with 1% molar amount of Eu³⁺, the same procedure was used, as above, except 0.005 Eu₂O₃ was added and the amount of Na₂CO₃ was adjusted to 0.495 in the blend. The emission spectra of Na₂UO₂P₂O₇ doped with Eu³⁺ is shown in FIG. 6B.

Na₂UO₂P₂O₇ doped with 1% molar amount of Pr³⁺ was prepared as for Na₂UO₂P₂O₇ doped with 1% molar amount of Eu³⁺ except that Pr₆O₁₁ was substituted for Eu₂O₃. The emission spectra of Na₂UO₂P₂O₇ doped with Pr³⁺ is shown in FIG. 6C.

Na₂UO₂P₂O₇ doped with 1% molar amount of Sm³⁺ was prepared as for Na₂UO₂P₂O₇ doped with 1% molar amount of Eu³⁺ except that Sm₂O₃ was substituted for Eu₂O₃. The emission spectra of Na₂UO₂P₂O₇ doped with Sm³⁺ is shown in FIG. 6D.

Na₂UO₂P₂O₇ doped with 1% molar amount of Tb³⁺ was prepared as for Na₂UO₂P₂O₇ doped with 1% molar amount of Eu³⁺ except that Tb₄O₇ was substituted for Eu₂O₃. The emission spectra of Na₂UO₂P₂O₇ doped with Tb³⁺ is shown in FIG. 6E.

Na₂UO₂P₂O₇ doped with 1% molar amount of Dy³⁺ was prepared as for Na₂UO₂P₂O₇ doped with 1% molar amount of Eu³⁺ except that Dy₂O₃ was substituted for Eu₂O₃. The emission spectra of Na₂UO₂P₂O₇ doped with Dy³⁺ is shown in FIG. 6F.

For preparing Na₂UO₂P₂O₇ doped with 1% Eu³⁺ and 1% Pr³⁺, Na₂HPO₄, HUO₂PO₄-4H₂O, Eu₂O₃, (NH₄)₂HPO₄ and Pr₆O₁₁ were weighted out in a mol ratio of 0.99:1:0.005:0.025:0.00167 and then put in a Nalgene bottle with zirconia media and ball milled for two hours. After the mixture was thoroughly blended the powder was transferred into an alumina crucible and fired at 500° C. for 5 hours, the mixture was then sieved through a 40-mesh screen and blended again in the same Nalgene bottle for two additional hours. The powder was put back into the alumina crucible and fired at 900° C. for 5 hours. After the final firing, a yellow body colored powder was obtained. The emission spectra of Na₂UO₂P₂O₇:Eu³⁺:Pr³⁺ is shown in FIG. 6G and results are shown in table 1.

For preparing Na₂UO₂P₂O₇ doped with 1% molar amount of Eu³⁺ and Sm³⁺ the same procedure was used as above, except the 0.00167 Pr₆O₁₁ was switched out with 0.005 Sm₂O₃. The emission spectra of Na₂UO₂P₂O₇:Eu³⁺,Sm³⁺ is shown in FIG. 6H and results are shown in table 1.

Results are shown in Table 1.

TABLE 1

| | Activator Ion | QE (vs | | |
|---|---|---|---|---|
| Phosphor | (1 molar %) | PFS) | ccx | ccy |
| Na₂UO₂P₂O₇ | None | 0.562 | 0.2054 | 0.6689 |
| Na₂UO₂P₂O₇ | Eu³⁺ | 1.025 | 0.6448 | 0.3496 |
| Na₂UO₂P₂O₇ | Pr³⁺ | | 0.5763 | 0.3988 |
| Na₂UO₂P₂O₇ | Sm³⁺ | 0.803 | 0.5870 | 0.4022 |
| Na₂UO₂P₂O₇ | Tb³⁺ | | 0.2113 | 0.6326 |
| Na₂UO₂P₂O₇ | Dy³⁺ | 0.448 | 0.1946 | 0.6201 |
| Na₂UO₂P₂O₇ | 1% Eu³⁺, 1% | 0.471 | 0.6440 | 0.3511 |
| | Pr³⁺ | | | |
| Na₂UO₂P₂O₇ | 1% Eu³⁺, 1% | 0.915 | 0.6329 | 0.3632 |
| | Sm³⁺ | | | |

Energy transfer is demonstrated by a difference in color coordinates ccx and ccy on the ClE chromaticity diagram. Phosphor materials Na₂UO₂P₂O₇ doped with activator ions Eu³⁺, Pr³⁺ and Sm³⁺ show energy transfer from the uranium ion to the activator ions. For example, phosphor Na₂UO₂P₂O₇ has a ccx value of 0.2054 and a ccy value of 0.6689. Na₂UO₂P₂O₇ doped with 1 molar % of Eu³⁺ has a ccx value of 0.6448 and a ccy value of 0.3496. This shows a significant difference in color change on the ClE chromaticity diagram and that there has been energy transfer to the activator ion, Eu³⁺. The energy transfer is also demonstrated in FIG. 6B. The emission spectra in FIG. 6B shows a significant shift in wavelength emission compared with the emission spectra in FIG. 6A. Phosphor materials Na₂UO₂P₂O₇ doped with activator ions Tb³⁺ and Dy³⁺ do not show energy transfer from the uranium ion to the activator ions. The difference in the ccx and ccy values compared with phosphor Na₂UO₂P₂O₇ are minimal and there is little change in the emission spectra in FIGS. 6E and 6F compared with the emission spectra in FIG. 6A. This shows that not all activator ions in the lanthanide group will work with uranium-based phosphors.

Na₂UO₂P₂O₇ doped with activator ion Eu³⁺ shows a significant increase in Quantum Efficiency (QE). It is believed that this is the first showing of an efficient energy transfer from a uranium ion the to a Europium activator ion. FIG. 6B shows that there is complete energy transfer to the Eu³⁺ ion and that the uranium emission has been fully quenched.

Na₂UO₂P₂O₇ doped with activator ion Sm³⁺ shows an increase in quantum efficiency. Na₂UO₂P₂O₇ co-doped with activator ions Eu³⁺ and Sm³⁺ also shows an increase in quantum efficiency. Na₂UO₂P₂O₇ co-doped with activator ions Eu³⁺ and Pr³⁺ shows a color shift, but decreased quantum efficiency to Na₂UO₂P₂O₇. Examples below demonstrate how quantum efficiency can be increased in the phosphor samples.

### Example 2: Preparation of K₂UO₂P₂O₇ Phosphor and K₂UO₂P₂O₇ Co-doped

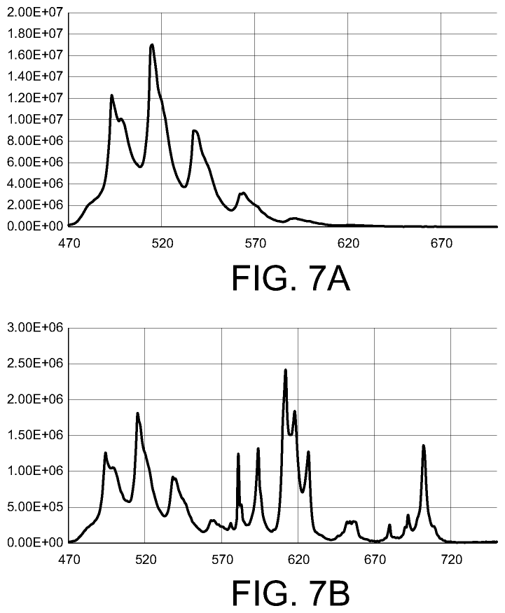

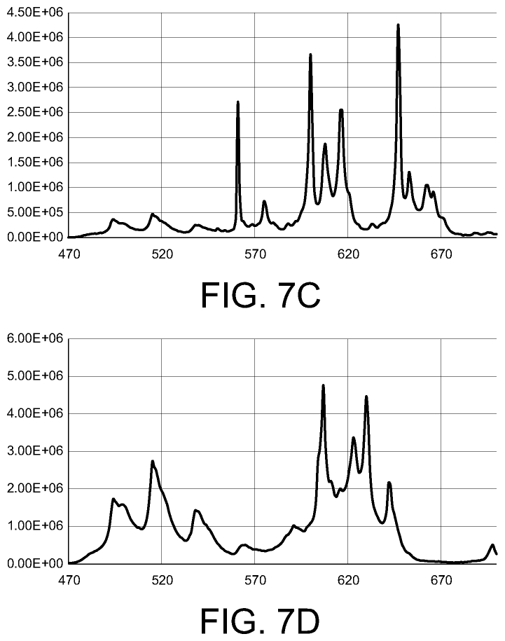

K₂CO₃, HUO₂PO₄-4H₂O and KH₂PO₄ were weighed out in a mol ratio of 0.5:1:1 and then put in a Nalgene bottle with zirconia media and ball milled for two hours. After the mixture was thoroughly blended the powder was transferred into an alumina crucible and fired at 500° C. for 5 hours, the mixture was then sieved through a 40-mesh screen and blended again in the same Nalgene bottle for two additional hours. The powder was put back into the alumina crucible and fired at 900° C. for 5 hours. After firing, a yellow body colored powder was obtained. The emission spectra of K₂UO₂P₂O₇ is shown in FIG. 7A.

For preparing K₂UO₂P₂O₇ doped with 1% molar amount of Eu³⁺, the same procedure was used, as above, except 0.005 Eu₂O₃ was added and the amount of K₂CO₃ was adjusted to 0.495 in the blend. The emission spectra of K₂UO₂P₂O₇ doped with Eu³⁺ is shown in FIG. 7B.

K₂UO₂P₂O₇ doped with 1% molar amount of Sm³⁺ was prepared as for K₂UO₂P₂O₇ doped with 1% molar amount of Eu³⁺ except that Sm₂O₃ was substituted for Eu₂O₃. The emission spectra of K₂UO₂P₂O₇ doped with Sm³⁺ is shown in FIG. 7C.

K₂UO₂P₂O₇ doped with 1% molar amount of Pr³⁺ was prepared as for K₂UO₂P₂O₇ doped with 1% molar amount of Eu except that Pr₆O₁₁ was substituted for Eu₂O₃. The emission spectra of K₂UO₂P₂O₇ doped with Pr³⁺ is shown in FIG. 7D.

Results are shown in Table 2.

TABLE 2

| | Activator Ion | QE (vs β- | | |
|---|---|---|---|---|
| Phosphor | (1 molar %) | SiAlON) | ccx | ccy |
| K₂UO₂P₂O₇ | None | 0.687 | 0.1783 | 0.6467 |
| K₂UO₂P₂O₇ | Eu³⁺ | 0.601 | 0.3951 | 0.5150 |
| K₂UO₂P₂O₇ | Sm³⁺ | 0.478 | 0.5405 | 0.4295 |
| K₂UO₂P₂O₇ | Pr³⁺ | 0.243 | 0.4608 | 0.4727 |

Energy transfer is demonstrated by the difference in color coordinates ccx and ccy. Phosphor material K₂UO₂P₂O₇ doped with activator ions Eu³⁺, Sm³⁺ and Pr³⁺ shows that there is energy transfer from the uranium ion to the activator ions. The quantum efficiency (QE) for K₂UO₂P₂O₇ doped with Eu³⁺ is maintained although there is a decrease in QE for K₂UO₂P₂O₇ doped with Sm³⁺ and Pr³⁺. Examples below demonstrate how quantum efficiency can be increased in the phosphor samples.

### Example 3: Preparation of NaUO₂P₃O₉ Phosphor and NaUO₂P₃O₉ doped with 1% Eu³⁺

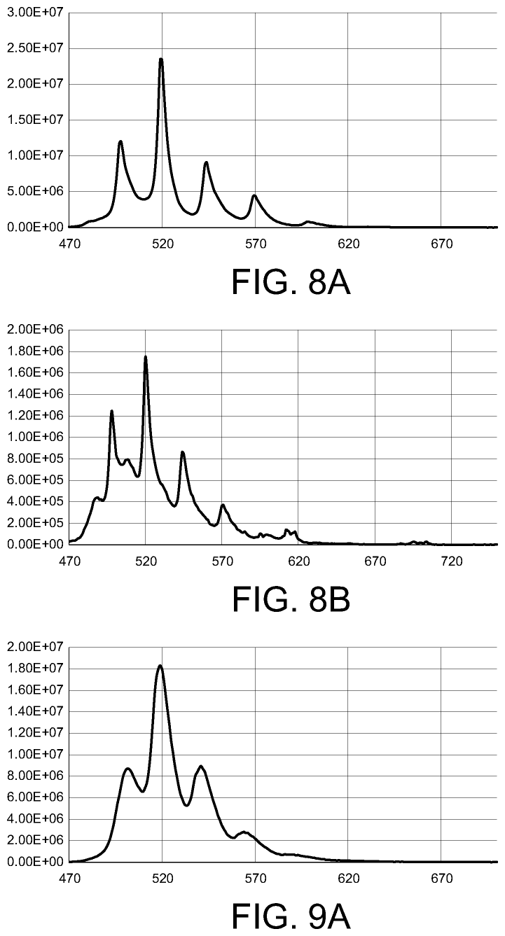

(NHahHPO₄ (DAP), HUO₂PO₄-4H₂O and NaH₂PO₄ were weighed out in a mol ratio of 1:1:1 and then put in a Nalgene bottle with zirconia media and ball milled for two hours. After the mixture was thoroughly blended the powder was transferred into an alumina crucible and fired at 300° C. for 5 hours, the mixture was then sieved through a 40-mesh screen and blended again in the same Nalgene bottle for two additional hours. The powder was put back into the alumina crucible and fired at 500° C. for 5 hours. After firing, a yellow body colored powder was obtained. The emission spectra of NaUO₂P₃O₉ is shown in FIG. 8A.

For preparing NaUO₂P₃O₉ doped with 1% Eu³⁺, the same procedure was used, as above, except 0.005 Eu₂O₃ was added and the amount of NaH₂PO₄ was adjusted to 0.495 in the blend. After firing, a yellow body colored powder was obtained. The emission spectra of NaUO₂P₃O₉ is shown in FIG. 8B.

Results are shown in Table 3.

TABLE 3

| | Activator Ion | QE (vs β- | | |
|---|---|---|---|---|
| Phosphor | (1 molar %) | SiAlON) | ccx | ccy |
| NaUO₂P₃O₉ | None | 0.728 | 0.2054 | 0.6689 |
| NaUO₂P₃O₉ | Eu³⁺ | | 0.2200 | 0.6346 |

Phosphor NaUO₂P₃O₉ emits a bright green and can provide a large gamut for display applications. Phosphor NaUO₂P₃O₉ did not demonstrate energy transfer from the uranium ion to the activator ion when doped with Eu³⁺ Example 4: Preparation of K₄UO₂(PO₄)₂ Phosphor and K₄UO₂(PO₄)₂ doped with 1% Eu³⁺.

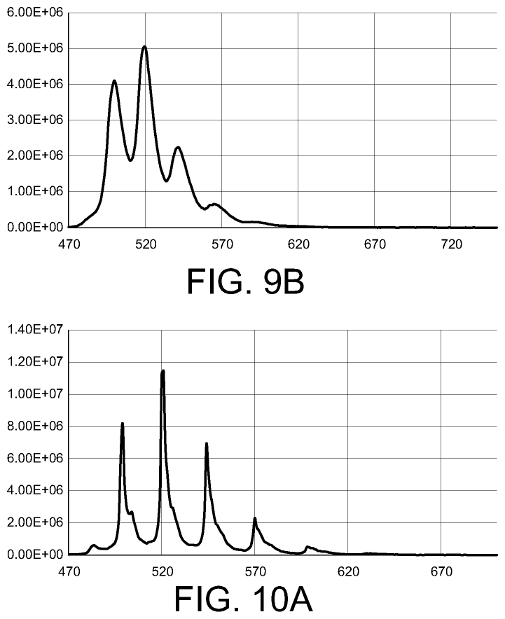

K₂CO₃, HUO₂PO₄-4H₂O and KH₂PO₄ were weighed out in a molar ratio of 1.5:1:1 and then put in a Nalgene bottle with zirconia media and ball milled for two hours. After the mixture was thoroughly blended the powder was transferred into an alumina crucible and fired at 500° C. for 5 hrs, the mixture was then sieved through a 40-mesh screen and blended again in the same Nalgene bottle for two additional hours. The powder was put back into the alumina crucible and fired at 900° C. for 5 hours. After firing, a yellow body colored powder was obtained. The emission spectra of K₄UO₂(PO₄)₂ is shown in FIG. 9A.

For preparing K₁UO₂(PO₄)₂ doped with 1% molar amount of Eu³⁺, the same procedure as above was used except 0.005 Eu₂O₃ was added and the amount of K₂CO₃ was adjusted to 1.495 in the blend. After firing, a yellow body-colored powder was obtained. The emission spectra of K₄UO₂(PO₄)₂ is shown in FIG. 9B.

Results are shown in Table 4.

TABLE 4

| | Activator Ion | QE (vs β- | | |
|---|---|---|---|---|
| Phosphor | (1 molar %) | SiAlON) | ccx | ccy |
| K₄UO₂(PO₄)₂ | None | 0.641 | 0.1930 | 0.7025 |
| K₄UO₂(PO₄)₂ | Eu³⁺ | | 0.1725 | 0.6849 |

Phosphor K₄UO₂(PO₄)₂ emits a bright green and can provide a large gamut for display applications. Phosphor K₄UO₂(PO₄)₂ did not demonstrate energy transfer from the uranium ion to an activator ion when doped with Eu³⁺.

### Example 5: Preparation of Ba₃(PO₄)₂(UO₂hP₂O₇ Phosphor and co-doped Ba₃(PO₄)₂(UO₂) P₂O₇ phosphor material

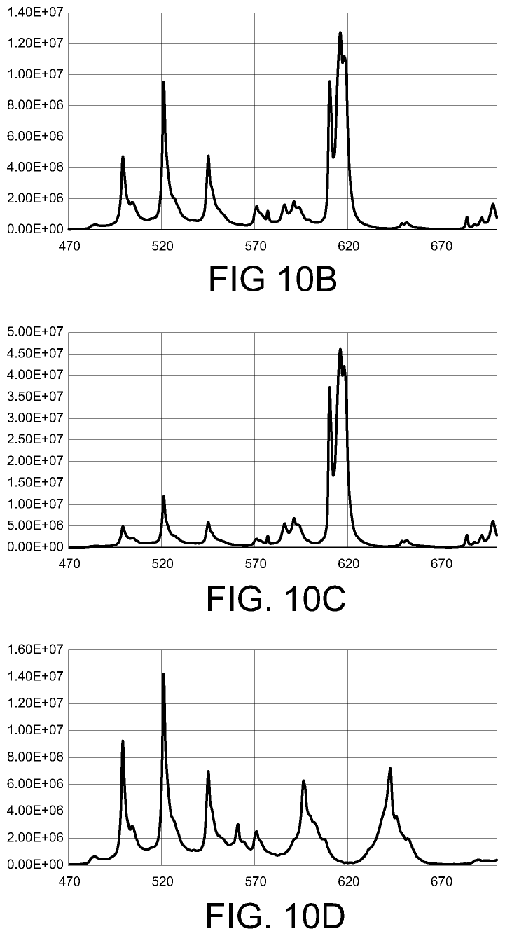

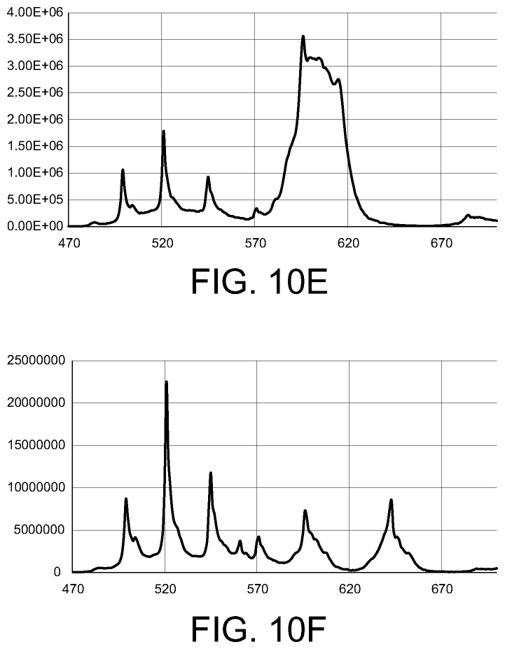

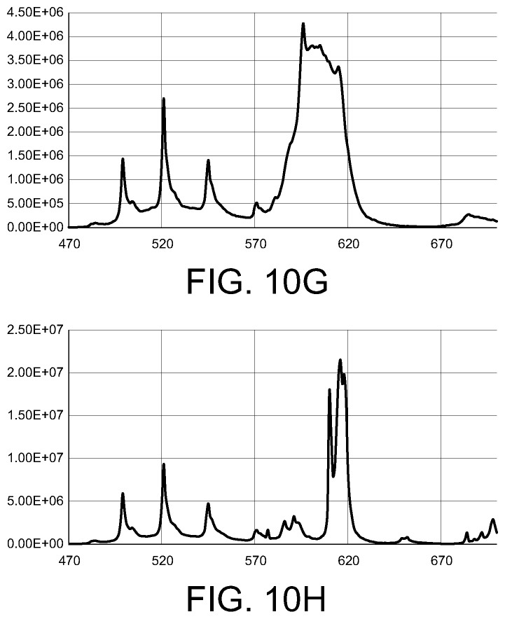

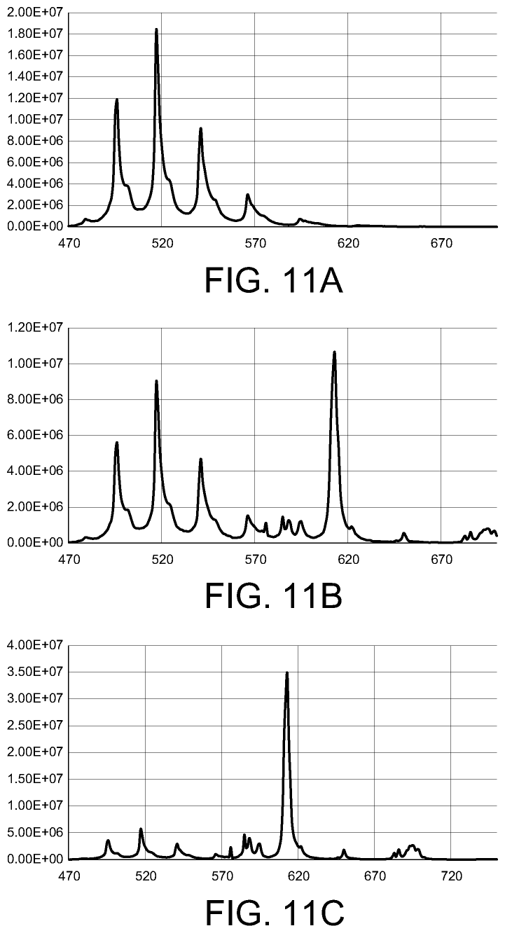

BaHPO₄, BaCO₃, HUO₂PO₄-4H₂O and DAP were weighed out in a mol ratio of 2:1:2:0.05 and then put in a Nalgene bottle with zirconia media and ball milled for two hours. After the mixture was thoroughly blended the powder was transferred into an alumina crucible and fired at 1100° C. for 5 hours. After firing, a yellow body-colored powder was obtained. The emission spectra of Ba₃(PO₄)₂(UO₂)₂P₂O₇ is shown in FIG. 10A. Results for Ba₃(PO₄)₂(UO₂)₂P₂O₇ is shown in Table 5 as Sample 1.

For preparing Ba₃(PO₄)₂(UO₂hP₂O₇ doped with 1% molar amount of Eu³⁺, the same procedure as above was used except 0.005 Eu₂O₃ was added and the amount for BaCO₃ was adjusted to 0.995. After firing, a yellow body colored powder was obtained. The emission spectra of Ba₃(PO₄)₂(UO₂hP₂O₇ doped with Eu³⁺ is shown in FIG. 10B. Results for Ba₃(PO₄)₂(UO₂)₂P₂O₇ doped with Eu³⁺ is shown in Table 5 as Sample 2.

For preparing Ba₃(PO₄)₂(UO₂hP₂O₇ doped with 1% molar amount of Eu³⁺ and K⁺, the same procedure as above was used except 0.005 Eu₂O₃ and 0.005 K₂CO₃ were substituted for BaCO₃. The emission spectra of Ba₃(PO₄)₂(UO₂)₂P₂O₇ doped with Eu³⁺ and K⁺ is shown in FIG. 10C. Results for Ba₃(PO₄)₂(UO₂hP₂O₇ doped with Eu³⁺ and K⁺ is shown in Table 5 as Sample 3.

Ba₃(PO₄)₂(UO₂)₂P₂O₇ doped with 1% molar amount of Sm³⁺ and K⁺ was prepared as for Ba₃(PO₄)₂(UO₂)₂P₂O₇ doped with 1% molar amount of Eu³⁺ and K⁺, except that Sm₂O₃ was substituted for Eu₂O₃. The emission spectra of Ba₃(PO₄)₂(UO₂hP₂O₇ doped with 1% molar amount of Sm³⁺ and K⁺, is shown in FIG. 10D. Results of Ba₃(PO₄)₂(UO₂)₂P₂O₇ doped with 1% molar amount of Sm³⁺ and K⁺, is shown in Table 5 as Sample 4.

Ba₃(PO₄)₂(UO₂)₂P₂O₇ doped with 1% molar amount of Pr³⁺ and K⁺ was prepared as for Ba₃(PO₄)₂(UO₂)₂P₂O₇ doped with 1% molar amount of Eu³⁺ and K⁺, except that Pr₆O₁₁ was substituted for Eu₂O₃. The emission spectra of Ba₃(PO₄)₂(UO₂)₂P₂O₇ doped with 1% molar amount of Eu³⁺ and K⁺, is shown in FIG. 10E. Results of Ba₃(PO₄)₂(UO₂)₂P₂O₇ doped with 1% molar amount of Pr³⁺ and K⁺, is shown in Table 5 as Sample 5.

Ba₃(PO₄)₂(UO₂)₂P₂O₇ doped with 1% molar amount of Sm³⁺ and K⁺ was prepared as for Ba₃(PO₄)₂(UO₂)₂P₂O₇ doped with 1% molar amount of Eu³⁺ and K⁺, except that SmPO₄ was substituted for Eu₂O₃ and KH₂PO₄ was substituted for K₂CO₃. The emission spectra of Ba₃(PO₄)₂(UO₂hP₂O₇ doped with 1% molar amount of Sm³⁺ and K⁺, is shown in FIG. 1 OF. The results of Ba₃(PO₄)₂(UO₂)₂P₂O₇ doped with 1% molar amount of Sm³⁺ and K⁺, is shown in Table 5 as Sample 6.

Ba₃(PO₄)₂(UO₂)₂P₂O₇ doped with 1% molar amount of Pr³⁺ and K⁺ was prepared as for Ba₃(PO₄)₂(UO₂)₂P₂O₇ doped with 1% molar amount of Eu³⁺ and K⁺, except that PrPO₄ was substituted for Eu₂O₃ and KH₂PO₄ was substituted for K₂CO₃. The emission spectra of Ba₃(PO₄)₂(UO₂hP₂O₇ doped with 1% molar amount of Pr³⁺ and K⁺, is shown in FIG. 10G. Results of Ba₃(PO₄)₂(UO₂)₂P₂O₇ doped with 1% molar amount of Pr³⁺ and K⁺, is shown in Table 5 as Sample 7.

Ba₃(PO₄)₂(UO₂)₂P₂O₇ doped with 1% molar amount of Eu³⁺ and K⁺ was prepared as for Ba₃(PO₄)₂(UO₂)₂P₂O₇ doped with 1% molar amount of Eu³⁺ and K⁺, except that EuPO₄ was substituted for Eu₂O₃ and KH₂PO₄ was substituted for K₂CO₃. The emission spectra of Ba₃(PO₄)₂(UO₂)₂P₂O₇ doped with 1% molar amount of Eu³⁺ and K⁺, is shown in FIG. 10H. Results of Ba₃(PO₄)₂(UO₂hP₂O₇ doped with 1% molar amount of Eu³⁺ and K⁺, is shown in Table 5 as Sample 8.

TABLE 5

| | Co-doped Ion | QE (vs β- | | |
|---|---|---|---|---|
| Phosphor | (1 molar %) | SiAlON) | ccx | ccy |
| Sample 1 | None | 0.539 | 0.2225 | 0.6638 |
| Sample 2 | Eu³⁺ | 0.378 | 0.4645 | 0.4900 |
| Sample 3 | Eu³⁺, K⁺ | 0.588 | 0.5595 | 0.4188 |
| Sample 4 | Sm³⁺, K⁺ | 0.364 | 0.3817 | 0.5563 |
| Sample 5 | Pr³⁺, K⁺ | 0.221 | 0.5468 | 0.4335 |
| Sample 6 | Sm³⁺, K⁺ | 0.375 | 0.3630 | 0.5810 |
| Sample 7 | Pr³⁺, K⁺ | 0.235 | 0.5347 | 0.4436 |
| Sample 8 | Eu³⁺, K⁺ | 0.492 | 0.5042 | 0.4595 |

Energy transfer is demonstrated by the difference in color coordinates ccx and ccy. Each sample 2-8 shows that there is energy transfer from the uranium ion to the activator ions. Phosphor material Ba₃(PO₄)₂(UO₂)₂P₂O₇ doped with activator ions Eu³⁺ has a drop in quantum efficiency, but the addition of counter ion K⁺ increases the QE over Phosphor material Ba₃(PO₄)₂(UO₂)₂P₂O₇ (sample 1). Samples 4-8 have a decrease in quantum efficiency. Other Examples demonstrate how quantum efficiency can be increased in the phosphor samples.

### Example 6: Preparation of BaZnUO₂(PO₄)₂ phosphor and co-doped BaZnUO₂(PO₄)₂ phosphor materials

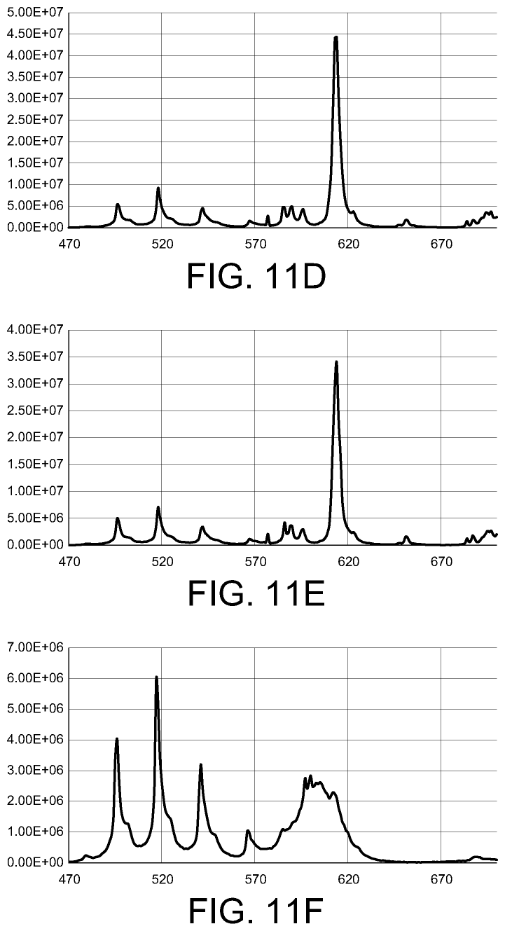

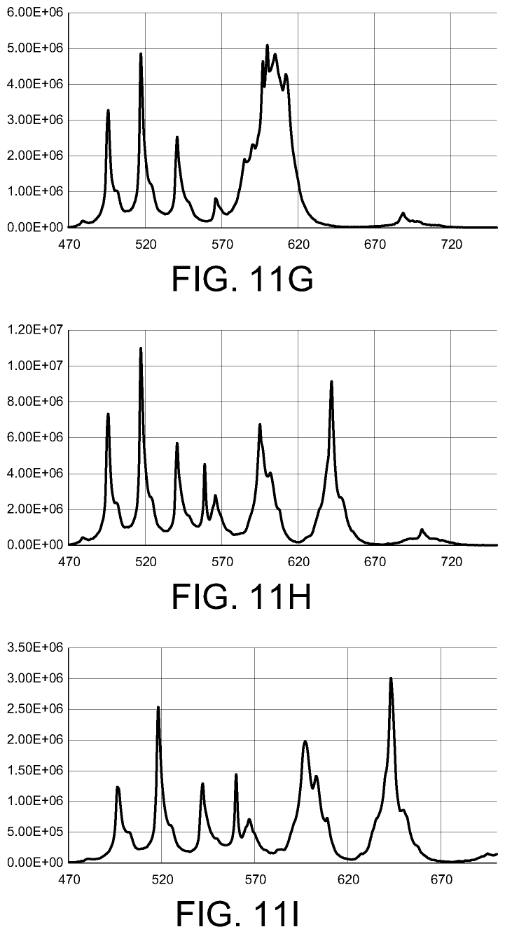

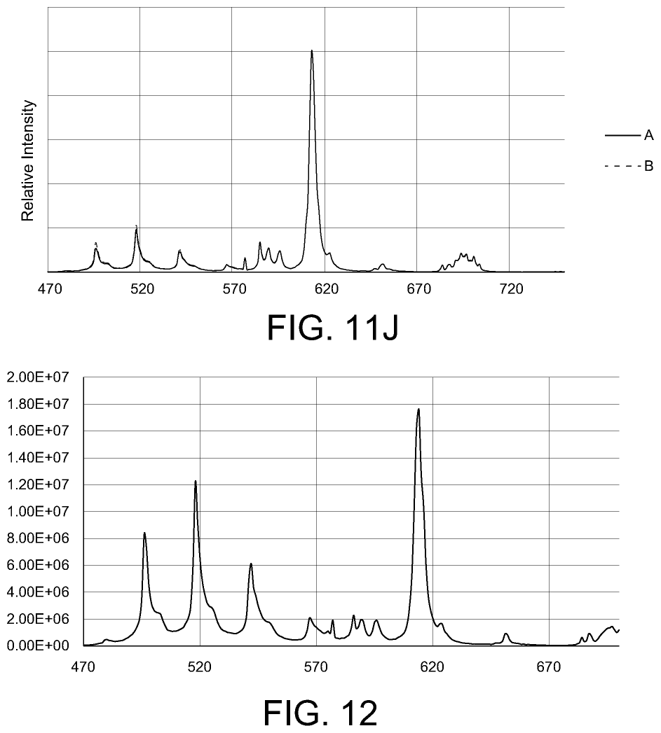

BaHPO₄, HUO₂PO₄-4H₂O, ZnO and DAP were weighed out in a mol ratio of 1:1:1:0.05 and then put in a Nalgene bottle with zirconia media and ball milled for two hours. After the mixture was thoroughly blended the powder was transferred into an alumina crucible and fired at 1050° C. for 5 hours under flowing wet air. After firing, a yellow body-colored powder was obtained. The emission spectra of BaZnUO₂(PO₄)₂ is shown in FIG. 11A. Results of BaZnUO₂(PO₄)₂ is shown in Table 6 as Sample A.

For preparing BaZnUO₂(PO₄)₂ doped with 1% molar amount of Eu³⁺, the same procedure as above was used except 0.005 Eu₂O₃ was substituted for BaHPO₄. After firing a yellow body colored powder was obtained. The emission spectra of BaZnUO₂(PO₄)₂ doped with Eu³⁺ is shown in FIG. 11B. Results of BaZnUO₂(PO₄)₂ doped with Eu³⁺ is shown in Table 6 as Sample B.

For preparing BaZnUO₂(PO₄)₂ doped with 1% molar amount of Eu³⁺ and K⁺, the same procedure as above was used except 0.005 Eu₂O₃ and 0.005 K₂CO₃ were substituted for BaHPO₄. After firing a yellow body colored powder was obtained. The emission spectra of BaZnUO₂(PO₄)₂ doped with Eu³⁺ and K⁺ is shown in FIG. 11C. Results of BaZnUO₂(PO₄)₂ doped with Eu³⁺ and K⁺ is shown in Table 6 as Sample B1.

BaZnUO₂(PO₄)₂ doped with 1% molar amount of Eu³⁺ and K⁺ was prepared as for Sample B1, except that EuPO₄ was substituted for Eu₂O₃ and KH₂PO₄ was substituted for K₂CO₃. Results of Ba₃(PO₄)₂(UO₂)₂P₂O₇ doped with 1% molar amount of Eu³⁺ and K⁺, is shown in Table 6 as Sample B2.

BaZnUO₂(PO₄)₂ doped with 1% molar amount of Eu³⁺ and Li⁺ was prepared as for Sample B1, except that Li₂CO₃ was substituted for K₂CO₃. The emission spectra of Ba₃(PO₄)₂(UO₂)₂P₂O₇ doped with 1% molar amount of Eu³⁺ and Li⁺, is shown in FIG. 11D. Results of Ba₃(PO₄)₂(UO₂hP₂O₇ doped with 1% molar amount of Eu³⁺ and Li⁺, is shown in Table 6 as Sample B3.

BaZnUO₂(PO₄)₂ doped with 1% molar amount of Eu³⁺ and Na⁺ was prepared as for Sample B1, except that Na₂CO₃ was substituted for K₂CO₃. The emission spectra of BaZnUO₂(PO₄)₂ doped with 1% molar amount of Eu³⁺ and Na, is shown in FIG. 11E. Results of BaZnUO₂(PO₄)₂ doped with 1% molar amount of Eu³⁺ and Na⁺, is shown in Table 6 as Sample B4.

BaZnUO₂(PO₄)₂ doped with 1% molar amount of Eu³⁺, Tb³⁺ and K⁺ was prepared as for Sample B1, except that Tb₄O₇ was also included. Results of BaZnUO₂(PO₄)₂ doped with 1% molar amount of Eu³⁺, Tb³⁺ and K⁺, is shown in Table 6 as Sample B5.

BaZnUO₂(PO₄)₂ doped with 1% molar amount of Eu³⁺, Dy³⁺ and K⁺ was prepared as for Sample B1, except that Dy₂O₃ was also included. Results of BaZnUO₂(PO₄)₂ doped with 1% molar amount of Eu³⁺, Dy³⁺ and K⁺, is shown in Table 6 as Sample B6.

BaZnUO₂(PO₄)₂ doped with 1% molar amount of Eu³⁺, Sm³⁺ and K⁺ was prepared as for Sample B1, except that Sm₂O₃ was also included. Results of BaZnUO₂(PO₄)₂ doped with 1% molar amount of Eu³⁺, Sm³⁺ and K⁺, is shown in Table 6 as Sample B7.

BaZnUO₂(PO₄)₂ doped with 1% molar amount of Pr³⁺ was prepared as for BaZnUO₂(PO₄)₂ doped with 1% molar amount of Eu³⁺ except that Pr₆O₁₁ was substituted for Eu₂O₃. The emission spectra of BaZnUO₂(PO₄)₂ doped with Pr³⁺ is shown in FIG. 11F. Results of BaZnUO₂(PO₄)₂ doped with Pr³⁺ is shown in Table 6 as Sample C.

BaZnUO₂(PO₄)₂ doped with 1% molar amount of Pr³⁺ and K⁺ was prepared as for Sample B1, except that Pr₆O₁₁ was substituted for Eu₂O₃. The emission spectra of BaZnUO₂(PO₄)₂ doped with Pr³⁺ and K⁺ is shown in FIG. 11G. Results of BaZnUO₂(PO₄)₂ doped with Pr³⁺ and K⁺ is shown in Table 6 as Sample C1.

BaZnUO₂(PO₄)₂ doped with 1% molar amount of Pr³⁺ and K⁺ was prepared as for Sample B1, except that PrPO₄ was substituted for Eu₂O₃ and KH₂PO₄ was substituted for K₂CO₃. Results of BaZnUO₂(PO₄)₂ doped with 1% molar amount of Pr³⁺ and K⁺, is shown in Table 6 as Sample C2.

BaZnUO₂(PO₄)₂ doped with 1% molar amount of Sm³⁺ was prepared as for BaZnUO₂(PO₄)₂ doped with 1% molar amount of Eu³⁺ except that Sm₂O₃ was substituted for Eu₂O₃. The emission spectra of BaZnUO₂(PO₄)z doped with Sm³⁺ is shown in FIG. 11H. Results of BaZnUO₂(PO₄)₂ doped with Sm³⁺ is shown in Table 6 as Sample D.

BaZnUO₂(PO₄)₂ doped with 1% molar amount of Sm³⁺ and K⁺ was prepared as for Sample B1, except that Sm₂O₃ was substituted for Eu₂O₃. The emission spectra of BaZnUO₂(PO₄)₂ doped with Sm³⁺ and K⁺ is shown in FIG. 11I. Results of BaZnUO₂(PO₄)₂ doped with Sm³⁺ and K⁺ is shown in Table 6 as Sample D1.

BaZnUO₂(PO₄)₂ doped with 1% molar amount of Sm³⁺ and K⁺ was prepared as for Sample B1, except that PrPO₄ was substituted for Eu₂O₃ and KH₂PO₄ was substituted for K₂CO₃. Results of BaZnUO₂(PO₄)₂ doped with 1% molar amount of Sm³⁺ and K⁺, is shown in Table 6 as Sample D2.

BaZnUO₂(PO₄)₂ doped with 1% molar amount of Sm³⁺, Tb³⁺and K⁺ was prepared as for Sample D2, except that Tb₄O₇ was also included. Results of BaZnUO₂(PO₄)₂ doped with Sm³⁺, Tb³⁺ and K⁺ is shown in Table 6 as Sample D3.

BaZnUO₂(PO₄)₂ doped with 1% molar amount of Sm³⁺, Dy³⁺ and K⁺ was prepared as for Sample D2, except that Dy₂O₃ was also included. Results of BaZnUO₂(PO₄)₂ doped with Sm³⁺, Dy³⁺ and K⁺ is shown in Table 6 as Sample D4.

BaZnUO₂(PO₄)₂ doped with 1% molar amount of Tb³⁺ was prepared as for BaZnUO₂(PO₄)₂ doped with 1% molar amount of Eu³⁺ except that Tb₄O₇ was substituted for Eu₂O₃. Results of BaZnUO₂(PO₄)₂ doped with Tb³⁺ is shown in Table 6 as Sample E.

BaZnUO₂(PO₄)₂ doped with 1% molar amount of Dy³⁺ was prepared as for BaZnUO₂(PO₄)z doped with 1% molar amount of Eu³⁺ except that Dy₂O₃ was substituted for Eu₂O₃. Results of BaZnUO₂(PO₄)₂ doped with Dy³⁺ is shown in Table 6 as Sample F.

BaZnUO₂(PO₄)₂ doped with 1% molar amount of Ce³⁺ was prepared as for BaZnUO₂(PO₄)z doped with 1% molar amount of Eu³⁺ except that CeO₂ was substituted for Eu₂O₃. Results of BaZnUO₂(PO₄)₂ doped with Ce³⁺ is shown in Table 6 as Sample G.

BaZnUO₂(PO₄)₂ doped with 1% molar amount of Ce³⁺ and K⁺ was prepared as for Sample B1, except that CeO₂ was substituted for Eu₂O₃. Results of BaZnUO₂(PO₄)₂ doped with Ce³⁺ and K⁺ is shown in Table 6 as Sample G1.

BaZnUO₂(PO₄)₂ doped with 1% molar amount of Sn²⁺ was prepared as for BaZnUO₂(PO₄)₂ doped with 1% molar amount of Eu³⁺ except that SnO was substituted for Eu₂O₃. Results of BaZnUO₂(PO₄)₂ doped with Sn²⁺ is shown in Table 6 as Sample H.

BaZnUO₂(PO₄)₂ doped with 1% molar amount of Sb³⁺ was prepared as for BaZnUO₂(PO₄)₂ doped with 1% molar amount of Eu³⁺ except that Sb₂O₃ was substituted for Eu₂O₃. Results of BaZnUO₂(PO₄)₂ doped with Sb³⁺ is shown in Table 6 as Sample I.

BaZnUO₂(PO₄)₂ doped with 1% molar amount of Mn²⁺ was prepared as for BaZnUO₂(PO₄)₂ doped with 1% molar amount of Eu³⁺ except that MnCO₃ was substituted for Eu₂O₃. Results of BaZnUO₂(PO₄)₂ doped with Mn²⁺ is shown in Table 6 as Sample J.

BaZnUO₂(PO₄)₂ doped with 1% molar amount of Era was prepared as for Sample A except that Er₂O₃ was substituted for Eu₂O₃. Results of BaZnUO₂(PO₄)₂ doped with Era is shown in Table 6 as Sample K.

BaZnUO₂(PO₄)₂ doped with 1% molar amount of Tm was prepared as for Sample A except that Tm₂O₃ was substituted for Eu₂O₃. Results of BaZnUO₂(PO₄)₂ doped with Tm³⁺ is shown in Table 6 as Sample L.

BaZnUO₂(PO₄)₂ doped with 1% molar amount of Yb³⁺ was prepared as for Sample A except that Yb₂O₃ was substituted for Eu₂O₃. Results of BaZnUO₂(PO₄)₂ doped with Yb³⁺ is shown in Table 6 as Sample M.

BaZnUO₂(PO₄)₂ doped with 1% molar amount of Yb³⁺ and K⁺ was prepared as for Sample B1, except that Yb₂O₃ was substituted for Eu₂O₃. Results of BaZnUO₂(PO₄)₂ doped with Yb³⁺ and K⁺ is shown in Table 6 as Sample M1.

BaZnUO₂(PO₄)₂ doped with 1% molar amount of Nd³⁺ was prepared as for Sample A except that Nd₂O₃ was substituted for Eu₂O₃. Results of BaZnUO₂(PO₄)₂ doped with Nd³⁺ is shown in Table 6 as Sample N.

BaZnUO₂(PO₄)₂ doped with 1% molar amount of Gd³⁺ was prepared as for Sample A except that Gd₂O₃ was substituted for Eu₂O₃. Results of BaZnUO₂(PO₄)₂ doped with Gd³⁺ is shown in Table 6 as Sample O.

BaZnUO₂(PO₄)₂ doped with 1% molar amount of Bi³⁺ was prepared as for Sample A except that Bi₂O₃ was substituted for Eu₂O₃. Results of BaZnUO₂(PO₄)₂ doped with Bi³⁺ is shown in Table 6 as Sample P.

BaZnUO₂(PO₄)₂ doped with 1% molar amount of Ho³⁺ was prepared as for Sample A except that Ho₂O₃ was substituted for Eu₂O₃. Results of BaZnUO₂(PO₄)₂ doped with Ho³⁺ is shown in Table 6 as Sample Q.

For preparing BaZnUO₂(PO₄)₂ with 1% Eu³⁺-1% Li⁺, BaHPO₄, HUO₂PO₄-4H₂O, ZnO, DAP, Eu₂O₃ and Li₂CO₃ were weighed out in a mol ratio of 0.98:1:1:0.05:0.005:0.005 and then put in a Nalgene bottle with zirconia media and ball milled for two hours. After the mixture was thoroughly blended the powder was transferred into an alumina crucible and fired at 1050° C. for 5 hours under flowing wet air. After firing, a yellow body-colored powder was obtained. The emission spectra of BaZnUO₂(PO₄)₂:Eu³⁺,Li⁺ is shown in FIG. 11J labeled as A. Results of BaZnUO₂(PO₄)₂:Eu³⁺,Li⁺ is shown in Table 6 as Sample R.

For preparing off stoichiometry BaZnUO₂(PO₄)₂ doped with 1% molar amount of Eu³⁺ and 1% Li⁺. BaHPO₄, HUO₂PO₄-4H₂O, ZnO, DAP, Eu₂O₃ and Li₂CO₃ were weighed out in a mol ratio of 0.97:0.96:1.05:0.05:0.005:0.005 and the same procedure as above was used except the blend ratio was off stoichiometry from above. After firing a yellow body colored powder was obtained. The emission spectra of the off stoichiometry BaZnUO₂(PO₄)₂ doped with Eu³⁺ and Li⁺ is shown in FIG. 11J labeled as B. Results of BaZnUO₂(PO₄)₂ (Ba_{0.99}Zn_{1.05}(UO₂)_{0.96}(PO₄)₂) doped with Eu³⁺ is shown in Table 6 as Sample S.

TABLE 6

| | Co-doped Ion | QE | | |
|---|---|---|---|---|
| Phosphor | (1 molar %) | (vs PFS) | ccx | ccy |
| Sample A | None | 0.94 | 0.1993 | 0.6571 |
| Sample B | Eu³⁺ | 0.26 | 0.3738 | 0.5407 |
| Sample B1 | Eu³⁺, K⁺ | 0.80 | 0.5386 | 0.4262 |
| Sample B2 | Eu³⁺, K⁺ | 0.97 | 0.4098 | 0.5200 |
| Sample B3 | Eu⁺, Li⁺ | 0.91 | 0.5291 | 0.4345 |
| Sample B4 | Eu⁺, Na⁺ | 1.05 | 0.5197 | 0.4389 |
| Sample B5 | Eu³⁺, Tb³⁺, K⁺ | 0.80 | 0.5064 | 0.4478 |
| Sample B6 | Eu³⁺, Dy³⁺, K⁺ | 0.76 | 0.5381 | 0.4262 |
| Sample B7 | Eu³⁺, Sm³⁺, K⁺ | 0.70 | 0.5047 | 0.4557 |
| Sample C | Pr³⁺ | 0.38 | 0.4141 | 0.5157 |
| Sample C1 | Pr³⁺, K⁺ | 0.37 | 0.4910 | 0.4638 |
| Sample C2 | Pr³⁺, K⁺ | 0.89 | 0.4265 | 0.5068 |
| Sample D | Sm³⁺ | 0.79 | 0.4008 | 0.5288 |
| Sample D1 | Sm³⁺, K⁺ | 0.78 | 0.4431 | 0.5078 |
| Sample D2 | Sm³⁺, K⁺ | 0.48 | 0.3982 | 0.5321 |
| Sample D3 | Sm³⁺, Tb³⁺, K⁺ | 0.76 | 0.4338 | 0.5103 |
| Sample D4 | Sm³⁺, Dy³⁺, K⁺ | 0.75 | 0.4463 | 0.5003 |
| Sample E | Tb³⁺ | 0.62 | 0.2092 | 0.6585 |
| Sample F | Dy³⁺ | 0.72 | 0.2002 | 0.6565 |
| Sample G | Ce³⁺ | 0.35 | 0.2066 | 0.6577 |
| Sample G1 | Ce³⁺, K⁺ | | 0.2015 | 0.6542 |
| Sample H | Sn²⁺ | 1.00 | 0.2025 | 0.6571 |
| Sample I | Sb³⁺ | 0.91 | 0.2016 | 0.6539 |
| Sample J | Mn²⁺ | | 0.2018 | 0.6564 |
| Sample K | Er³⁺ | 0.64 | 0.2029 | 0.6564 |
| Sample L | Tm³⁺ | 0.82 | 0.2021 | 0.6572 |
| Sample M | Yh³⁺ | 0.91 | 0.1994 | 0.6527 |
| Sample M1 | Yb³⁺, K⁺ | 0.95 | 0.2044 | 0.6612 |
| Sample N | Nd³⁺ | | 0.2012 | 0.6584 |
| Sample O | Gd³⁺ | 0.60 | 0.2035 | 0.6591 |
| Sample P | Bi³⁺ | | 0.1998 | 0.6570 |
| Sample Q | Ho³⁺ | 0.58 | 0.2021 | 0.6598 |
| Sample R | 1% Eu³⁺, 1% Li⁺ | 0.92 | 0.5365 | 0.4300 |
| Sample S | 1% Eu³⁺, 1% Li⁺ | 1.01 | 0.5268 | 0.4356 |

Energy transfer is demonstrated by the difference in color coordinates ccx and ccy. Phosphor materials BaZnUO₂(PO₄)₂ doped with activator ions Eu³⁺, Pr³⁺ and Sm³⁺ show that there is a energy transfer from the uranium ion to the activator ions. Phosphor materials BaZnUO₂(PO₄)₂ doped with activator ions Ce³⁺, Sn²⁺, Sb³⁺, Mn²⁺, Tb³⁺, Er³⁺, Tm³⁺, Yb³⁺, Nd³⁺, Gd³⁺, Bi³⁺, Ho³⁺ and Dy³⁺ do not show energy transfer from the uranium ion to the activator ions. This shows unexpected results, as not all activator ions in the lanthanide group will work with uranium-based phosphors.

An alkali counter ion can improve or at least maintain the energy transfer and quantum efficiency properties exhibited by the phosphor doped with activator ions Eu³⁺, Sm³⁺ and Pr³⁺. BaZnUO₂(PO₄)₂ doped with Eu³⁺ has significant improvement in energy transfer and quantum efficiency when co-doped with an alkali counter ion (K⁺ and Li⁺), but the counter ion does not provide for energy transfer where there is no energy transfer to the activator ion, as shown for Ce³⁺ and Yb³⁺.

### Example 7 Preparation of co-doped BaZnUO₂(PO₄)₂ phosphor materials

BaZnUO₂(PO₄)₂ doped with 1% molar amount of Eu³⁺ and K⁺ were prepared by using BaHPO₄, HUO₂PO₄-4H₂O, ZnO, DAP, Eu₂O₃ and K₂CO₃ which were weighed out in a mol ratio of 0.98:1:1:0.07:0.005:0.005 and then put in a Nalgene bottle with zirconia media and ball milled for two hours. After the mixture was thoroughly blended the powder was transferred into an alumina crucible and fired at 1050° C. for 5 hours under flowing wet air. After firing a yellow body colored powder was obtained. After firing, a yellow body-colored powder was obtained. Results of BaZnUO₂(PO₄)₂ doped with Eu³⁺ and K⁺ is shown in Table 7 as Sample B5-1%.

BaZnUO₂(PO₄)₂ doped with 2% molar amount of Eu³⁺ and K⁺ was prepared as for Sample B5-1%, except that 2% Eu₂O₃ and 2% K₂CO₃ was added. Results of Ba₃(PO₄)₂(UO₂) P₂O₇ doped with 2% molar amount of Eu³⁺ and K⁺, is shown in Table 7 as Sample B5-2%.

BaZnUO₂(PO₄)₂ doped with 3% molar amount of Eu³⁺ and K⁺ was prepared as for Sample B5-1%, except that 3% Eu₂O₃ and 3% K₂CO₃ was added. Results of BaZnUO₂(PO₄)₂ doped with 3% molar amount of Eu³⁺ and K⁺, is shown in Table 7 as Sample B5-3%.

TABLE 7

| | Co-doped Ion | QE | | |
|---|---|---|---|---|
| Phosphor | (molar %) | (vs PFS) | ccx | ccy |
| Sample B | 1% Eu³⁺ | 0.26 | 0.3738 | 0.5407 |
| Sample B5-1% | 1% Eu³⁺, 1% K⁺ | 0.72 | 0.5386 | 0.4262 |
| Sample B5-2% | 2% Eu³⁺, 2% K⁺ | 0.82 | 0.4098 | 0.5200 |
| Sample B5-3% | 3% Eu³⁺, 3% K⁺ | 0.77 | 0.5291 | 0.4345 |

Energy transfer is demonstrated by the difference in color coordinates ccx and ccy. Phosphor materials BaZnUO₂(PO₄)₂ co-doped with counter ion K⁺ show an increased QE. Using different amounts of the activator ion Eu³⁺ show how the phosphor can be color-tuned.

### Example 8 Preparation of BaZnUO₂(PO₄)₂ and co-doped phosphor materials

BaZnUO₂(PO₄)₂ was prepared as above for Sample A in Example 6.

For preparing BaZnUO₂(PO₄)₂ doped with 1% molar amount of Eu³⁺, BaHPO₄, HUO₂PO₄-4H₂O, ZnO, DAP and Eu₂O₃ were weighed out in a mol ratio of 0.99:1:1:0.06:0.005 and then put in a Nalgene bottle with zirconia media and ball milled for two hours. After the mixture was thoroughly blended the powder was transferred into an alumina crucible and fired at 1050° C. for 5 hours under flowing wet air. After firing, a yellow body-colored powder was obtained. The emission spectra of BaZnUO₂(PO₄)₂ doped with Eu³⁺ is shown in FIG. 12.

For preparing BaZnUO₂(PO₄)₂ doped with 1% molar amount of Eu³⁺ and K⁺, BaHPO₄, HUO₂PO₄-4H₂O, ZnO, DAP, Eu₂O₃ and K₂CO₃ were weighed out in a mol ratio of 0.98:1:1:0.07:0.005:0.005 and then put in a Nalgene bottle with zirconia media and ball milled for two hours. After the mixture was thoroughly blended the powder was transferred into an alumina crucible and fired at 1050° C. for 5 hours under flowing wet air. After firing, a yellow body-colored powder was obtained.

BaZnUO₂(PO₄)₂ doped with 1% molar amount of Eu³⁺ and Li⁺ was prepared as for preparing BaZnUO₂(PO₄)₂ doped with 1% molar amount of Eu³⁺ and K⁺, except that Li₂CO₃ was substituted for K₂CO₃.

BaZnUO₂(PO₄)₂ doped with 1% molar amount of Eu³⁺ and Na⁺ was prepared as for preparing BaZnUO₂(PO₄)₂ doped with 1% molar amount of Eu and K⁺, except that Na₂CO₃ was substituted for K₂CO₃.

BaZnUO₂(PO₄)₂ doped with 1% molar amount of Eu³⁺ and Rb⁺ was prepared as for preparing BaZnUO₂(PO₄)₂ doped with 1% molar amount of Eu and K⁺, except that Rb₂CO₃ was substituted for K₂CO₃.

BaZnUO₂(PO₄)₂ doped with 1% molar amount of Eu and Cs⁺ was prepared as for preparing BaZnUO₂(PO₄)₂ doped with 1% molar amount of Eu³⁺ and K⁺, except that Cs₂CO₃ was substituted for K₂CO₃.

Results shown in Table 8.

TABLE 8

| | Co-doped Ion | QE | | |
|---|---|---|---|---|
| Phosphor | (1 molar %) | (vs PFS) | ccx | ccy |
| BaZnUO₂(PO₄)₂ | None | 0.94 | 0.1993 | 0.6571 |
| BaZnUO₂(PO₄)₂ | Eu³⁺ | 0.31 | 0.4022 | 0.5229 |
| BaZnUO₂(PO₄)₂ | Eu³⁺, K⁺ | 0.97 | 0.4098 | 0.5200 |
| BaZnUO₂(PO₄)₂ | Eu³⁺, Li⁺ | 0.99 | 0.5368 | 0.4268 |
| BaZnUO₂(PO₄)₂ | Eu³⁺, Na⁺ | 0.92 | 0.5344 | 0.4295 |
| BaZnUO₂(PO₄)₂ | Eu³⁺, Rb⁺ | 0.56 | 0.4892 | 0.4625 |
| BaZnUO₂(PO₄)₂ | Eu³⁺, Cs⁺ | 0.28 | 0.3884 | 0.5295 |

Energy transfer is demonstrated by the difference in color coordinates ccx and ccy. Phosphor materials BaZnUO₂(PO₄)₂ co-doped with an activator ion show an energy transfer. BaZnUO₂(PO₄)₂ co-doped with an activator ion and a counter ion shows an energy transfer and can increase or maintain the QE over the phosphor material without the counter ion.

Example 9 Preparation of gamma-Ba₂UO₂(PO₄)₂ and co-doped phosphor material

For preparing gamma-Ba₂UO₂(PO₄)₂, BaHPO₄, UO₂, and DAP were weighed out in a mol ratio of 2:1:0.05 and then put in a Nalgene bottle with zirconia media and ball milled for two hours. After the mixture was thoroughly blended the powder was transferred into an alumina crucible and fired at 1100° C. for 5 hours in air. After firing a yellow body colored powder was obtained. The emission spectra of gamma-Ba₂UO₂(PO₄)z is shown in FIG. 13A. The XRD powder pattern for gamma-Ba₂UO₂(PO₄)₂ is shown in FIG. 13H.

For preparing gamma-Ba₂UO₂(PO₄)₂ doped with 1 mol % Eu³⁺, BaHPO₄, UO₂, DAP and Eu₂O₃ were weighed out in a mol ratio of 1.99:1:0.05:0.005 and then put in a Nalgene bottle with zirconia media and ball milled for two hours. After the mixture was thoroughly blended the powder was transferred into an alumina crucible and fired at 1100° C. for 5 hours in air. After firing a yellow body colored powder was obtained. The emission spectra of gamma-Ba₂UO₂(PO₄)₂ doped with Eu³⁺ is shown in FIG. 13B.

For preparing gamma-Ba₂UO₂(PO₄)₂ doped with 1 mol % Eu³⁺ and 1 mol % K⁺, BaHPO₄, UO₂, DAP, Eu₂O₃ and K₂CO₃ were weighed out in a mol ratio of 1.98:1:0.05:0.005:0.005 and then put in a Nalgene bottle with zirconia media and ball milled for two hours. After the mixture was thoroughly blended the powder was transferred into an alumina crucible and fired at 1100° C. for 5 hours in air. After firing a yellow body colored powder was obtained. The emission spectra of gamma-Ba₂UO₂(PO₄)₂ doped with Eu³⁺ and K⁺ is shown in FIG. 13C.

For preparing gamma-Ba₂UO₂(PO₄)₂ doped with 1 mol % Sm³⁺ and 1 mol % K⁺, BaHPO₄, UO₂, DAP, Sm₂O₃ and K₂CO₃ were weighed out in a mol ratio of 1.98:1:0.05:0.005:0.005 and then put in a Nalgene bottle with zirconia media and ball milled for two hours. After the mixture was thoroughly blended the powder was transferred into an alumina crucible and fired at 1100° C. for 5 hours in air. After firing a yellow body colored powder was obtained. The emission spectra of gamma-Ba₂UO₂(PO₄)₂ doped with Sm and K⁺ is shown in FIG. 13D.

For preparing gamma-Ba₂UO₂(PO₄)z doped with 1 mol % Pr³⁺ and 1 mol % K⁺, BaHPO₄, UO₂, DAP, Pr₆O₁₁ and K₂CO₃ were weighed out in a mol ratio of 1.98:1:0.05:0.00167:0.005 and then put in a Nalgene bottle with zirconia media and ball milled for two hours. After the mixture was thoroughly blended the powder was transferred into an alumina crucible and fired at 1100° C. for 5 hours in air. After firing a yellow body colored powder was obtained. The emission spectra of gamma-Ba₂UO₂(PO₄)₂ doped with Pr³⁺ and K⁺ is shown in FIG. 13E.

For preparing gamma-Ba₂UO₂(PO₄)₂ doped with 1 mol % Dy³⁺ and 1 mol % K⁺, BaHPO₄, UO₂, DAP, Dy₂O₃ and K₂CO₃ were weighed out in a mol ratio of 1.98:1:0.05:0.005:0.005 and then put in a Nalgene bottle with zirconia media and ball milled for two hours. After the mixture was thoroughly blended the powder was transferred into an alumina crucible and fired at 1100° C. for 5 hours in air. After firing a yellow body colored powder was obtained. The emission spectra of gamma-Ba₂UO₂(PO₄)z doped with Dy and K⁺ is shown in FIG. 13F.

For preparing gamma-Ba₂UO₂(PO₄)₂ doped with 1 mol % TbI and 1 mol % K⁺, BaHPO₄, UO₂, DAP, Tb₄O₇ and K₂CO₃ were weighed out in a mol ratio of 1.98:1:0.05:0.0025:0.005 and then put in a Nalgene bottle with zirconia media and ball milled for two hours. After the mixture was thoroughly blended the powder was transferred into an alumina crucible and fired at 1100° C. for 5 hours in air. After firing a yellow body colored powder was obtained. The emission spectra of gamma-Ba₂UO₂(PO₄)₂ doped with Dy³⁺ and K⁺ is shown in FIG. 13G.

Results are shown in Table 9

TABLE 9

| | Dopant (1 | QE (vs | | |
|---|---|---|---|---|
| Phosphor | molar %) | PFS) | ccx | ccy |
| γ-Ba₂UO₂(PO₄)₂ | None | 0.99 | 0.2903 | 0.6691 |
| γ-Ba₂UO₂(PO₄)₂ | Ey³⁺ | 0.33 | 0.3002 | 0.6609 |
| γ-Ba₂UO₂(PO₄)₂ | Eu³⁺, K⁺ | 0.88 | 0.3890 | 0.5840 |
| γ-Ba₂UO₂(PO₄)₂ | Sm³⁺, K⁺ | 0.88 | 0.2988 | 0.6631 |
| γ-Ba₂UO₂(PO₄)₂ | Pr³⁺, K⁺ | 0.43 | 0.4098 | 0.5641 |
| γ-Ba₂UO₂(PO₄)₂ | Dy³⁺, K⁺ | 0.97 | 0.2930 | 0.6685 |
| γ-Ba₂UO₂(PO₄)₂ | Tb³⁺, K⁺ | 0.93 | 0.2909 | 0.6695 |

Energy transfer is demonstrated by the difference in color coordinates ccx and ccy. Phosphor materials gamma-Ba₂UO₂(PO₄)z co-doped with an activator ion Eu³⁺, Pr³⁺ and Sm³⁺ have an energy transfer from the uranium ion to the activator ions; however, the peak is very broad, so the ccx and ccy changes are not as strong as other compositions (see FIG. 13A). The addition of activator ion Eu³⁺ can be seen at about 610 in FIG. 13B. The addition of both an activator ion and counter ion shows a more pronounced peak forming at 610 in FIG. 13C. The addition of activator peaks can be seen in FIG. 13D (Sm³⁺) and FIG. 13E (Pr³⁺); whereas no additional peaks are observed in FIGS. 13F and 13G for Dy³⁺ and Tb³⁺, which do not show an energy transfer from the uranium ion to the activator ions. Gamma phase Ba₂UO₂(PO₄)₂ co-doped with an activator ion and a counter ion increases or maintains the QE over the phosphor material without the counter ion. Other Examples herein demonstrate how quantum efficiency can be further increased in the phosphor samples.

### Example 10 Preparation of gamma-Ba₂UO₂(PO₄)₂ and co-doped phosphor material

For preparing gamma-Ba₂UO₂(PO₄)₂ doped with 1 mol % Eu³⁺ and 1 mol % K⁺, BaHPO₄, UO₂, DAP, Eu₂O₃ and K₂CO₃ were weighed out in a mol ratio of 1.98:1:0.05:0.005:0.005 and then put in a Nalgene bottle with zirconia media and ball milled for two hours. After the mixture was thoroughly blended the powder was transferred into an alumina crucible and fired at 1100° C. for 5 hours in air. After firing, a yellow body colored powder was obtained.

For preparing gamma-Ba₂UO₂(PO₄)z doped with 2 mol % Eu³⁺ and 2 mol % K⁺, BaHPO₄, UO₂, DAP, Eu₂O₃ and K₂CO₃ were weighed out in a mol ratio of 1.96:1:0.05:0.01:0.01 and then put in a Nalgene bottle with zirconia media and ball milled for two hours. After the mixture was thoroughly blended the powder was transferred into an alumina crucible and fired at 1100° C. for 5 hours in air. After firing, a yellow body colored powder was obtained.

For preparing gamma-Ba₂UO₂(PO₄)z doped with 3 mol % Eu³⁺ and 3 mol % K⁺, BaHPO₄, UO₂, DAP, Eu₂O₃ and K₂CO₃ were weighed out in a mol ratio of 1.94:1:0.05:0.015:0.015 and then put in a Nalgene bottle with zirconia media and ball milled for two hours. After the mixture was thoroughly blended the powder was transferred into an alumina crucible and fired at 1100° C. for 5 hours in air. After firing, a yellow body colored powder was obtained.

Results are shown in Table 10

TABLE 10

| | Activator | QE (vs | | |
|---|---|---|---|---|
| Phosphor | Ion | PFS) | ccx | ccy |
| γ-Ba₂UO₂(PO₄)₂ | Eu³⁺, K⁺ (1%) | 0.86 | 0.3802 | 0.5893 |
| γ-Ba₂UO₂(PO₄)₂ | Eu³⁺, K⁺ (2%) | 0.86 | 0.3912 | 0.5782 |
| γ-Ba₂UO₂(PO₄)₂ | Eu³⁺, K⁺ (3%) | 0.88 | 0.3922 | 0.5778 |

coordinates ccx and ccy. Phosphor materials Ba₂UO₂(PO₄)₂ co-doped with counter ion K⁺ show an increased QE. Using different amounts of the activator ion Eu³⁺ show how the phosphor can be color-tuned.

### Example 11

Na₂UO₂P₂O₇ doped with 1% molar amount of Eu³⁺ (U-Eu red phosphor) was prepared as follows: Na₂CO₃, HUO₂PO₄-4H₂O, NaH₂PO₄ and Eu₂O₃ were weighed out in a molar ratio of 0.5:1:1:0.005 in a Nalgene bottle with zirconia media and ball milled for two hours. After the mixture was thoroughly blended the powder was transferred into an alumina crucible and fired at 500° C. for 5 hours. The mixture was then sieved through a 40-mesh screen and blended again in the same Nalgene bottle for two additional hours. The powder was put back into the alumina crucible and fired at 900° C. for 5 hours. After firing, a yellow body colored powder was obtained.

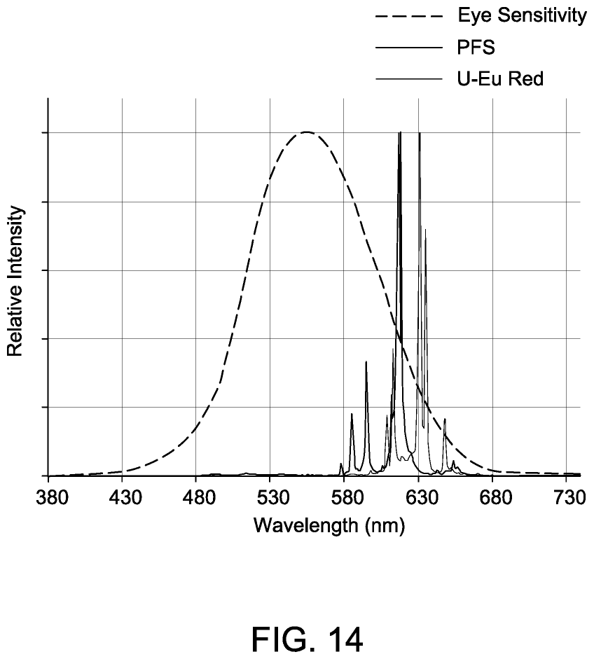

The U-Eu red phosphor was compared with K₂SiF₆:Mn⁴⁺ phosphor (PFS) on FIG. 14. FIG. 14 also shows an eye sensitivity range related to human vision in daylight or other bright light conditions. The eye sensitivity range is centered at 555 nm. The U-Eu red phosphor has a red color and is spectrally shifted closer to the center of the eye sensitivity range than PFS and the emitted light for U-Eu red phosphor will appear brighter. The U-Eu red phosphor has a spectral power of 317.42 lms/Wrad and PFS has a spectral power of 200.82 Lms/Wrad. The U-Eu red phosphor exhibits 58% increase in absorbance over PFS.

The efficacy of white light blends using the U-Eu red phosphor and the PFS phosphor were modeled. Each red phosphor was blended with a YAG phosphor and modeled with a blue LED having a CCT of 4100K. Both blends were modeled in a device to determine efficacy (Lms/watt) measurements. The white light blend with PFS was also measured in a device. Efficacy measurements for the white light blends are shown in Table 11.

TABLE 11

| | Efficacy in Device | Efficacy modeled in |
|---|---|---|
| White light blend | (Lms/W) | Device (Lms/W) |
| White blend with PFS | 168 | 100% |
| White blend with U-Eu red | N/A | 115% |

*Difference in modeling vs actual due to optical losses

The modeled efficacy for the white blend with the U-Eu red phosphor has a 15% increase in efficacy over a white blend with PFS. The high efficacy for the white blend with U-Eu red phosphor is not currently available for commercial market phosphor blends or white LEDs. The CRI measurement for both the White blend with U-EU red and White blend with PFS is >80.

### Example 12: Preparation of Na₂UO₂P₂O₇ Phosphor and Na₂UO₂P₂O₇ doped with 1% Activator Ions Eu³⁺ and varying (NH₄)₂HPO₄ (DAP)

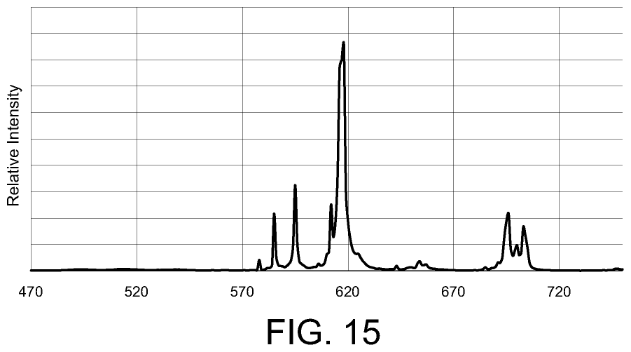

Na₂HPO₄, HUO₂PO₄-4H₂O, Eu₂O₃ and (NH₄)₂HPO₄ were weighted out in a mol ratio of 0.995:1:0.005:0 and then put in a Nalgene bottle with zirconia media and ball milled for two hours. After the mixture was thoroughly blended the powder was transferred into an alumina crucible and fired at 500° C. for 5 hours, the mixture was then sieved through a 40-mesh screen and blended again in the same Nalgene bottle for two additional hours. The powder was put back into the alumina crucible and fired at 900° C. for 5 hours. After the final firing, a yellow body colored powder was obtained. The emission spectra of Na₂UO₂P₂O₇:Eu³⁺ is shown in FIG. 15 and results are shown in Table 12.

For preparing Na₂UO₂P₂O₇ doped with 1% molar amount of Eu³⁺ and 2.5% excess DAP, the same procedure was used, as above, except 0.025 DAP was added. The QE of Na₂UO₂P₂O₇ doped with Eu³⁺ and 2.5% excess (xs) DAP and results are shown in table 12.

Na₂UO₂P₂O₇ doped with 1% molar amount of Eu³⁺ and 5% excess DAP, the same procedure was used, as above, except 0.05 DAP was added. The QE of Na₂UO₂P₂O₇ doped with Eu and 5% xs DAP is shown in table 12.

Na₂UO₂P₂O₇ doped with 1% molar amount of Eu³⁺ and 7.5% excess DAP, the same procedure was used, as above, except 0.075 DAP was added. The QE of Na₂UO₂P₂O₇ doped with Eu³⁺ and 7.5% xs DAP is shown in table 12.

TABLE 12

| | Activator Ion | | QE |
|---|---|---|---|
| Phosphor | (1 molar %) | DAP xs | (vs PFS) |
| Sample 1 | Eu³⁺ | 0 | 0.977 |
| Sample 2 | Eu³⁺ | 2.5 | 1.055 |
| Sample 3 | Eu³⁺ | 5 | 1.037 |
| Sample 4 | Eu³⁺ | 7.5 | 1.007 |

The color point of the phosphor remains the same with excess from 0-7.5% excess (xs) DAP while the QE shows a maximum at 2.5% xs DAP. Only one spectrum is shown in FIG. 15.

### Example 13: Preparation of Na₂UO₂P₂O₇ Phosphor with varying Eu³⁺ concentration

For preparing Na₂UO₂P₂O₇ doped with 1% Eu³⁺, Na₂HPO₄, HUO₂PO₄-4H₂O, Eu₂O₃ and (NH₄)₂HPO₄ were weighted out in a mol ratio of 0.995:1:0.005:0.25 and then put in a Nalgene bottle with zirconia media and ball milled for two hours. After the mixture was thoroughly blended the powder was transferred into an alumina crucible and fired at 500° C. for 5 hours, the mixture was then sieved through a 40-mesh screen and blended again in the same Nalgene bottle for two additional hours. The powder was put back into the alumina crucible and fired at 900° C. for 5 hours. After the final firing, a yellow body colored powder was obtained. The emission spectra of Na₂UO₂P₂O₇:Eu³⁺is shown in FIG. 15, it is the same samples used in example 12 in the results in table 13 it is shown as sample A.

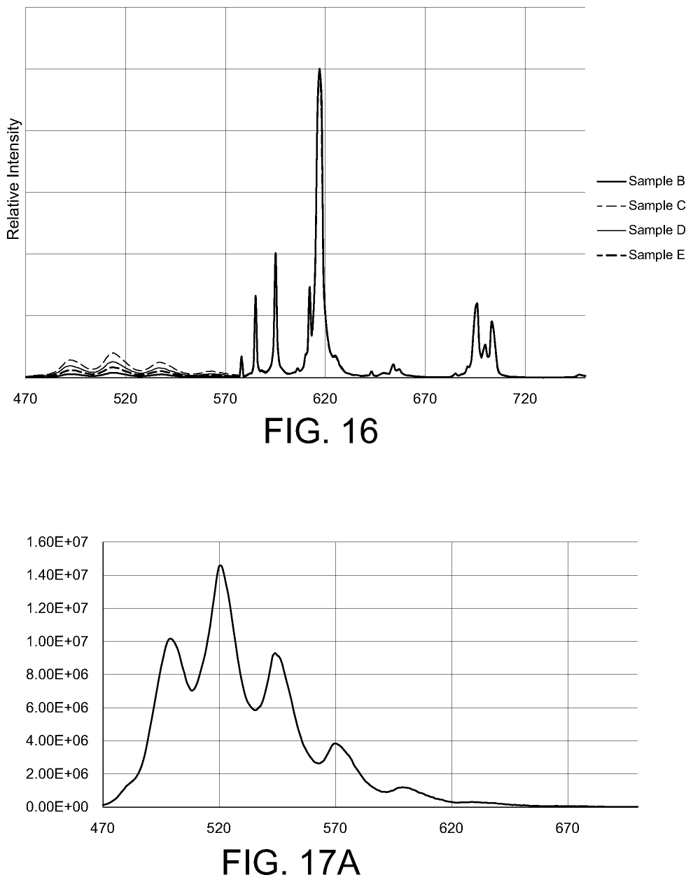

For preparing Na₂UO₂P₂O₇ doped with 0.1% molar amount of Eu³⁺ the same procedure was used, as above, except 0.9995 Na₂HPO₄ and 0.0005 Eu₂O₃ was added. The emission spectra of Na₂UO₂P₂O₇ doped with 0.1% Eu³⁺ is shown in FIG. 16 as sample B and results are shown in table 13.

Na₂UO₂P₂O₇ doped with 0.05% molar amount of Eu³⁺, the same procedure was used, as above, except 0.99975 Na₂HPO₄ and 0.00025 Eu₂O₃ was added. The emission spectra of Na₂UO₂P₂O₇ doped with Eu³⁺ and 0.05% Eu³⁺ is shown in FIG. 16 as sample C and results are shown in table 13.

For preparing Na₂UO₂P₂O₇ doped with 0.03% molar amount of Eu³⁺ the same procedure was used, as above, except 0.99985 Na₂HPO₄ and 0.00015 Eu₂O₃ was added. The emission spectra of Na₂UO₂P₂O₇ doped with 0.03% Eu³⁺ is shown in FIG. 16 as sample D and results are shown in table 13.

Na₂UO₂P₂O₇ doped with 0.02% molar amount of Eu³⁺, the same procedure was used, as above, except 0.9999 Na₂HPO₄ and 0.0001 Eu₂O₃ was added. The emission spectra of Na₂UO₂P₂O₇ doped with Eu³⁺ and 0.02% Eu³⁺ is shown in FIG. 16 as sample E and results are shown in table 13.

TABLE 13

| | Activator | QE (vs | | |
|---|---|---|---|---|
| Phosphor | Ion | PFS) | ccx | ccy |
| Sample A | 1% Eu³⁺ | 1.055 | 0.6394 | 0.3526 |
| Sample B | 0.1% Eu³⁺ | 0.833 | 0.6220 | 0.3639 |
| Sample C | 0.05% Eu³⁺ | 0.765 | 0.5877 | 0.3845 |
| Sample D | 0.03% Eu³⁺ | 0.712 | 0.5581 | 0.4004 |
| Sample E | 0.02% Eu³⁺ | 0.665 | 0.5199 | 0.4257 |

### Example 16: Preparation of Rb₂UO₂P₂O₇ phosphor doped with 1% Activator Ions of Sm³⁺, Eu³⁺ and Pr³⁺

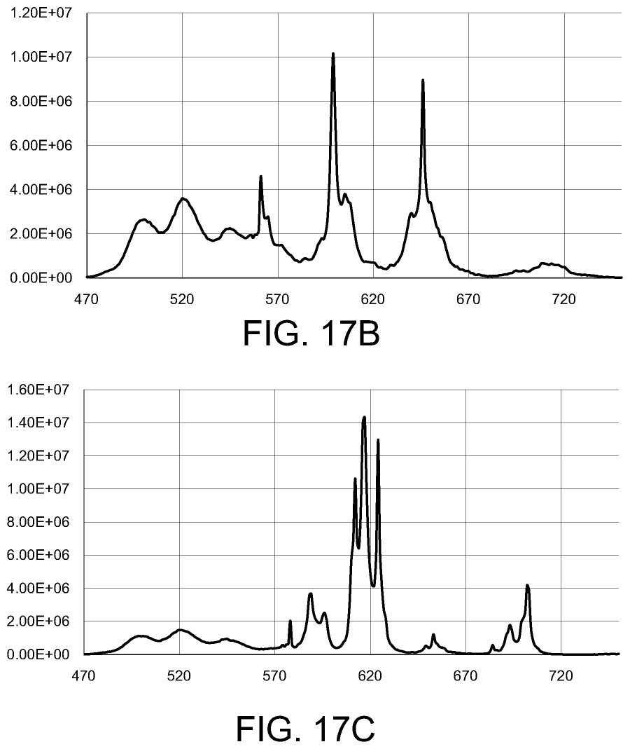

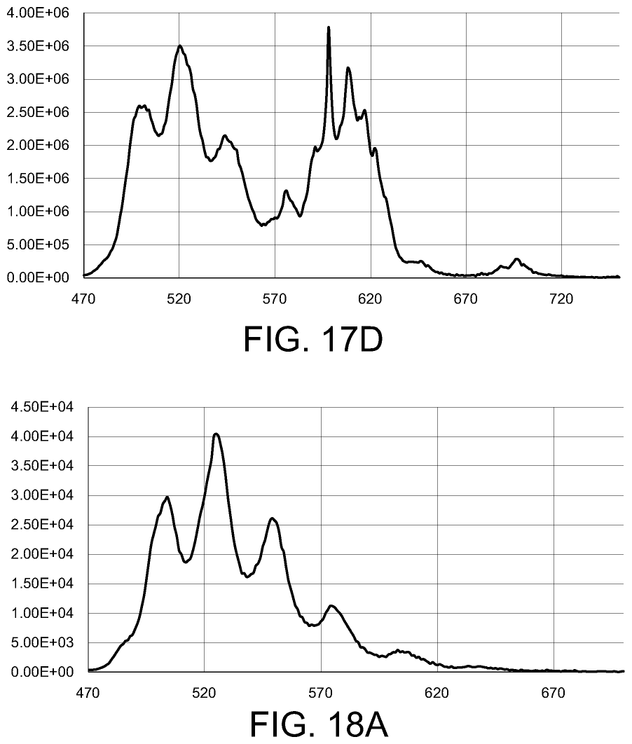

Rb₂CO₃, HUO₂PO₄-4H₂O and (NH₄hHPO₄ were weighted out in a mol ratio of 1:1:1 and then put in a Nalgene bottle with zirconia media and ball milled for two hours. After the mixture was thoroughly blended the powder was transferred into an alumina crucible and fired at 500° C. for 5 hours. The mixture was then sieved through a 40-mesh screen and blended again in the same Nalgene bottle for two additional hours. The powder was put back into the alumina crucible and fired at 900° C. for 5 hours. After the final firing, a yellow body colored powder was obtained. The emission spectra of Rb₂UO₂P₂O₇ is shown in FIG. 17A and the results are shown in Table 16.

For preparing Rb₂UO₂P₂O₇ doped with 1% molar amount of Sm³⁺, the same procedure was used, as above, except 0.995 Rb₂CO₃ and 0.005 Sm₂O₃ was added. The results of Rb₂UO₂P₂O₇ doped with Sm³⁺ is shown in FIG. 17B and the results are shown in table 16.

For preparing Rb₂UO₂P₂O₇ doped with 1% molar amount of Eu³⁺, the same procedure was used, as above, except 0.995 Rb₂CO₃ and 0.005 Eu₂O₃ was added. The results of Rb₂UO₂P₂O₇ doped with Eu³⁺ is shown in FIG. 17C and the results are shown in table 16.

For preparing Rb₂UO₂P₂O₇ doped with 1% molar amount of Pr³⁺, the same procedure was used, as above, except 0.995 Rb₂CO₃ and 0.00167 Pr₆O₁₁ was added. The results of Rb₂UO₂P₂O₇ doped with Pr³⁺ is shown in FIG. 17D and the results are shown in table 16.

TABLE 16

| | Activator Ion | QE (vs B- | | |
|---|---|---|---|---|
| Phosphor | (1 molar %) | SiAlON) | ccx | ccy |
| Rb₂UO₂P₂O₇ | | 0.621 | 0.2254 | 0.6505 |
| Rb₂UO₂P₂O₇ | Sm³⁺ | 0.258 | 0.4107 | 0.5281 |
| Rb₂UO₂P₂O₇ | Eu³⁺ | 0.704 | 0.5399 | 0.4266 |
| Rb₂UO₂P₂O₇ | Pr³⁺ | 0.455 | 0.3863 | 0.5416 |

The color point change shows energy transfer to the Sm, Eu, Pr ions. The addition of Eu³⁺ showed an increase in the QE; while activator ions Sm³⁺ and Pr³. Other Examples herein demonstrate how quantum efficiency can be increased in the phosphor samples.

### Example 17: Preparation of Cs₂UO₂P₂O₇ phosphor doped with 1% activator ions of Eu³⁺, Pr³⁺ and Sm³⁺

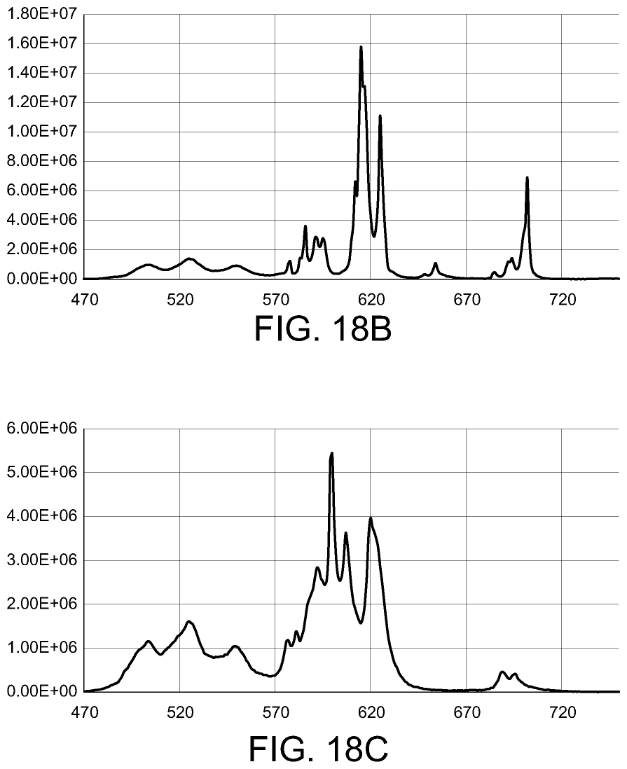

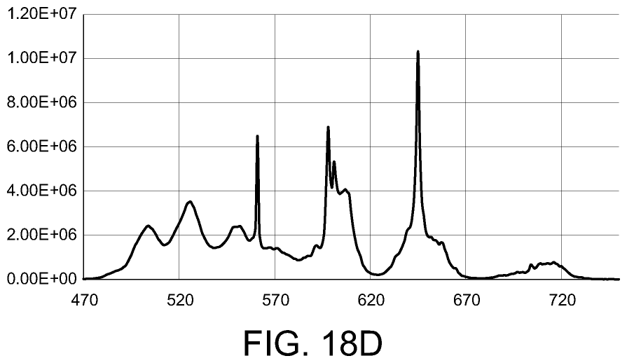

For preparing Cs₂UO₂P₂O₇, Cs₂CO₄, HUO₂PO₄-4H₂O and (NH₄)₂HPO₄ were weighted out in a mol ratio of 1:1:1 and then put in a Nalgene bottle with zirconia media and ball milled for two hours. After the mixture was thoroughly blended the powder was transferred into an alumina crucible and fired at 500° C. for 5 hours, the mixture was then sieved through a 40-mesh screen and blended again in the same Nalgene bottle for two additional hours. The powder was put back into the alumina crucible and fired at 900° C. for 5 hours. After the final firing, a yellow body colored powder was obtained. The emission spectra of Cs₂UO₂P₂O₇ is shown in FIG. 18A and the results are shown in table 17.

For preparing Cs₂UO₂P₂O₇ doped with 1% molar amount of Eu³⁺ the same procedure was used, as above, except 0.995 Cs₂CO₃ and 0.005 Eu₂O₃ was added. The emission spectra of Cs₂UO₂P₂O₇ doped with 1% Eu³⁺ is shown in FIG. 18B and the results are shown in table 17.

Another sample of Cs₂UO₂P₂O₇ doped with 1% molar amount of Eu³⁺ was prepared in the same manner and a wash step was included. Sample Cs₂UO₂P₂O₇ doped with 1% molar amount of Eu³⁺ was washed in water. The results are shown in table 17.

Cs₂UO₂P₂O₇ doped with 1% molar amount of Pr³⁺, the same procedure was used, as above, except 0.995 Cs₂CO₃ and 0.00167 Pr₆O₁₁ was added. The emission spectra of Cs₂UO₂P₂O₇ doped with 1% Pr³⁺ is shown in FIG. 18C and the results are shown in table 17.

For preparing Cs₂UO₂P₂O₇ doped with 1% molar amount of Sm³⁺ the same procedure was used, as above, except 0.995 Cs₂CO₃ and 0.005 Sm₂O₃ was added. The emission spectra of Cs₂UO₂P₂O₇ doped with 1% Sm³⁺ is shown in FIG. 18D and the results are shown in table 17.

TABLE 17

| | Activator | QE (vs B- | | |
|---|---|---|---|---|
| Phosphor | Ion | Sialon) | ccx | ccy |
| Cs₂UO₂P₂O₇ | | 0.662 | 0.2462 | 0.6542 |
| Cs₂UO₂P₂O₇ | 1% Eu³⁺ | 0.748 | 0.5512 | 0.4245 |
| Cs₂UO₂P₂O₇ | 1% Eu³⁺ | 0.867 | | |
| with Wash step | | | | |
| Cs₂UO₂P₂O₇ | 1% Pr³⁺ | | 0.4974 | 0.4682 |
| Cs₂UO₂P₂O₇ | 1% Sm³⁺ | 0.587 | 0.4246 | 0.5296 |

The color point change shows that there is energy transfer to the ions of Eu, Pr and Sm. The QE measurement for the phosphor containing activator ion Sm was slightly reduced. The QE measurement for the phosphor with Eu³⁺ was improved. The QE measurement was improved further by adding a wash step. The water wash step not only slightly increased the QE of the sample, but showed that the host lattice is not hygroscopic.

### Example 18: Preparation of Cs₂UO₂P₂O₇ Phosphor doped with varying amounts of Eu³⁺

For preparing Cs₂UO₂P₂O₇ doped with 1% Eu³⁺, Cs₂CO₃, HUO₂PO₄-4H₂O, (NH₄)₂HPO₄ and Eu₂O₃ were weighted out in a mol ratio of 0.995:1:1:0.005 and then put in a Nalgene bottle with zirconia media and ball milled for two hours. After the mixture was thoroughly blended the powder was transferred into an alumina crucible and fired at 500° C. for 5 hours, the mixture was then sieved through a 40-mesh screen and blended again in the same Nalgene bottle for two additional hours. The powder was put back into the alumina crucible and fired at 900° C. for 5 hours. After the final firing, a yellow body colored powder was obtained. The results of Cs₂UO₂P₂O₇:1% Eu³⁺ is shown in table 18.

For preparing Cs₂UO₂P₂O₇ doped with 2% molar amount of Eu³⁺ the same procedure was used as above, except 0.99 Cs₂CO₃ and 0.01 Eu₂O₃ was added. The results of Cs₂UO₂P₂O₇:2% Eu³⁺ is shown in table 18.

For preparing Cs₂UO₂P₂O₇ doped with 3% molar amount of Eu³⁺ the same procedure was used as above, except 0.985 Cs₂CO₃ and 0.015 Eu₂O₃ was added. The results of Cs₂UO₂P₂O₇:3% Eu³⁺ is shown in table 18.

TABLE 18

| | Activator | QE (vs B- | | |
|---|---|---|---|---|
| Phosphor | Ion | Sialon) | ccx | ccy |
| Cs₂UO₂P₂O₇ | 1% Eu³⁺ | 0.753 | 0.5337 | 0.4368 |
| Cs₂UO₂P₂O₇ | 2% Eu³⁺ | 0.732 | 0.5196 | 0.4470 |
| Cs₂UO₂P₂O₇ | 3% Eu³⁺ | 0.707 | 0.5308 | 0.4399 |

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A uranium-based phosphor selected from the group consisting of:
(i) a phosphor having formula I or II: 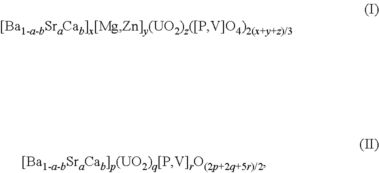
wherein the phosphor having formula I or II is doped with an activator ion comprising Pr^{;+}, Sm³⁺, or mixtures thereof, wherein 0≤a≤1, 0≤b≤1, 0.75≤x≤1.25, 0.75≤y≤1.25, 0.75≤z≤1.25, 2.5≤p≤3.5, 1.75≤q≤2.25, and 3.5≤r≤4.5;
(ii) a phosphor having formula I or II, wherein the phosphor having formula I or II is doped with an activator ion selected from the group consisting of: Eu³⁺, Pr³⁺, Sm³⁺, and mixtures thereof, and a counter ion comprising one or more alkali metal ions; and
(iii) a phosphor having formula III: 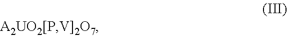
wherein the phosphor having formula III is doped with an activator ion selected from the group consisting of: Eu³⁺, Pr³⁺, Sm³⁺, and mixtures thereof, wherein A is Li, Na, K, Rb, Cs, or a combination thereof.

2. The uranium-based phosphor according to claim 1, wherein the uranium-based phosphor is (i) a phosphor having formula I or II, wherein the phosphor having formula I or II is doped with an activator ion comprising Pr^{y}, Sm³⁺, or mixtures thereof.

3. The uranium-based phosphor according to claim 1, wherein the phosphors having formula I or II are selected from the group consisting of: Ba₃(PO₄)₂(UO₂)₂P₂O₇, BaZnUO₂(PO₄)₂, BaMgUO₂(PO₄)₂, and γ-Ba₂UO₂(PO₄)₂ and the phosphors having formula III are selected from the group consisting of: Na₂UO₂P₂O₇, K₂UO₂P₂O₇, Rb₂UO₂P₂O₇, and Cs₂UO₂P₂O₇.

4. The uranium-based phosphor according to claim 1, wherein the uranium-based phosphor is (ii) a phosphor having formula I or II, wherein the phosphor having formula I or II is doped with an activator ion selected from the group consisting of: Eu³, Pr^{y}, Sm³⁺, and mixtures thereof, and a counter ion comprising one or more alkali metal ions.

5. The uranium-based phosphor according to claim 4, wherein the one or more alkali metal ions is selected from the group consisting of: Li⁺, Na⁺, K⁺, Rb⁺ and Cs⁺.

6. The uranium-based phosphor according to claim 1, wherein the uranium-based phosphor is (iii) a phosphor having formula III, wherein the phosphor is doped with an activator ion selected from the group consisting of: Eu³⁺, Pr³⁺, Sm³⁺, and mixtures thereof.

7. The uranium-based phosphor according to claim 1, wherein the activator ion is present in an amount of from about 0.1 molar percent to about 10 molar percent.

8. A uranium-based phosphor having formula (III), (N) or (V): 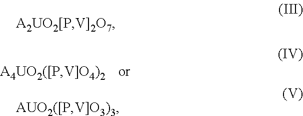
wherein A is Li, Na, K, Rb, Cs, or a combination thereof.

9. The uranium-based phosphor according to claim 8, wherein the uranium-based phosphor is K₂UO₂P₂O₇, Na₂UO₂P₂O₇, Rb₂UO₂P₂O₇, Cs₂UO₂P₂O₇, K₄UO₂(PO₄)₂ or NaUO₂P₃O₉.

10. The uranium-based phosphor according to claim 1 or claim 8, wherein the uranium-based phosphor has a D50 particle size from about 0.1 μm to about 15 μm.

11. A phosphor composition comprising the uranium-based phosphor according to claim 1 and a red emitting phosphor having formula VI: 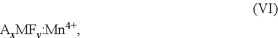
wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof, x is an absolute value of a charge of the MF_{y} ion; and y is 5, 6 or 7.

12. The phosphor composition according to claim 11, wherein the red emitting phosphor comprises:
K₂(TiF₆):Mn⁴⁺, K₂(SnF₆):Mn⁴⁺, Cs₂(TiF₆):Mn⁴⁺, Rb₂(TiF₆):Mn⁴⁺, Cs₂(SiF₆):Mn⁴⁺, Rb₂(SiF₆):Mn⁴⁺, Na₂(SiF₆):Mn⁴⁺, Na₂(TiF₆):Mn⁴¹ Na₂(ZrF₆):Mn⁴⁺, K₃(ZrF₇):Mn⁴⁺, K₃(BiF₇):Mn⁴⁺, K₃(YF₇):Mn⁴⁺, K₃(LaF₇):Mn⁴⁺, K₃(GdF₇):Mn⁴⁺, K₃(NbF₇):Mn⁴⁺or K₃(TaF₇):Mn⁴⁺.

13. The phosphor composition according to claim 11, wherein the red emitting phosphor is K₂SiF₆:Mn⁴⁺.

14. The phosphor composition according to claim 11, wherein the red emitting phosphor is at least partially coated with a surface coating comprising a metal fluoride or a silica.

15. The phosphor composition according to claim 14, wherein the metal fluoride is selected from the group consisting of MgF₂, CaF₂, SrF₂, BaF₂, AgF, ZnF₂, AlF₃, and a combination thereof.

16. The phosphor composition according to claim 11, wherein the uranium-based phosphor and the red emitting phosphor have a D50 particle size from about 0.1 μm to about 15 μm.

17. A phosphor composition comprising the uranium-based phosphor according to claim 1 and at least one other luminescent material.

18. The phosphor composition according to claim 17, wherein the at least one other luminescent material comprises [Ba,Sr,Ca]₂SiO₄:Eu²⁺[Y,Gd,Lu,Tb]₃[Al,Ga]₅O₁₂:Ce³⁺, β-SiAlON:Eu²⁺, [Sr,Ca,Ba][Ga,Al]₂Sa:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, K₂SiF₆:Mn⁴⁺, phosphorescent dyes, color filter pigments, scattering particles, polyfluorenes, or quantum dot material.

19. The phosphor composition according to claim 18, wherein the quantum dot material comprises perovskite quantum dots.

20. A device comprising an LED light source radiationally and/or optically coupled to the uranium-based phosphor according to claim 1 or claim 8.

21. The device according to claim 20, further comprising a red emitting phosphor having formula VI: 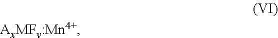
wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof, x is an absolute value of a charge of the MF_{y} ion; and y is 5, 6 or 7.

22. The device according to claim 20, further comprising at least one other luminescent material comprises [Ba,Sr,Ca]₂SiO₄:Eu²⁺, [Y,Gd,Lu,Tb]₃[Al,Ga]₅O₁₂:Ce³⁺, β-SiAlON:Eu²⁺, [Sr,Ca,Ba][Ga,Al]₂S₄:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, K₂SiF₆:Mn⁴⁺, polyfluorenes, or quantum dot material.

23. The device according to claim 20 wherein the uranium-based phosphor is in a form of a film and is located remotely from the LED light source.

24. The device according to claim 23, wherein the film comprises a single layer or a multilayered structure and the single layer or each layer of the multilayered structure comprises at least one of the uranium-based phosphor or a quantum dot material.

25. A lighting apparatus comprising the device of claim 20.

26. A backlight apparatus comprising the device of claim 20.

27. A display apparatus comprising the device of claim 20.

28. The device according to claim 20, wherein the LED light source is a mini LED or a micro LED.

29. A television comprising the backlight apparatus of claim 26.

30. A mobile phone comprising the backlight apparatus of claim 26.

31. A computer monitor comprising the backlight apparatus of claim 26.

32. A laptop comprising the backlight apparatus of claim 26.

33. A tablet computer comprising the backlight apparatus of claim 26.

34. An automotive display comprising the backlight apparatus of claim 26.

35. A horticulture lighting apparatus comprising the device of claim 20.

36. The horticulture lighting apparatus according to claim 35, and further comprising a red emitting phosphor of formula VI: 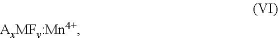
wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof, x is an absolute value of a charge of the MF_{y} ion; and y is 5, 6 or 7.

37. A phosphor package for horticulture lighting, the phosphor package comprising a phosphor material comprising the uranium-based phosphor according to claim 1.

38. The phosphor package for horticulture lighting according to claim 37, further comprising a red phosphor having formula VI: 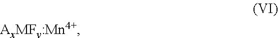
wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof, x is an absolute value of a charge of the MF_{y} ion; and y is 5, 6 or 7.

39. The phosphor package of claim 38, wherein the uranium-based phosphor and the red phosphor have a particle size from about 0.1 micron to about 5 microns and is dispersed in a film or sheet.

40. The phosphor package of claim 37, wherein the activator ion is Sm³⁺ or Pr³⁺.

41. The phosphor package of claim 37, wherein the uranium-based phosphor has a particle size from about 0.1 micron to about 5 microns and is dispersed in a film or sheet.

42. The uranium-based phosphor according to claim 7, wherein the counter ion is present in about the same amount as the activator ion.

43. A uranium-based phosphor selected from the group consisting of:
(i) a phosphor having formula VII: 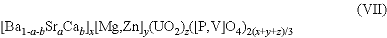
wherein the phosphor having formula VII is doped with an activator ion selected from the group consisting of: Sn²⁺, Sb³⁺, Er³⁺, Tm³⁺, Yb³⁺, Ho³⁺, and mixtures thereof, wherein O≤a≤1, 0≤b≤1, 0.75≤x≤1.25, 0.75≤y≤1.25, and 0.75≤z≤1.25;
(ii) a phosphor having formula VII, wherein the phosphor having formula VII is doped with an activator ion selected from the group consisting of: Eu³⁺, Tb³⁺, Dy³⁺, Ce³⁺, Mn²⁺, Nd³⁺, Gd³⁺, Bi³⁺, and mixtures thereof, wherein 0≤a≤1, 0≤b:51, 0.75≤x≤1.25, 0.75≤y≤1.25, and 0.75≤z≤1.25;
(iii) a phosphor having formula VII, wherein the phosphor having formula VII or VIII is doped with an activator ion selected from the group consisting of Eu³⁺, Sm³⁺, Tb³⁺, Ce³⁺, Yb³⁺, and mixtures thereof, and a counter ion comprising one or more alkali metal ions;
(iv) a phosphor having formula VIII: 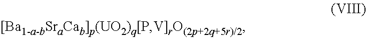
wherein the phosphor having formula VIII is doped with an activator ion comprising Tb³⁺, Dy³⁺, or mixtures thereof, wherein 0≤a≤1, 0≤b≤1, 2.5≤p≤3.5, 1.75≤q≤2.25, and 3.5≤r≤4.5; and a counter ion comprising one or more alkali metal ions;
(v) a phosphor having formula IX: 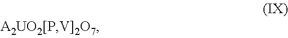
wherein the phosphor having formula IX is doped with an activator ion selected from the group consisting of: Tb³⁺, Dy³⁺, or mixtures thereof, wherein A is Li, Na, K, Rb, Cs, or a combination thereof.

44. The uranium-based phosphor according to claim 43, wherein the phosphors having formula VII or VIII are selected from the group consisting of: Ba₃(PO₄)₂(UO₂)₂P₂O₇, BaZnUO₂(PO₄)₂, BaMgUO₂(PO₄)₂, and γ-Ba₂UO₂(PO₄)₂ and the phosphors having formula IX are selected from the group consisting of Na₂UO₂P₂O₇, K₂UO₂P₂O₇, Rb₂UO₂P₂O₇, and Cs₂UO₂P₂O₇.

45. The uranium-based phosphor according to claim 43, wherein the activator ion is present in an amount of from about 0.1 molar percent to about 10 molar percent.

46. The uranium-based phosphor according to claim 43, wherein the uranium-based phosphor is (i) a phosphor having formula VII, wherein the phosphor having formula VII is doped with an activator ion selected from the group consisting of: Sn²⁺, Sb³⁺, Er³⁺, Tm³⁺, Yb³⁺, Ho³, and mixtures thereof, wherein 0≤a≤1, 0≤b≤1, 0.75≤x≤1.25, 0.75≤y≤1.25, and 0.75≤z≤1.25.

47. The uranium-based phosphor according to claim 43, wherein the uranium-based phosphor is (iii) a phosphor having formula VII, wherein the phosphor having formula VII or VIII is doped with an activator ion selected from the group consisting of Eu³⁺, Sm³⁺, Tb³⁺, Dy³⁺, Ce³⁺, Yb³⁺, and mixtures thereof, and a counter ion comprising one or more alkali metal ions.

48. The uranium-based phosphor according to claim 47, wherein the one or more alkali metal ions is selected from the group consisting of: Li⁺, Na⁺, K⁺, Rb⁺ and Cs⁺.

49. The uranium-based phosphor according to claim 47, wherein the activator ion is present in an amount of from about 0.1 molar percent to about 10 molar percent and the counter ion is present in about the same amount as the activator ion.

50. A phosphor composition comprising the uranium-based phosphor according to claim 43 and a red emitting phosphor having formula X: 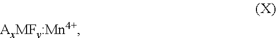
wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof, x is an absolute value of a charge of the MF_{y} ion; and y is 5, 6 or 7.

51. The phosphor composition according to claim 50, wherein the red emitting phosphor comprises:
K₂(TiF₆):Mn⁴⁺, K₂(SnF₆):Mn⁴⁺, Cs₂(TiF₆):Mn⁴⁺, Rb₂(TiF₆):Mn⁴⁺, Cs₂(SiF₆):Mn⁴, Rb₂(SiF₆):Mn⁴⁺, Na₂(SiF₆):Mn⁴⁺, Na₂(TiF₆):Mn⁴⁺, Na₂(ZrF₆):Mn⁴⁺, K₃(ZrF₇):Mn⁴⁺, K₃(BiF₇):Mn⁴⁺, K₃(YF₇):Mn⁴⁺, K₃(LaF₇):Mn⁴⁺, K₃(GdF₇):Mn⁴⁺, K₃(NbF₇):Mn⁴⁺or K₃(TaF₇):Mn⁴⁺.

52. The phosphor composition according to claim 50, wherein the red emitting phosphor is K₂SiF₆:Mn⁴⁺.

53. The phosphor composition according to claim 50, wherein the red emitting phosphor is at least partially coated with a surface coating comprising a metal fluoride or a silica.

54. The phosphor composition according to claim 53, wherein the metal fluoride is selected from the group consisting of MgF₂, CaF₂, SrF₂, BaF₂, AgF, ZnF₂, AlF₃, and a combination thereof.

55. The phosphor composition according to claim 50, wherein the uranium-based phosphor and the red emitting phosphor have a D50 particle size from about 0.1 μm to about 15 μm.

56. A phosphor composition comprising the uranium-based phosphor according to claim 43 and at least one other luminescent material.

57. The phosphor composition according to claim 56, wherein the at least one other luminescent material comprises [Ba,Sr,Ca]₂SiO₄:Eu²+[Y,Gd,Lu,Tb]₃[Al,Ga]₅O₁₂:Ce³⁺, β-SiAlON:Eu²⁺, [Sr,Ca,Ba][Ga,Al]₂Sa:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, K₂SiF₆:Mn⁴⁺, phosphorescent dyes, color filter pigments, scattering particles, polyfluorenes, or quantum dot material.

58. The phosphor composition according to claim 57, wherein the quantum dot material comprises perovskite quantum dots.

59. A device comprising an LED light source radiationally and/or optically coupled to the uranium-based phosphor according to claim 43.

60. The device according to claim 59, further comprising a red emitting phosphor having formula X: 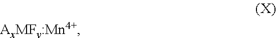
wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof, x is an absolute value of a charge of the MF_{y} ion; and y is 5, 6 or 7.

61. The device according to claim 60, further comprising at least one other luminescent material comprises [Ba,Sr,Ca]₂SiO₄:Eu²⁺, [Y,Gd,Lu,Tb]3[Al,Ga]₅O₁₂:Ce³⁺, β-SiAlON:Eu²⁺, [Sr,Ca,Ba][Ga,Al]₂S₄:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, K₂SiF₆:Mn⁴⁺, polyfluorenes, or quantum dot material.

62. The device according to claim 61, wherein the uranium-based phosphor is in a form of a film and is located remotely from the LED light source.

63. The device according to claim 62, wherein the film comprises a single layer or a multilayered structure and the single layer or each layer of the multilayered structure comprises at least one of the uranium-based phosphor or a quantum dot material.

64. A lighting apparatus comprising the device of claim 59.

65. A backlight apparatus comprising the device of claim 59.

66. A display apparatus comprising the device of claim 59.

67. The device according to claim 59, wherein the LED light source is a mini LED or a micro LED.

68. A television comprising the backlight apparatus of claim 65.

69. A mobile phone comprising the backlight apparatus of claim 65.

70. A computer monitor comprising the backlight apparatus of claim 65.

71. A laptop comprising the backlight apparatus of claim 65.

72. A tablet computer comprising the backlight apparatus of claim 65.

73. An automotive display comprising the backlight apparatus of claim 65.

74. A horticulture lighting apparatus comprising the device of claim 59.

75. The horticulture lighting apparatus according to claim 74, further comprising a red emitting phosphor of formula X: 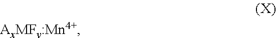
wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof, x is an absolute value of a charge of the MF_{y} ion; and y is 5, 6 or 7.

76. A phosphor package for horticulture lighting, the phosphor package comprising a phosphor material comprising the uranium-based phosphor according to claim 43.

77. The phosphor package according to claim 76, further comprising a red emitting phosphor of formula X: 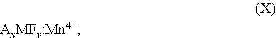
wherein A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof, x is an absolute value of a charge of the MF_{y} ion; and y is 5, 6 or 7.

78. The phosphor package of claim 77, wherein the uranium-based phosphor and the red phosphor have a particle size from about 0.1 micron to about 5 microns and is dispersed in a film or sheet.
